(19) United States
(12) Patent Application Publication
(10) Pub. No.: US 2026/0193277 A1
(43) Pub. Date: Jul. 9, 2026

(54) METAL AMIDE COMPLEXES AND METHODS OF USE THEREOF

(71) Applicants: The University of Hong Kong, Hong Kong (CN); Hong Kong Quantum AI Lab Limited, Hong Kong (CN)

(72) Inventors: Chi-Ming Che, Hong Kong (CN); Huixing Shu, Hong Kong (CN); Ching-Fai Yip, Hong Kong (CN)

(21) Appl. No.: 19/414,551

(22) Filed: Dec. 10, 2025

Related U.S. Application Data
(60) Provisional application No. 63/741,514, filed on Jan. 3, 2025.

(51) Int. Cl. C07F 1/10; C07F 15/00; H10K 50/10

(52) U.S. Cl. CPC C07F 1/10; C07F 15/006; C07F 15/0086; H10K 50/10

(57) ABSTRACT

Described herein are metal complexes and their methods of making and using thereof. In some forms, the metal complexes contain a C_{NHC}\hat{ }C\hat{ }C_{NHC} (NHC=N-heterocyclic carbene) pincer ligand, and feature a through-bond donor-acceptor configuration. The donor (e.g., the amide group) is coordinated to the metal ion, while the acceptor (e.g., 2,4,6-triphenyl-1,3,5-triazine and its derivatives) is incorporated to the pincer ligand and located at the para-position of carbanion. In some forms, the incorporation of an acceptor (e.g., 2,4,6-triphenyl-1,3,5-triazine and its derivatives) can be applied to pincer ligands N\hat{ }C\hat{ }N and/or C\hat{ }C\hat{ }N, in which the C_{NHC} donors of C_{NHC}\hat{ }C\hat{ }C_{NHC} ligand can be replaced with neutral N-donor(s) and/or a carbanion in the metal complexes. The design of the metal complexes disclosed herein can lead to improved photophysical properties, such as shortened emission lifetime and/or increased radiative decay rate constant, and thereby improving their device performance in OLED devices.

### CROSS-REFERENCE TO RELATED APPLICATIONS

This application claims the benefit of and priority to U.S. Provisional Application No. 63/741,514 filed Jan. 3, 2025, which is herein incorporated by reference in its entirety.

### FIELD OF THE INVENTION

This invention is generally in the field of metal complexes and their use as light emitters.

### BACKGROUND OF THE INVENTION

Over the past decade, many tetradentate platinum emitters (red, green and blue) have been reported that display photophysical properties and are useful in OLED devices.

Although tetradentate platinum emitters may show stronger chelating effect and rigidity, the preparation of such tetradentate ligands requires complicated chemical synthetic procedures and substantial efforts.

There remains a need for metal complexes that are light emitters.

Therefore, it is the object of the present invention to provide metal complexes that emit light.

It is a further object of the present invention to provide metal complexes with increased radiative decay rate constant and/or shortened emission lifetime.

It is a further object of the present invention to provide devices containing the metal complexes.

It is a further object of the present invention to provide methods for using the metal complexes.

### BRIEF SUMMARY OF THE INVENTION

Metal amide complexes (also referred to herein as “metal complexes”) that are efficient light emitters and methods of making and using thereof are described. In some forms, the metal complexes contain a C_{NHC}\hat{ }C\hat{ }C_{NHC} (NHC=N-heterocyclic carbene) pincer ligand, and feature a through-bond donor-acceptor configuration. The donor (e.g., the amide group) is coordinated to the metal ion, while the acceptor (e.g., 2,4,6-triphenyl-1,3,5-triazine and its derivatives) is incorporated to the pincer ligand and located at the para-position of carbanion. In some forms, the incorporation of an acceptor (e.g., 2,4,6-triphenyl-1,3,5-triazine and its derivatives) can be applied to pincer ligands N\hat{ }C\hat{ }N and/or C\hat{ }C\hat{ }N, in which the C_{NHC} donors of C_{NHC}\hat{ }C\hat{ }C_{NHC} ligand can be replaced with neutral N-donor(s) and/or a carbanion in the metal complexes.

The molecular design of the metal complexes introduces ligand (e.g., the amide group) to ligand (e.g., 2,4,6-triphenyl-1,3,5-triazine and its derivatives) charge transfer (LL′CT) character to the excited states of the metal complexes. This is different from the molecular design employed by Li et al. (CN116675718A) that uses platinum/palladium amide complexes with the acceptor group covalently bonded to the amide group and the acceptor group faces the pincer metal complex, resulting in metal-perturbed intraligand charge transfer (MPICT) excited state. The design of the metal complexes disclosed herein can improve the photophysical properties of these metal complexes (d8 metal amide complexes (Pt(II), Pd(II), Au(III)) with C_{NHC}\hat{ }C\hat{ }C_{NHC}, N\hat{ }CAN and/or C\hat{ }CAN ligands), such as shortened emission lifetime and/or increased radiative decay rate constant, and thereby improving their device performance in OLED devices.

In some forms, the metal complexes can have the structure of Formula I:

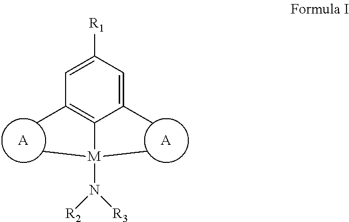

wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) R₁ can be

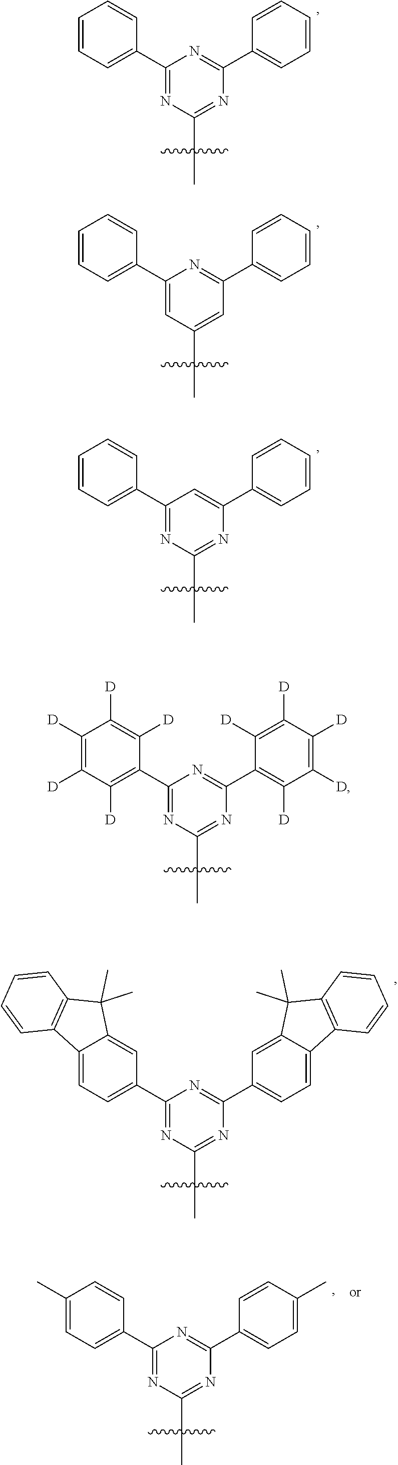

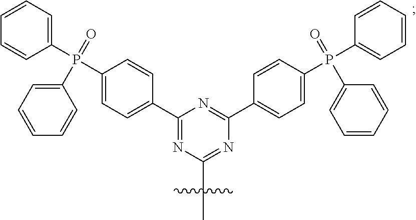 [SMILES: *c1nc(-c2ccc(P(=O)(c3ccccc3)c3ccccc3)cc2)nc(-c2ccc(P(=O)(c3ccccc3)c3ccccc3)cc2)n1]

(iv) R₂ and R₃ can be independently a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or R₂ and R₃ together with the nitrogen atom to which they are attached can form a fused ring system; and (v) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

In some forms, R₂ and R₃ can be independently a substituted alkyl, an unsubstituted alkyl, a substituted aryl (e.g., a substituted phenyl), or an unsubstituted aryl (e.g., an unsubstituted phenyl). In some forms, R₂ and R₃ can be independently an unsubstituted alkyl or an unsubstituted phenyl.

When R₂ and R₃ together with the nitrogen atom to which they are attached can form a fused ring system, the fused ring system can contain aromatic rings, non-aromatic rings, or a combination thereof, such as a polyaryl, an heteropolyaryl, a polyheteroaryl, a fused cycloalkyl, a fused cycloalkenyl, a fused cycloalkynyl, etc.

In some forms, the metal complex can have any one of the following structures:

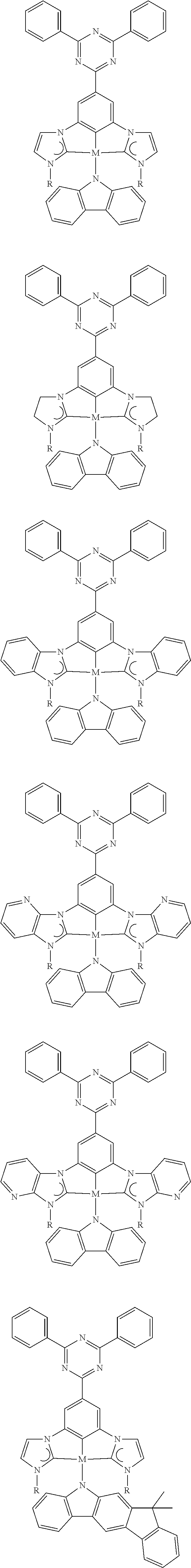

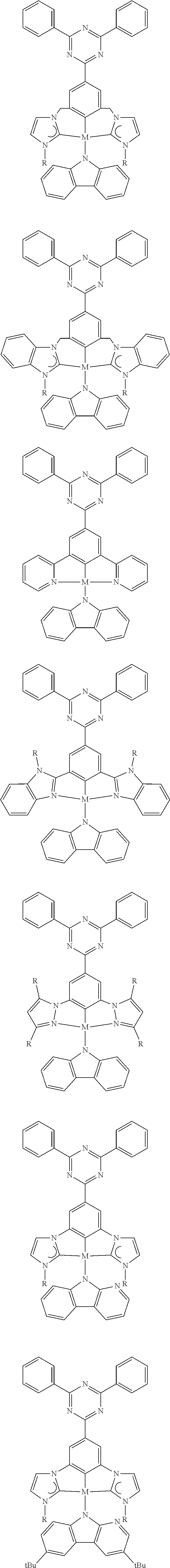

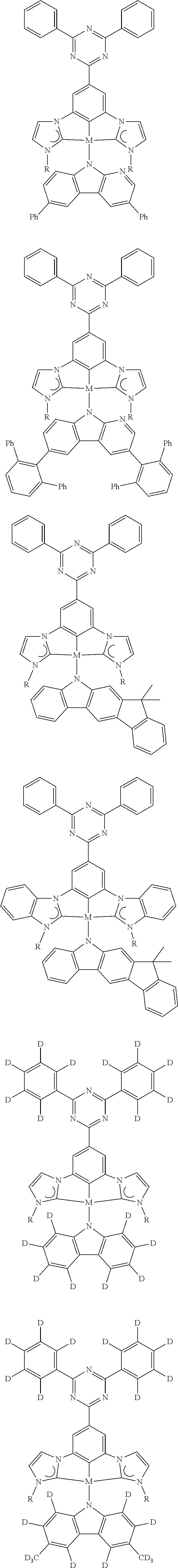

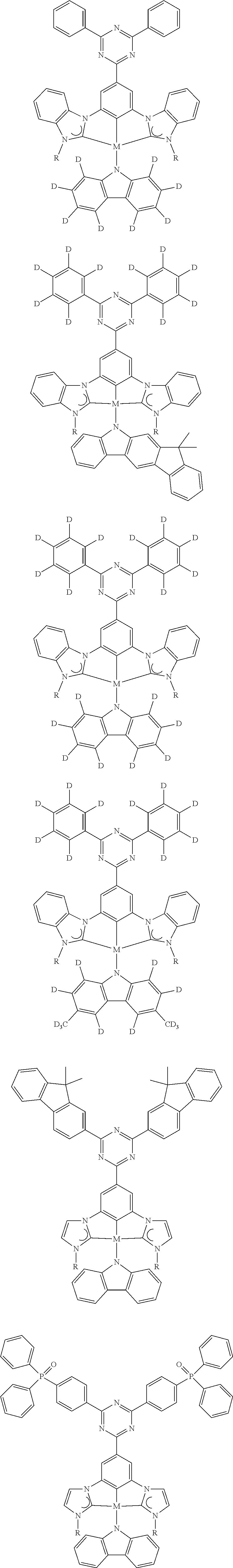

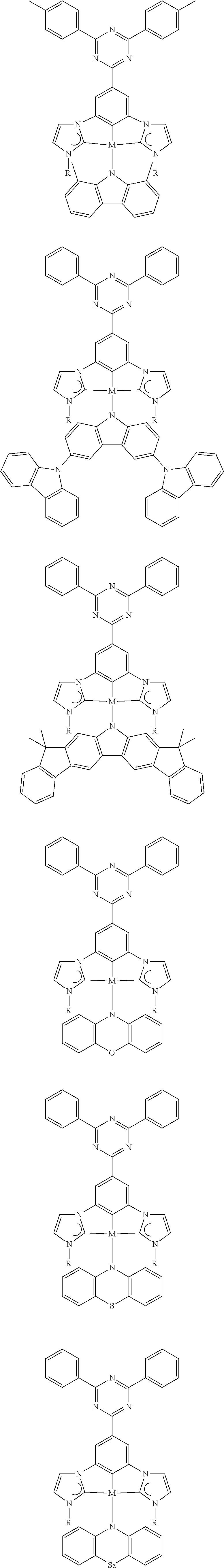

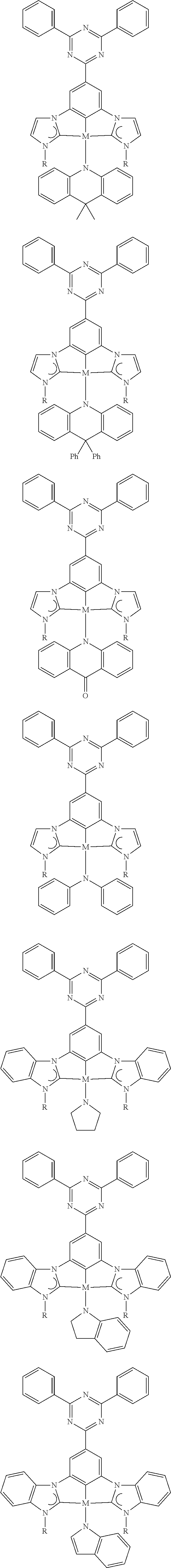

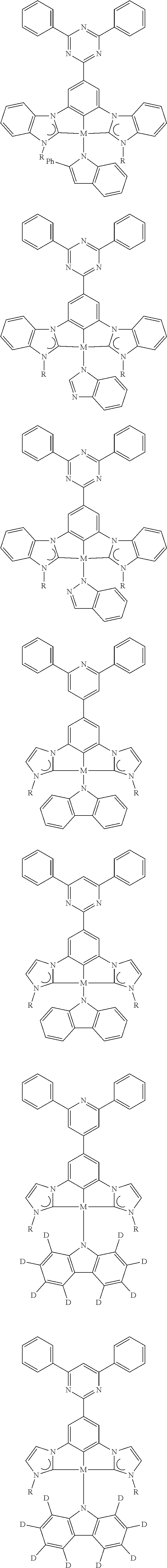

wherein M can be Pt, Pd, or Au; each R can be independently a substituted C₁-C₆ alkyl, an unsubstituted C₁-C₆ alkyl, a substituted phenyl, or an unsubstituted phenyl; and the substituent(s), when present, can be independently an unsubstituted C₁-C₁₂ alkyl. In some forms, each R can be independently an unsubstituted C₁-C₆ alkyl,

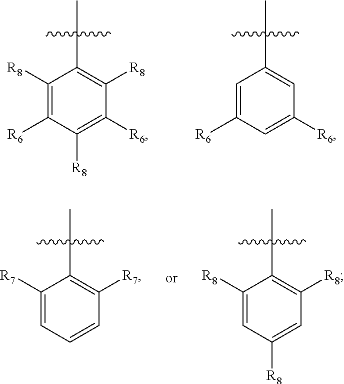

and each R₆, R₇, and R₈ can be independently hydrogen, deuterium, or an unsubstituted C₁-C₁₂ alkyl. In some forms, each R can be independently

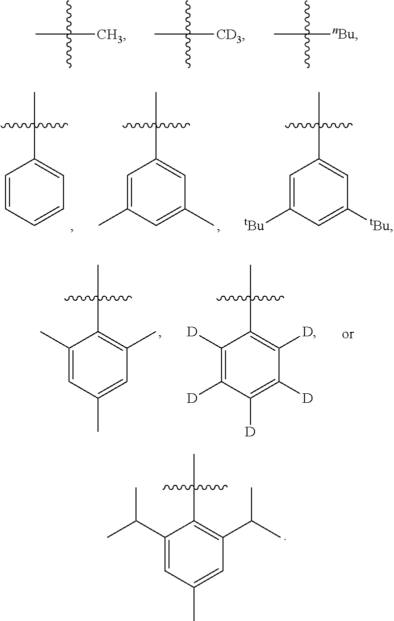

Exemplary Pt and Pd complexes are presented below.

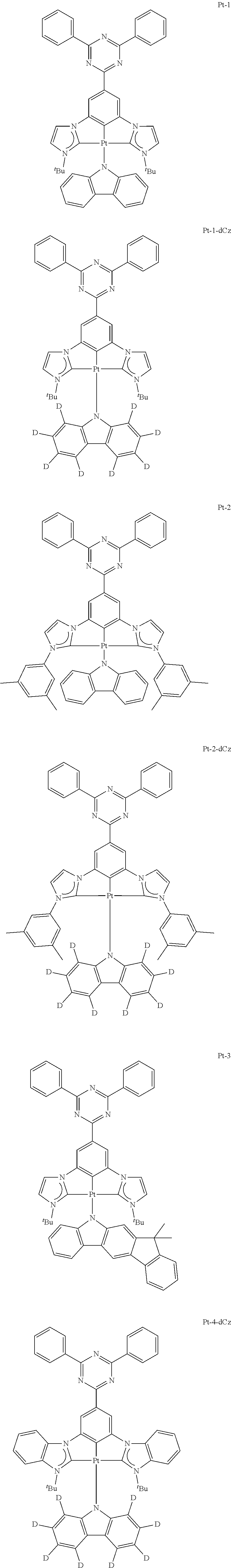

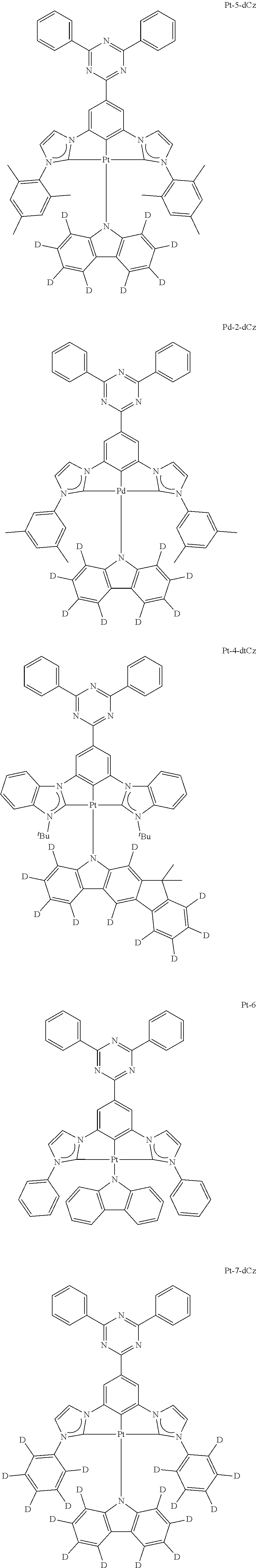

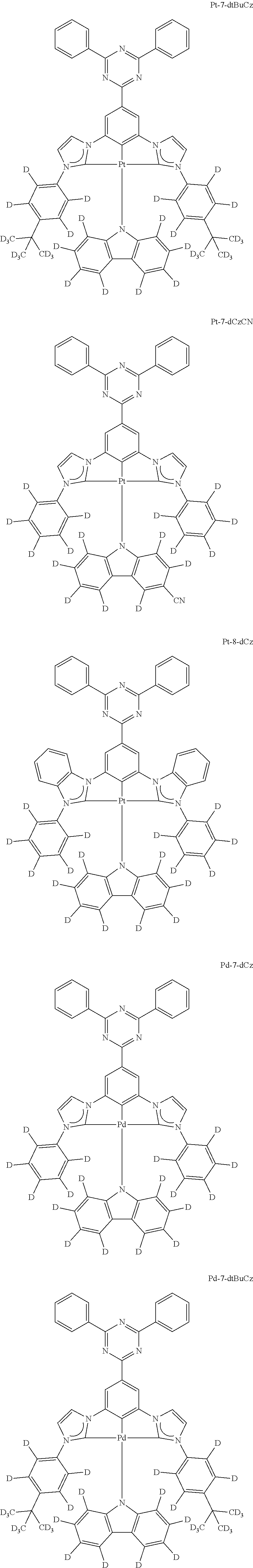

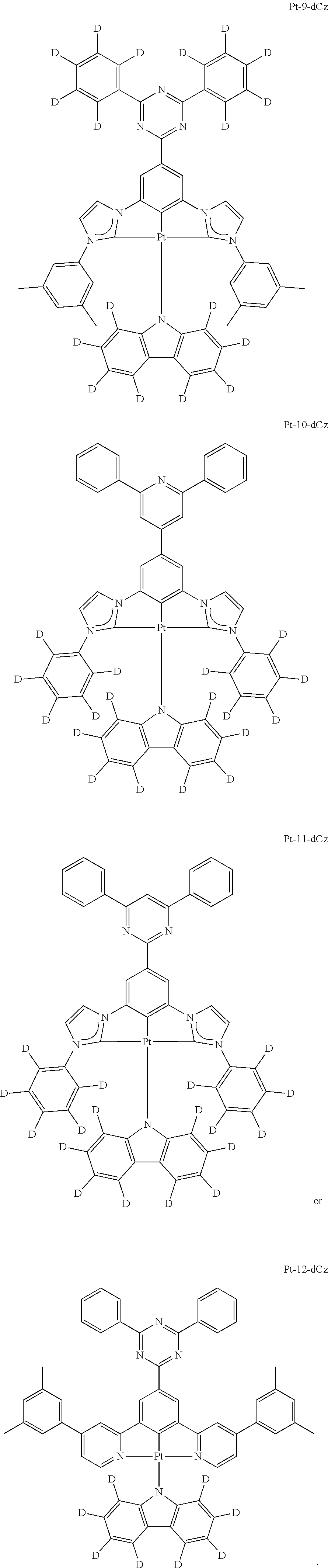

Exemplary Au complexes are presented below.

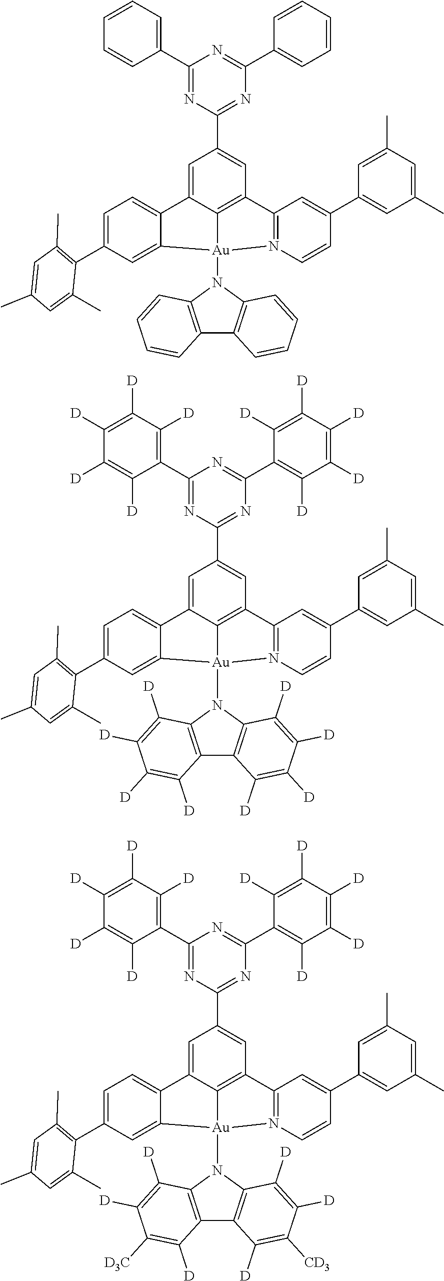

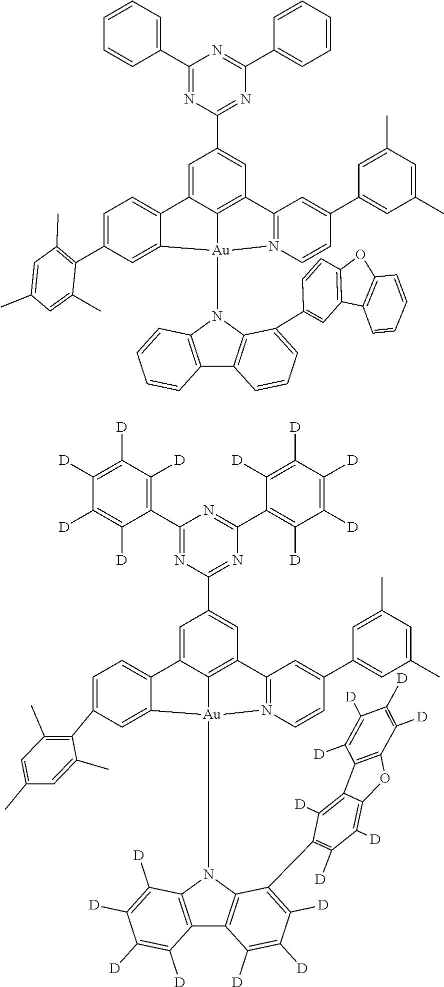

The metal complexes are strongly emissive in thin film, such as with an emission maxima at 562-650 nm, an emission quantum yield up to 89%, and/or an emission lifetime below 2.3 μs. The emission color of these metal complexes can be tuned by changing the metal ion, the wingtip of NHC moiety, and the amide ligand. For example, platinum(II) complexes can be strongly emissive in thin film with emission maxima at 562-624 nm, emission quantum yield up to 89%, and emission lifetime below 1.25 μs.

The metal complexes show high radiative decay rate constant (kᵣ). Without being bound to any theories, it is believed that the increased kᵣ is attributed to the through-bond charge transfer character of the donor-acceptor configuration of the metal complexes. For example, platinum(II) complexes can have a radiative decay rate constant of up to 1.6×10⁶ s⁻¹, which is significantly higher than the kᵣ values (about 2 to 5×10⁵ s⁻¹) of reported mononuclear platinum(II) emitters. Accordingly, the high radiative decay rate constant of the metal complexes can solve the problem of limited radiative decay rate constants of mononuclear platinum(II) emitters. For example, using the metal complexes disclosed herein, the OLED device degradation processes caused by long-lived triplet excited state can be avoided, leading to operationally stable OLEDs.

The metal complexes disclosed herein can be included in organic light-emitting devices, such as organic light-emitting diodes (“OLEDs”), resulting in high performance devices. For example, vapor-deposited OLEDs are fabricated with platinum/palladium(II) complexes to attain electroluminescence (EL) emission maxima of 554-637 nm and maximum EQE up to 30%, such as about 25.5%. For example, vapor-deposited OLEDs fabricated with the Pt(II) complexes can attain EL emission maxima of 541-599 nm and a maximum EQE up to 21.4%. Further, OLEDs fabricated using the metal complexes can exhibit long operational lifetime, such as an unprecedentedly operational lifetime with LT₉₅ of up to 7289 hours at 1000 cd m⁻². For example, vapor-deposited OLEDs fabricated with the Pt(II) complexes can exhibit an unprecedentedly long operational lifetime with LT₉₅ of up to 6660 hours at 1000 cd m⁻². In some forms, the operational lifetimes of OLEDs using metal complexes with deuterated ligands can further extend the operational lifetimes of the OLEDs by more than 4-fold, compared to OLEDs fabricated using Pt-1 and Pt-1-dCz.

### BRIEF DESCRIPTION OF THE DRAWINGS

FIG. 1A is a graph showing the emission spectra of Pt-1, Pt-1-dCz, Pt-2, Pt-2-dCz and Pt-3 in deaerated toluene. FIG. 1B is a graph showing the emission spectra of Pt-1, Pt-1-dCz, Pt-2, Pt-2-dCz and Pt-3 doped in PMMA (Poly(methyl methacrylate)) films at a concentration of 2 wt %.

FIG. 2 is a graph showing the emission spectrum of Pd-2-dCz in deaerated toluene.

FIG. 3A is a graph showing the emission spectra of Pt-4-dCz and Pt-5-dCz in deaerated toluene. FIG. 3B is a graph showing the emission spectrum of Pt-4-dCz doped in PMMA film at a concentration of 2 wt %. FIG. 3C is a graph showing the emission spectrum of Pt-5-dCz doped in mCP (1,3-bis(N-carbazolyl)benzene) film at a concentration of 2 wt %.

FIGS. 4A-4D are graphs showing the EL spectra (FIG. 4A) and performance characteristics of devices fabricated with Pt-1 with doping concentration of 4, 8, 12 and 16 wt %. The performance characteristics of these devices include EQE (FIG. 4B), luminance (FIG. 4C), and current density (FIG. 4D).

FIG. 5 is a graph showing the lifetime data of the device fabricated with Pt-1 with doping concentration of 4 wt %.

FIGS. 6A-6D are graphs showing the EL spectra (FIG. 6A) and performance characteristics of devices fabricated with Pt-1-dCz with doping concentration of 2, 4 and 8 wt %. The performance characteristics of these devices include EQE (FIG. 6B), luminance (FIG. 6C), and current density (FIG. 6D).

FIG. 7 is a graph showing the lifetime data of the device fabricated with Pt-1-dCz with doping concentration of 4 wt %.

FIGS. 8A-8D are graphs showing are graphs showing the EL spectra (FIG. 8A) and performance characteristics of devices fabricated with Pt-2-dCz with doping concentration of 2, 4 and 6 wt %. The performance characteristics of these devices include EQE (FIG. 8B), luminance (FIG. 8C), and current density (FIG. 8D).

FIGS. 9A-9D are graphs showing the EL spectra (FIG. 9A) and performance characteristics of devices fabricated with Pt-4-dCz with doping concentration of 2, 4, 6 and 8 wt %. The performance characteristics of these devices include EQE (FIG. 9B), luminance (FIG. 9C), and current density (FIG. 9D).

FIG. 10 is a graph showing the lifetime data of the device fabricated with Pt-4-dCz with doping concentration of 6 wt %.

FIGS. 11A-11D are graphs showing the EL spectra (FIG. 11A) and performance characteristics of devices fabricated with Pt-5-dCz with doping concentration of 2, 4, 6 and 8 wt %. The performance characteristics of these devices include EQE (FIG. 11B), luminance (FIG. 11C), and current density (FIG. 11D).

FIG. 12 is a graph showing the lifetime data of the device fabricated with Pt-5-dCz with doping concentration of 6 wt %.

FIGS. 13A-13D are graphs showing the EL spectra (FIG. 13A) and performance characteristics of devices fabricated with Pd-2-dCz with doping concentration of 1, 2 and 4 wt %. The performance characteristics of these devices include EQE (FIG. 13B), luminance (FIG. 13C), and current density (FIG. 13D).

FIG. 14 is a graph showing the lifetime data of the device fabricated with Pd-2-dCz with doping concentration of 1 wt %.

FIGS. 15A-15D are graphs showing the EL spectra (FIG. 15A) and performance characteristics of devices fabricated with Pd-2-dCz with doping concentration of 2 and 4 wt %. The performance characteristics of these devices include EQE (FIG. 15B), luminance (FIG. 15C), and current density (FIG. 15D).

FIG. 16 is a graph showing the lifetime data of the device fabricated with Pd-2-dCz with doping concentration of 4 wt %.

FIG. 17 shows a non-limiting example of an organic light-emitting diode device, 100, having a multilayer architecture.

FIGS. 18A-18B are graphs showing the emission spectra of Pt(II) complexes, Pt-4-dfCz, Pt-6, Pt-7-dCz, Pt-8-dCz and Pt-12-dCz in toluene (FIG. 18A) and in 2 wt % PMMA (FIG. 18B). FIG. 18C-18D are graphs showing the emission spectra of Pt(II) complexes, Pt-7-dCz, Pt-7-dtBuCz, Pt-7-dtCzCN, Pt-10-dCz and Pt-11-dCz in toluene (FIG. 18C) and Pt-7-dCz, Pt-7-dtBuCz, Pt-7-dCzCN, Pt-10-dCz and Pt-11-dCz in 2 wt % PMMA (FIG. 18D).

FIGS. 19A-19B are graphs showing the emission spectra of Pd(II) complexes Pd-7-dCz and Pd-7-dtBuCz in toluene (FIG. 19A) and in 2 wt % PMMA (FIG. 19B).

FIGS. 20A-20D are graphs showing the EL spectra (FIG. 20A) and performance characteristics of devices fabricated with Pt-6 with doping concentration of 2, 4, and 8 wt %. The performance characteristics of these devices include EQE (FIG. 20B), luminance (FIG. 20C), and current density (FIG. 20D).

FIGS. 21A-21D are graphs showing the EL spectra (FIG. 21A) and performance characteristics of devices fabricated with Pt-7-dCz with doping concentration of 2, 4, and 8 wt %. The performance characteristics of these devices include EQE (FIG. 21B), luminance (FIG. 21C), and current density (FIG. 21D).

FIGS. 22A-22D are graphs showing the EL spectra (FIG. 22A) and performance characteristics of devices fabricated with Pt-7-dCzCN with doping concentration of 2, 6, and 8 wt %. The performance characteristics of these devices include EQE (FIG. 22B), luminance (FIG. 22C), and current density (FIG. 22D).

FIG. 23 is a graph showing the lifetime data of the device fabricated with Pt-7-dCzCN with doping concentration of 8 wt %.

FIGS. 24A-24D are graphs showing the EL spectra (FIG. 24A) and performance characteristics of devices fabricated with Pt-7-dCz:BN green with doping concentration of 8 wt %:1 wt %, 8 wt %:0.5 wt %, and 0 wt %:1 wt % respectively. The performance characteristics of these devices include EQE (FIG. 42B), luminance (FIG. 24C), and current density (FIG. 24D).

FIG. 25A is a graph showing the lifetime data of the device fabricated with Pt-7-dCzCN:BN green with doping concentration of 8 wt %:0.5 wt % respectively. FIG. 25B is a graph showing the lifetime data of the device fabricated with Pt-7-dCzCN:BN green with doping concentration of 0 wt %:1 wt % respectively.

FIGS. 26A-26D are graphs showing the EL spectra (FIG. 26A) and performance characteristics of devices fabricated with Pt-9-dCz with doping concentration of 2, 4, and 6 wt %. The performance characteristics of these devices include EQE (FIG. 26B), luminance (FIG. 26C), and current density (FIG. 26D).

FIG. 27 is a graph showing the lifetime data of the device fabricated with Pt-9-dCz with doping concentration of 6 wt %.

FIGS. 28A-28D are graphs showing the EL spectra (FIG. 28A) and performance characteristics of devices fabricated with Pt-12-dCz with doping concentration of 2 wt %.

The performance characteristics of these devices include EQE (FIG. 28B), luminance (FIG. 28C), and current density (FIG. 28D).

FIGS. 29A-29D are graphs showing the EL spectra (FIG. 29A) and performance characteristics of devices fabricated with Pd-7-dCz with doping concentration of 2 and 4 wt %. The performance characteristics of these devices include EQE (FIG. 29B), luminance (FIG. 29C), and current density (FIG. 29D).

FIG. 30 is a graph showing the lifetime data of the device fabricated with Pd-7-dCz with doping concentration of 4 wt %.

FIG. 31A is a drawing of the structure of Pt-1-dCz. FIGS. 31B-31E are graphs showing the normalized temperature-dependent PL spectra (FIG. 31B), PL intensity decay curves (FIG. 31C) and emission lifetime plot (FIG. 31D) with the corresponding Arrhenius plot with linear fitting to the kinetic data (FIG. 31E) of Pt-1-dCz in 2 wt % PMMA film.

FIG. 32A is a drawing of the structure of Pt-2-dCz. FIGS. 32B-32E are graphs showing the normalized temperature-dependent PL spectra (FIG. 32B), PL intensity decay curves (FIG. 32C), and emission lifetime plot (FIG. 32D) with the corresponding Arrhenius plot with linear fitting to the kinetic data (FIG. 32E) of Pt-2-dCz in 2 wt % PMMA film.

FIG. 33A is a drawing of the structure of Pt-3. FIGS. 33B-33E are graphs showing the normalized temperature-dependent PL spectra (FIG. 33B), PL intensity decay curves (FIG. 33C), and emission lifetime plot (FIG. 33D) with the corresponding Arrhenius plot with linear fitting to the kinetic data (FIG. 33E) of Pt-3 in 2 wt % PMMA film.

FIG. 34A is a drawing of the structure of Pd-7-dCz. FIGS. 34B-34E are graphs showing the normalized temperature-dependent PL spectra (FIG. 34B), PL intensity decay curves (FIG. 34C) and emission lifetime plot (FIG. 34D) with the corresponding Arrhenius plot with linear fitting to the kinetic data (FIG. 34E) of Pd-7-dCz in 2 wt % PMMA film.

### DETAILED DESCRIPTION OF THE INVENTION

### I. Definitions

It is to be understood that the disclosed compounds, compositions, and methods are not limited to specific synthetic methods, specific analytical techniques, or to particular reagents unless otherwise specified, and, as such, may vary. It is also to be understood that the terminology used herein is for the purpose of describing particular forms and embodiments only and is not intended to be limiting.

“Substituted,” as used herein, refers to all permissible substituents of the compounds or functional groups described herein. In the broadest sense, the permissible substituents include acyclic and cyclic, branched and unbranched, carbocyclic and heterocyclic, aromatic and nonaromatic substituents of organic compounds. Illustrative substituents include, but are not limited to, halogens, hydroxyl groups, or any other organic groupings containing any number of carbon atoms, preferably 1-14 carbon atoms, and optionally include one or more heteroatoms such as oxygen, sulfur, or nitrogen grouping in linear, branched, or cyclic structural formats. Representative substituents include a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, an amino acid. Such a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, and an amino acid can be further substituted.

Heteroatoms such as nitrogen may have hydrogen substituents and/or any permissible substituents of organic compounds described herein which satisfy the valences of the heteroatoms. It is understood that “substitution” or “substituted” includes the implicit proviso that such substitution is in accordance with permitted valence of the substituted atom and the substituent, and that the substitution results in a stable compound, i.e., a compound that does not spontaneously undergo transformation such as by rearrangement, cyclization, elimination, etc.

“Alkyl,” as used herein, refers to the radical of saturated aliphatic groups, including straight-chain alkyl groups, branched-chain alkyl, and cycloalkyl (alicyclic). In some forms, a straight chain or branched chain alkyl has 30 or fewer carbon atoms in its backbone (e.g., C₁-C₃₀ for straight chains, C₃-C₃₀ for branched chains), 20 or fewer, 15 or fewer, or 10 or fewer. Alkyl includes methyl, ethyl, n-propyl, isopropyl, n-butyl, isobutyl, t-butyl, pentyl, hexyl, heptyl, octyl, decyl, tetradecyl, hexadecyl, eicosyl, tetracosyl and the like. Likewise, a cycloalkyl is a non-aromatic carbon-based ring composed of at least three carbon atoms, such as a nonaromatic monocyclic or nonaromatic polycyclic ring containing 3-30 carbon atoms, 3-20 carbon atoms, or 3-10 carbon atoms in their ring structure, and have 5, 6 or 7 carbons in the ring structure. Cycloalkyls containing a polycyclic ring system can have two or more non-aromatic rings in which two or more carbons are common to two adjoining rings (i.e., “fused cycloalkyl rings”). Examples of cycloalkyl groups include, but are not limited to, cyclopropyl, cyclobutyl, cyclopentyl, cyclohexyl, cycloheptyl, cyclooctanyl, etc.

“Substituted alkyl” refers to alkyl moieties having one or more substituents replacing a hydrogen on one or more carbons of the hydrocarbon backbone. Such substituents can be any substituents described above, e.g., halogen (such as fluorine, chlorine, bromine, or iodine), hydroxyl, carbonyl (such as a carboxyl, alkoxycarbonyl, formyl, or an acyl), thiocarbonyl (such as a thioester, a thioacetate, or a thioformate), aryl, alkoxyl, aralkyl, phosphonium, phosphanyl, phosphonyl, phosphoryl, phosphate, phosphonate, a phosphinate, amino, amido, amidine, imine, cyano, nitro, azido, oxo, sulfhydryl, thiol, alkylthio, silyl, sulfinyl, sulfate, sulfonate, sulfamoyl, sulfonamido, sulfonyl, heterocyclyl, an aromatic or heteroaromatic moiety. —NRR′, wherein R and R′ are independently hydrogen, alkyl, or aryl, and wherein the nitrogen atom is optionally quaternized; —SR, wherein R is a phosphonyl, a sulfinyl, a silyl a hydrogen, an alkyl, or an aryl; —CN; —NO₂; —COOH; carboxylate; —COR, —COOR, or —CON(R)₂, wherein R is hydrogen, alkyl, or aryl; imino, silyl, ether, haloalkyl (such as —CF3, —CH₂—CF₃, —CCl₃); —CN; —NCOCOCH₂CH₂; —NCOCOCHCH; and —NCS; and combinations thereof.

It will be understood by those skilled in the art that the moieties substituted on the hydrocarbon chain can themselves be substituted, if appropriate. For instance, the substituents of a substituted alkyl may include halogen, hydroxy, nitro, thiols, amino, aralkyl, azido, imino, amido, phosphonium, phosphanyl, phosphoryl (including phosphonate and phosphinate), oxo, sulfonyl (including sulfate, sulfonamido, sulfamoyl and sulfonate), and silyl groups, as well as ethers, alkylthios, carbonyls (including ketones, aldehydes, carboxylates, and esters), haloalkyls, —CN and the like. Cycloalkyls can be substituted in the same manner.

Unless the number of carbons is otherwise specified, “lower alkyl” as used herein means an alkyl group, as defined above, but having from one to ten carbons, more preferably from one to six carbon atoms in its backbone structure. Likewise, “lower alkenyl” and “lower alkynyl” have similar chain lengths.

“Heteroalkyl,” as used herein, refers to straight or branched chain, or cyclic carbon-containing alkyl radicals, or combinations thereof, containing at least one heteroatom on the carbon backbone. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkyl group” is a cycloalkyl group as defined above where at least one of the carbon atoms of the ring is substituted with a heteroatom such as, but not limited to, nitrogen, oxygen, sulphur, or phosphorus.

The term “alkenyl” as used herein is a hydrocarbon group of from 2 to 24 carbon atoms and structural formula containing at least one carbon-carbon double bond. Alkenyl groups include straight-chain alkenyl groups, branched-chain alkenyl, and cycloalkenyl. A cycloalkenyl is a non-aromatic carbon-based ring composed of at least three carbon atoms and at least one carbon-carbon double bond, such as a nonaromatic monocyclic or nonaromatic polycyclic ring containing 3-30 carbon atoms and at least one carbon-carbon double bond, 3-20 carbon atoms and at least one carbon-carbon double bond, or 3-10 carbon atoms and at least one carbon-carbon double bond in their ring structure, and have 5, 6 or 7 carbons and at least one carbon-carbon double bond in the ring structure. Cycloalkenyls containing a polycyclic ring system can have two or more non-aromatic rings in which two or more carbons are common to two adjoining rings (i.e., “fused cycloalkenyl rings”) and contain at least one carbon-carbon double bond. Asymmetric structures such as (AB)C=C(C′D) are intended to include both the E and Z isomers. This may be presumed in structural formulae herein wherein an asymmetric alkene is present, or it may be explicitly indicated by the bond symbol C. The term “alkenyl” as used throughout the specification, examples, and claims is intended to include both “unsubstituted alkenyls” and “substituted alkenyls,” the latter of which refers to alkenyl moieties having one or more substituents replacing a hydrogen on one or more carbons of the hydrocarbon backbone. The term “alkenyl” also includes “heteroalkenyl.”

The term “substituted alkenyl” refers to alkenyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, oxo, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

“Heteroalkenyl,” as used herein, refers to straight or branched chain, or cyclic carbon-containing alkenyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkenyl group” is a cycloalkenyl group where at least one of the carbon atoms of the ring is substituted with a heteroatom such as, but not limited to, nitrogen, oxygen, sulphur, or phosphorus.

The term “alkynyl group” as used herein is a hydrocarbon group of 2 to 24 carbon atoms and a structural formula containing at least one carbon-carbon triple bond. Alkynyl groups include straight-chain alkynyl groups, branched-chain alkynyl, and cycloalkynyl. A cycloalkynyl is a non-aromatic carbon-based ring composed of at least three carbon atoms and at least one carbon-carbon triple bond, such as a nonaromatic monocyclic or nonaromatic polycyclic ring containing 3-30 carbon atoms and at least one carbon-carbon triple bond, 3-20 carbon atoms and at least one carbon-carbon triple bond, or 3-10 carbon atoms and at least one carbon-carbon triple bond in their ring structure, and have 5, 6 or 7 carbons and at least one carbon-carbon triple bond in the ring structure. Cycloalkynyls containing a polycyclic ring system can have two or more non-aromatic rings in which two or more carbons are common to two adjoining rings (i.e., “fused cycloalkynyl rings”) and contain at least one carbon-carbon triple bond. Asymmetric structures such as (AB)C≡C(C″D) are intended to include both the E and Z isomers. This may be presumed in structural formulae herein wherein an asymmetric alkyne is present, or it may be explicitly indicated by the bond symbol C. The term “alkynyl” as used throughout the specification, examples, and claims is intended to include both “unsubstituted alkynyls” and “substituted alkynyls,” the latter of which refers to alkynyl moieties having one or more substituents replacing a hydrogen on one or more carbons of the hydrocarbon backbone. The term “alkynyl” also includes “heteroalkynyl.”

The term “substituted alkynyl” refers to alkynyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

“Heteroalkynyl,” as used herein, refers to straight or branched chain, or cyclic carbon-containing alkynyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkynyl group” is a cycloalkynyl group where at least one of the carbon atoms of the ring is substituted with a heteroatom such as, but not limited to, nitrogen, oxygen, sulphur, or phosphorus.

“Aryl,” as used herein, refers to C₄-C₂₆-membered aromatic rings or fused ring systems containing one aromatic ring and optionally one or more non-aromatic rings. Examples of aryl groups are benzene, tetralin, indane, etc.

The term “substituted aryl” refers to an aryl group, wherein one or more hydrogen atoms on one or more aromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), —CN, aryl, heteroaryl, and combinations thereof.

“Heterocyclo” and “heterocyclyl” are used interchangeably, and refer to a cyclic radical attached via a ring carbon or nitrogen atom of a monocyclic ring or polycyclic ring system containing 3-30 ring atoms, 3-20 ring atoms, 3-10 ring atoms, or 5-6 ring atoms, where the polycyclic ring system contains one or more non-aromatic rings and optionally one or more aromatic rings, where at least one non-aromatic ring contains carbon and one to four heteroatoms each selected from the group consisting of non-peroxide oxygen, sulfur, and N(Y) wherein Y is absent or is H, O, C₁-C₁₀ alkyl, phenyl or benzyl, and optionally containing 1-3 double bonds and optionally substituted with one or more substituents. Heterocyclyl are distinguished from heteroaryl by definition. Heterocycles can be a heterocycloalkyl, a heterocycloalkenyl, a heterocycloalkynyl, etc., such as piperazinyl, piperidinyl, piperidonyl, 4-piperidonyl, dihydrofuro[2,3-b]tetrahydrofuran, morpholinyl, piperazinyl, piperidinyl, piperidonyl, 4-piperidonyl, piperonyl, pyranyl, 2H-pyrrolyl, 4H-quinolizinyl, quinuclidinyl, tetrahydrofuranyl, 6H-1,2,5-thiadiazinyl. Heterocyclic groups can optionally be substituted with one or more substituents as defined above for alkyl and aryl.

The term “heteroaryl” refers to C₃-C₂₆-membered aromatic rings or fused ring systems containing one aromatic ring and optionally one or more non-aromatic rings, in which one or more carbon atoms on the aromatic ring structure have been substituted with a heteroatom. Suitable heteroatoms include, but are not limited to, oxygen, sulfur, and nitrogen. Examples of heteroaryl groups pyrrole, furan, thiophene, imidazole, oxazole, thiazole, triazole, tetrazole, pyrazole, pyridine, pyrazine, pyridazine and pyrimidine, and the like. Examples of heteroaryl rings include, but are not limited to, benzimidazolyl, benzofuranyl, benzothiofuranyl, benzothiophenyl, benzoxazolyl, benzoxazolinyl, benzthiazolyl, benztriazolyl, benztetrazolyl, benzisoxazolyl, benzisothiazolyl, benzimidazolinyl, carbazolyl, 4aH-carbazolyl, carbolinyl, chromanyl, chromenyl, cinnolinyl, decahydroquinolinyl, 2H,6H-1,5,2-dithiazinyl, furanyl, furazanyl, imidazolidinyl, imidazolinyl, imidazolyl, 1H-indazolyl, indolenyl, indolinyl, indolizinyl, indolyl, 3H-indolyl, isatinoyl, isobenzofuranyl, isochromanyl, isoindazolyl, isoindolinyl, isoindolyl, isoquinolinyl, isothiazolyl, isoxazolyl, methylenedioxyphenyl, naphthyridinyl, octahydroisoquinolinyl, 1,2,3-oxadiazolyl, 1,2,4-oxadiazolyl, 1,2,5-oxadiazolyl, 1,3,4-oxadiazolyl, oxazolidinyl, oxazolyl, oxindolyl, pyrimidinyl, phenanthridinyl, phenanthrolinyl, phenazinyl, phenothiazinyl, phenoxathinyl, phenoxazinyl, phthalazinyl, pteridinyl, purinyl, pyrazinyl, pyrazolidinyl, pyrazolinyl, pyrazolyl, pyridazinyl, pyridooxazole, pyridoimidazole, pyridothiazole, pyridinyl, pyridyl, pyrimidinyl, pyrrolidinyl, pyrrolinyl, pyrrolyl, quinazolinyl, quinolinyl, quinoxalinyl, tetrahydroisoquinolinyl, tetrahydroquinolinyl, tetrazolyl, 1,2,3-thiadiazolyl, 1,2,4-thiadiazolyl, 1,2,5-thiadiazolyl, 1,3,4-thiadiazolyl, thianthrenyl, thiazolyl, thienyl, thienothiazolyl, thienooxazolyl, thienoimidazolyl, thiophenyl and xanthenyl. One or more of the rings can be substituted as defined below for “substituted heteroaryl.”

The term “substituted heteroaryl” refers to a heteroaryl group in which one or more hydrogen atoms on one or more heteroaromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), —CN, aryl, heteroaryl, and combinations thereof.

The term “polyaryl” refers to a fused ring system that includes two or more aromatic rings and optionally one or more non-aromatic rings. Examples of polyaryl groups are naphthalene, anthracene, phenanthrene, chrysene, pyrene, corannulene, coronene, etc. When a fused ring system containing two or more aromatic rings and optionally one or more non-aromatic rings, in which one or more carbon atoms on two or more aromatic ring structures have been substituted with a heteroatom, the fused ring system can be referred to as a “polyheteroaryl”. When a fused ring system containing two or more aromatic rings and optionally one or more non-aromatic rings, in which one or more carbon atoms in the fused ring system is substituted with a heteroatom it can be referred to as a “heteropolyaryl.”

The term “substituted polyaryl” refers to a polyaryl in which one or more of the aryls are substituted, with one or more substituents including, but not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfoxide, sulfonamido, sulfonyl, heterocyclyl, alkylaryl, haloalkyl, —CN, aryl, heteroaryl, and combinations thereof. When a polyheteroaryl is involved, the chemical moiety can be referred to as a “substituted polyheteroaryl.”

The term “cyclic ring” or “cyclic group” refers to a substituted or unsubstituted monocyclic ring or a substituted or unsubstituted polycyclic ring (such as those formed from single or fused ring systems), such as a substituted or unsubstituted cycloalkyl, a substituted or unsubstituted cycloalkenyl, a substituted or unsubstituted cycloalkynyl, or a substituted or unsubstituted heterocyclyl, that have from three to 30 carbon atoms, as geometric constraints permit. The substituted cycloalkyls, cycloalkenyls, cycloalkynyls, and heterocyclyls are substituted as defined above for the alkyls, alkenyls, alkynyls, and heterocyclyls, respectively.

The term “aralkyl” as used herein is an aryl group or a heteroaryl group having an alkyl, alkynyl, or alkenyl group as defined above attached to the aromatic group, such as an aryl, a heteroaryl, a polyaryl, or a polyheteroaryl. An example of an aralkyl group is a benzyl group.

The terms “alkoxyl” or “alkoxy,” “aroxy” or “aryloxy,” generally describe compounds represented by the formula —OR, wherein RV includes, but is not limited to, a substituted or unsubstituted alkyl, a substituted or unsubstituted alkenyl, a substituted or unsubstituted alkynyl, a substituted or unsubstituted cycloalkyl, a substituted or unsubstituted heterocyclyl, a substituted or unsubstituted cycloalkenyl, a substituted or unsubstituted heterocycloalkenyl, a substituted or unsubstituted aryl, a substituted or unsubstituted heteroaryl, a substituted or unsubstituted polyaryl, a substituted or unsubstituted polyheteroaryl, a substituted or unsubstituted arylalkyl, a substituted or unsubstituted heteroalkyl, a substituted or unsubstituted alkylaryl, a substituted or unsubstituted alkylheteroaryl, a substituted or unsubstituted aralkyl, a substituted or unsubstituted carbonyl, a phosphonium, a phosphanyl, a phosphonyl, a sulfinyl, a silyl, a thiol, an amido, and an amino. Exemplary alkoxyl groups include methoxy, ethoxy, propyloxy, tert-butoxy and the like. A “lower alkoxy” group is an alkoxy group containing from one to six carbon atoms. An “ether” is two functional groups covalently linked by an oxygen as defined below. Accordingly, the substituent of an alkyl that renders that alkyl an ether is or resembles an alkoxyl, such as can be represented by one of —O-alkyl, —O-alkenyl, —O-alkynyl, —O— arakyl, —O-aryl, —O-heteroaryl, —O-polyaryl, —O-polyheteroaryl, —O-heterocyclyl, etc.

The term “substituted alkoxy” refers to an alkoxy group having one or more substituents replacing one or more hydrogen atoms on one or more carbons of the alkoxy backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, oxo, sulfate, sulfonate, sulfamoyl, sulfonamido, sulfonyl, heterocyclyl, alkylaryl, haloalkyl, —CN, aryl, heteroaryl, and combinations thereof.

The term “ether” as used herein is represented by the formula A²OA¹, where A² and A¹ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a phosphonyl, a sulfinyl, a silyl, a thiol, a substituted or unsubstituted carbonyl, an alkoxy, an amido, or an amino, described above.

The term “polyether” as used herein is represented by the formula:

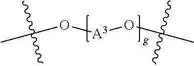

where A³ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a substituted or unsubstituted carbonyl, an alkoxy, an amido, or an amino, described above; g can be a positive integer from 1 to 30.

The term “phenoxy” is art recognized and refers to a compound of the formula —OR wherein R^{v} is C₆H₅ (i.e., —O—C₆H₅). One of skill in the art recognizes that a phenoxy is a species of the aroxy genus.

The term “substituted phenoxy” refers to a phenoxy group, as defined above, having one or more substituents replacing one or more hydrogen atoms on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “aroxy” and “aryloxy,” as used interchangeably herein, are represented by —O-aryl or —O-heteroaryl, wherein aryl and heteroaryl are as defined herein.

The terms “substituted aroxy” and “substituted aryloxy,” as used interchangeably herein, represent —O-aryl or —O-heteroaryl, having one or more substituents replacing one or more hydrogen atoms on one or more ring atoms of the aryl and heteroaryl, as defined herein. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The term “amino” as used herein includes the group

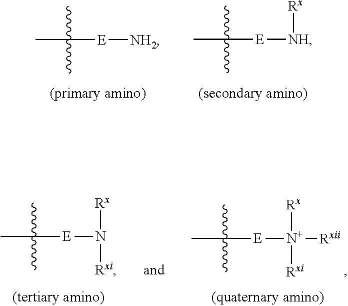

wherein, E is absent, or E is substituted or unsubstituted alkyl, substituted or unsubstituted alkenyl, substituted or unsubstituted alkynyl, substituted or unsubstituted aralkyl, substituted or unsubstituted aryl, substituted or unsubstituted heteroaryl, a substituted or unsubstituted polyaryl, a substituted or unsubstituted polyheteroaryl, substituted or unsubstituted heterocyclyl, wherein independently of E, R^{x}, R^{xi}, and R^{xii} each independently represent a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. The term “quaternary amino” also includes the groups where the nitrogen, R^{x}, R^{xi}, and R^{xii} with the N⁺ to which they are attached complete a heterocyclyl or heteroaryl having from 3 to 14 atoms in the ring structure. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The terms “amide” or “amido” are used interchangeably, refer to both “unsubstituted amido” and “substituted amido” and are represented by the general formula:

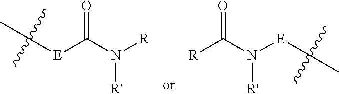

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted aryl, substituted or unsubstituted heteroaryl, a substituted or unsubstituted polyaryl, a substituted or unsubstituted polyheteroaryl, or a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. In some forms, when E is oxygen, a carbamate is formed. It is understood by those of ordinary skill in the art, that the E groups listed above are divalent (e.g., methylene, ethane-1,2-diyl, ethene-1,2-diyl, 1,4-phenylene, cyclohexane-1,2-diyl).

“Carbonyl,” as used herein, is art-recognized and includes such moieties as can be represented by the general formula:

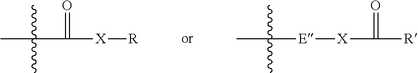

wherein X is a bond, or represents an oxygen or a sulfur, and R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″, or a pharmaceutical acceptable salt; E″ is absent, or E″ is a substituted or unsubstituted alkyl, a substituted or unsubstituted alkenyl, a substituted or unsubstituted alkynyl, a substituted or unsubstituted aralkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl; R′ represents a hydrogen, a substituted or unsubstituted alkyl, a substituted or unsubstituted alkenyl, a substituted or unsubstituted alkynyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″; R″ represents a hydroxyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof. It is understood by those of ordinary skill in the art, that the E″ groups listed above are divalent (e.g., methylene, ethane-1,2-diyl, ethene-1,2-diyl, 1,4-phenylene, cyclohexane-1,2-diyl). Where X is oxygen and R is defined as above, the moiety is also referred to as a carboxyl group. When X is oxygen and R is hydrogen, the formula represents a “carboxylic acid.” Where X is oxygen and R′ is hydrogen, the formula represents a “formate.” Where X is oxygen and R or R′ is not hydrogen, the formula represents an “ester.” In general, where the oxygen atom of the above formula is replaced by a sulfur atom, the formula represents a “thiocarbonyl” group. Where X is sulfur and R or R′ is not hydrogen, the formula represents a “thioester.” Where X is sulfur and R is hydrogen, the formula represents a “thiocarboxylic acid.” Where X is sulfur and R′ is hydrogen, the formula represents a “thioformate.” Where X is a bond and R is not hydrogen, the above formula represents a “ketone.” Where X is a bond and R is hydrogen, the above formula represents an “aldehyde.”

The term “phosphanyl” is represented by the formula

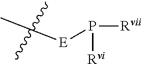

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi} and R^{vii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonium” is represented by the formula

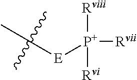

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi}, R^{vii}, and R^{viii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi}, R^{vii}, and R^{viii} taken together with the P⁺ atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonyl” is represented by the formula

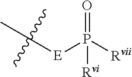

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, oxygen, alkoxy, aroxy, or substituted alkoxy or substituted aroxy, wherein, independently of E, R^{vi} and R^{vii} are independently a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphoryl” defines a phosphonyl in which E is absent, oxygen, alkoxy, aroxy, substituted alkoxy or substituted aroxy, as defined above, and independently of E, R^{vi} and R^{vii} are independently hydroxyl, alkoxy, aroxy, substituted alkoxy or substituted aroxy, as defined above. When E is oxygen, the phosphoryl cannot be attached to another chemical species, such as to form an oxygen-oxygen bond, or other unstable bonds, as understood by one of ordinary skill in the art. When E, R^{vi} and R^{vii} are substituted, the substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfinyl” is represented by the formula

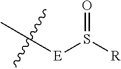

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a silyl, a thiol, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonyl” is represented by the formula

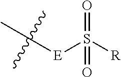

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonic acid” refers to a sulfonyl, as defined above, wherein R is hydroxyl, and E is absent, or E is substituted or unsubstituted cycloalkyl, substituted or unsubstituted heterocyclyl, substituted or unsubstituted alkylaryl, substituted or unsubstituted arylalkyl, substituted or unsubstituted aryl, a substituted or unsubstituted polyaryl, a substituted or unsubstituted polyheteroaryl, or substituted or unsubstituted heteroaryl. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfate” refers to a sulfonyl, as defined above, wherein E is absent, oxygen, alkoxy, aroxy, substituted alkoxy or substituted aroxy, as defined above, and R is independently hydroxyl, alkoxy, aroxy, substituted alkoxy or substituted aroxy, as defined above. When E is oxygen, the sulfate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonate” refers to a sulfonyl, as defined above, wherein E is oxygen, alkoxy, aroxy, substituted alkoxy or substituted aroxy, as defined above, and R is independently hydrogen, substituted or unsubstituted alkyl, substituted or unsubstituted alkenyl, substituted or unsubstituted alkynyl, substituted or unsubstituted amino, substituted or unsubstituted cycloalkyl, substituted or unsubstituted heterocyclyl, substituted or unsubstituted aralkyl, substituted or unsubstituted alkylaryl, substituted or unsubstituted arylalkyl, substituted or unsubstituted aryl, substituted or unsubstituted heteroaryl, a substituted or unsubstituted polyaryl, a substituted or unsubstituted polyheteroaryl, —(CH₂)ₘ—R′″, R′″ represents a hydroxy group, substituted or unsubstituted carbonyl group, an aryl, a cycloalkyl ring, a cycloalkenyl ring, a heterocycle, an amido, an amino, or a polycycle; and m is zero or an integer ranging from 1 to 8. When E is oxygen, sulfonate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfamoyl” refers to a sulfonamide or sulfonamide represented by the formula

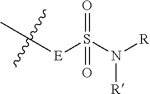

wherein E is absent, or E is substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted cycloalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “silyl group” as used herein is represented by the formula —SiRR′R,″ where R, R′, and R″ can be, independently, a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, a phosphonyl, a sulfinyl, a thiol, an amido, an amino, an alkoxy, or an oxo, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The terms “thiol” are used interchangeably and are represented by —SR, where R can be a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, an amido, an amino, an alkoxy, an oxo, a phosphonyl, a sulfinyl, or a silyl, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted, independently, with the substituents described above in the definition of “substituted.”

The numerical ranges disclose individually each possible number that such a range could reasonably encompass, as well as any sub-ranges and combinations of sub-ranges encompassed therein. For example, in a given range carbon range of C₃-C₉, the range also discloses C₃, C₄, C₅, C₆, C₇, C₈, and C₉, as well as any subrange between these numbers (for example, C₄-C₆), and any possible combination of ranges possible between these values. In yet another example, a given temperature range may be from about 25° C. to 30° C., where the range also discloses temperatures that can be selected independently from about 25, 26, 27, 28, 29, and 30° C., as well as any range between these numbers (for example, 26 to 28° C.), and any possible combination of ranges between these values.

Use of the term “about” is intended to describe values either above or below the stated value, which the term “about” modifies, to be within a range of approximately +/−10%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted with, independently, with the substituents described above in the definition of “substituted.”
“oxo” refers to ═O.

The compounds and substituents can be substituted, independently, with the substituents described above in the definition of “substituted.”

Numerical ranges such as ranges of C₁-C₃₀, C₄-C₃₀, C₃-C₃₀, C₁-C₂₀, C₄-C₂₀, C₃-C₂₀, C₁-C₁₀, C₄-C₁₀, C₃-C₁₀, C₁-C₆, C₄-C₆, C₃-C₆, C₁-C₄, C₃-C₄, C₁-C₉, C₁-C₈, C₁-C₇, C₁-C₅, C₁-C₃, C₁-C₂, C₃-C₉, C₃-C₉, C₃-C₈, C₃-C₇, C₃-C₅, C₃-C₄, C₄-C₂₅, C₄-C₂₀, C₄-C₁₈, C₄-C₁₆, C₄-C₁₅, C₄-C₁₄, C₄-C₁₃, C₄-C₁₂, C₄-C₉, C₄-C₈, C₄-C₇, C₄-C₅, etc. The ranges disclose individually each possible number that such a range could reasonably encompass, as well as any sub-ranges and combinations of sub-ranges encompassed therein. For example, in a given range carbon range of C₃-C₉, the range also discloses C₃, C₄, C₅, C₆, C₇, C₈, and C₉, as well as any subrange between these numbers (for example, C₄-C₆), and any possible combination of ranges possible between these values. In yet another example, a given temperature range may be from about 25° C. to 30° C., where the range also discloses temperatures that can be selected independently from about 25, 26, 27, 28, 29, and 30° C., as well as any range between these numbers (for example, 26 to 28° C.), and any possible combination of ranges between these values.

Use of the term “about” is intended to describe values either above or below the stated value, which the term “about” modifies, to be within a range of approximately +/−10%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

### II. Compositions

Disclosed are metal amide complexes (also referred to herein as “metal complexes”) that are efficient light emitters. In some forms, the metal complexes contain a C_{NHC}\hat{ }C\hat{ }C_{NHC} (NHC=N-heterocyclic carbene) pincer ligand, and feature a through-bond donor-acceptor configuration. The donor (e.g., the amide group) is coordinated to the metal ion, while the acceptor (e.g., 2,4,6-triphenyl-1,3,5-triazine and its derivatives) is incorporated to the pincer ligand and located at the para-position of carbanion. In some forms, the incorporation of an acceptor (e.g., 2,4,6-triphenyl-1,3,5-triazine and its derivatives) can be applied to pincer ligands N\hat{ }C\hat{ }N and/or C\hat{ }C\hat{ }N, in which the C_{NHC} donors of C_{NHC}\hat{ }C\hat{ }C_{NHC} ligand can be replaced with neutral N-donor(s) and/or a carbanion in the metal complexes.

The molecular design of the metal complexes introduces ligand (e.g., the amide group) to ligand (e.g., 2,4,6-triphenyl-1,3,5-triazine and its derivatives) charge transfer (LL′CT) character to the excited states of the metal complexes. This is different from the molecular design employed by Li et al. (CN116675718A) that uses platinum/palladium amide complexes with the acceptor group covalently bonded to the amide group and the acceptor group faces the pincer metal complex, resulting in metal-perturbed intraligand charge transfer (MPICT) excited state. The design of the metal complexes disclosed herein can improve the photophysical properties of these metal complexes (d8 metal amide complexes (Pt(II), Pd(II), Au(III)) with N\hat{ }C\hat{ }N and/or C\hat{ }C\hat{ }N ligands), such as shortened emission lifetime and/or increased radiative decay rate constant, and thereby improving their device performance in OLED devices.

### A. Metal Complexes

In some forms, the metal complexes can have the structure of Formula I:

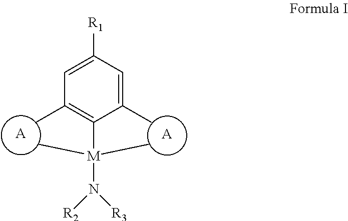

wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) R₁ can be

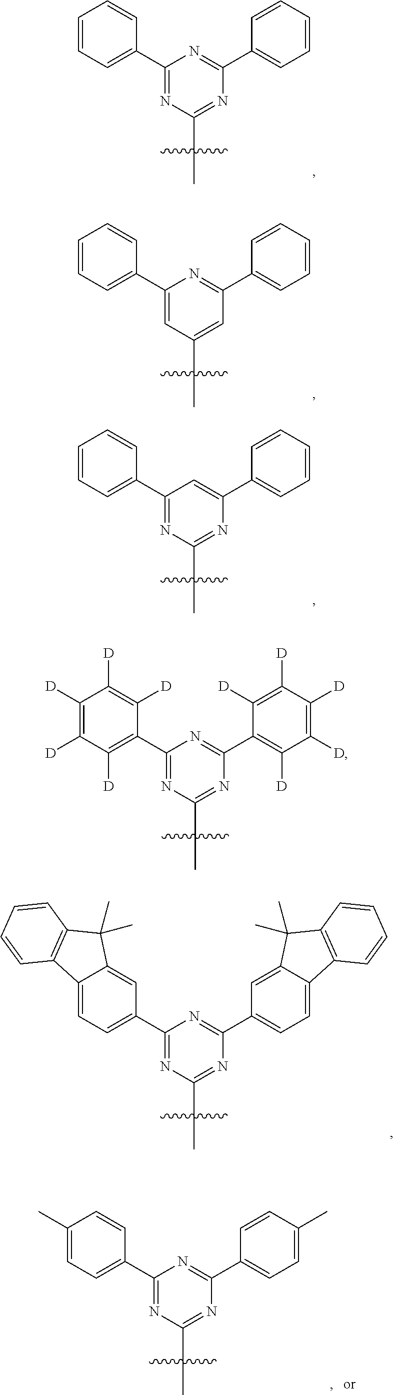

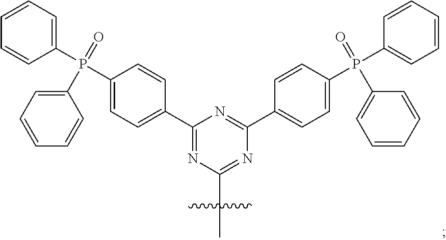 [SMILES: *c1nc(-c2ccc(P(=O)(c3ccccc3)c3ccccc3)cc2)nc(-c2ccc(P(=O)(c3ccccc3)c3ccccc3)cc2)n1]

(iv) R₂ and R₃ can be independently a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or R₂ and R₃ together with the nitrogen atom to which they are attached can form a fused ring system; and (v) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

In some forms, the metal complexes can have the structure of Formula I, wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) R₁ can be

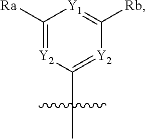

wherein (a) Rₐ and R_{b} each can independently be a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, and (b) Y₁, Y₂, and Y₃ can be independently a carbon or a nitrogen; and (iv) R₂ and R₃ can be independently a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or R₂ and R₃ together with the nitrogen atom to which they are attached can form a fused ring system; and (v) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

In some forms, Rₐ and R_{b} can be independently,

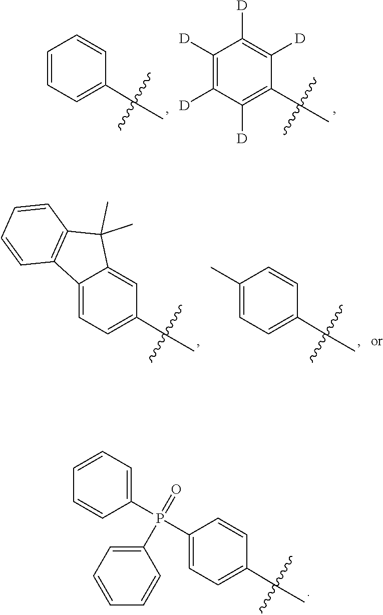

In some forms, R₁ can be

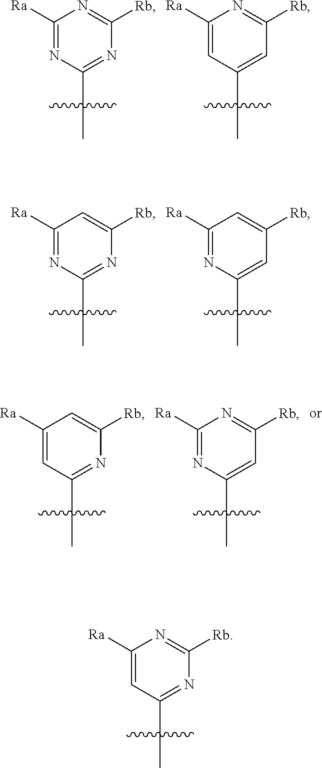

In some forms, R₂ and R₃ can be independently a substituted alkyl, an unsubstituted alkyl, a substituted aryl (e.g., a substituted phenyl), or an unsubstituted aryl (e.g., an unsubstituted phenyl). In some forms, R₂ and R₃ can be independently an unsubstituted alkyl or an unsubstituted phenyl.

When R₂ and R₃ together with the nitrogen atom to which they are attached can form a fused ring system, the fused ring system can contain aromatic rings, non-aromatic rings, or a combination thereof, such as a polyaryl, an heteropolyaryl, a polyheteroaryl, a fused cycloalkyl, a fused cycloalkenyl, a fused cycloalkynyl, etc.

In some forms, the metal complexes can have the structure of Formula II:

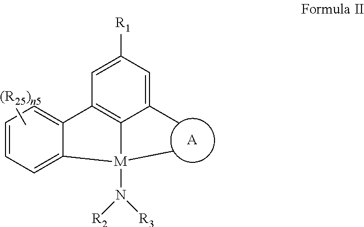

wherein: M, \textcircled{A}, R₂, and R₃ can be as defined above for Formula I; n5 can be an integer from 0 to 4, from 0 to 3, from 0 to 2, or 0 or 1; each occurrence of R₂₅ can be independently hydrogen, deuterium, an unsubstituted C₁-C₆ alkyl,

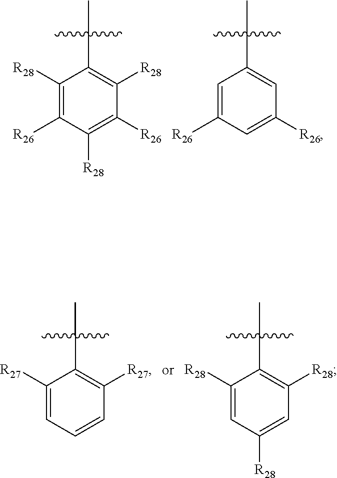

and each R₂₆, R₂₇, and R₂₈ can be independently hydrogen, deuterium, an unsubstituted C₁-C₁₂ alkyl, or an unsubstituted phenyl. In some forms, each R₂₅ can be independently an unsubstituted C₁-C₆ alkyl,

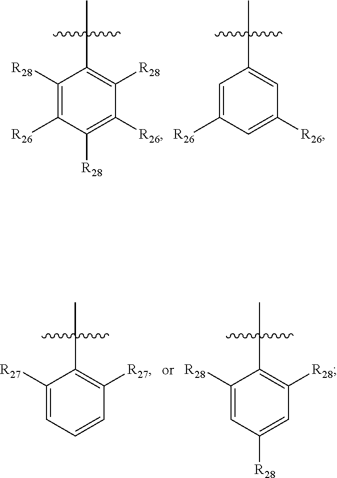

and each R₂₆, R₂₇, and R₂₈ can be independently hydrogen, deuterium, or an unsubstituted C₁-C₁₂ alkyl.

In some forms, R₁ can be

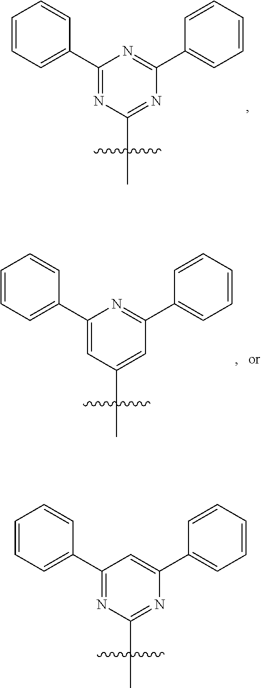 [SMILES: *c1nc(-c2ccccc2)nc(-c2ccccc2)n1 ; *c1cc(-c2ccccc2)nc(-c2ccccc2)c1 ; *c1nc(-c2ccccc2)cc(-c2ccccc2)n1]

In some forms, the metal complexes can have the structure of Formula III:

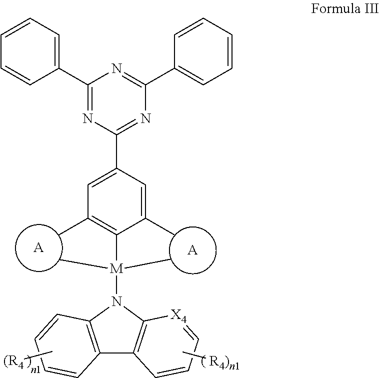

wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) X₄ can be C or N; (iv) each n1 can be independently an integer from 0 to 4, from 0 to 3, from 0 to 2, or 0 or 1; (v) each occurrence of R₄ can be independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or two neighboring R₄ together with the carbon atom (and/or nitrogen atom when X₄ is nitrogen) to which they are attached form a fused ring system; (vi) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

When two neighboring R₄ together with the carbon atom (and/or nitrogen atom when X₄ is nitrogen) to which they are attached form a fused ring system, the fused ring system can contain aromatic rings, non-aromatic rings, or a combination thereof, such as a polyaryl, an heteropolyaryl, a polyheteroaryl, a fused cycloalkyl, a fused cycloalkenyl, a fused cycloalkynyl, etc. For example, two neighboring R₄ together is

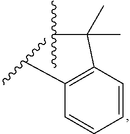 [SMILES: *c1ccccc1C(*)(C)C]

which can form a polyaryl together with the carbon atoms to which it attaches.

In some forms, R₄ can be hydrogen, deuterium, an unsubstituted alkyl (which can be a regular alkyl having hydrogen atoms, such as a regular methyl —CH₃, or a deuterium alkyl with one or more deuterium instead of hydrogen, such as a deuterium methyl —CD₃), an unsubstituted phenyl, a phenyl substituted with unsubstituted alkyl and/or unsubstituted phenyl (such a

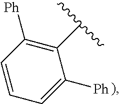 [SMILES: *c1c(-c2ccccc2)cccc1-c1ccccc1]

or an unsubstituted heteropolyaryl (such as

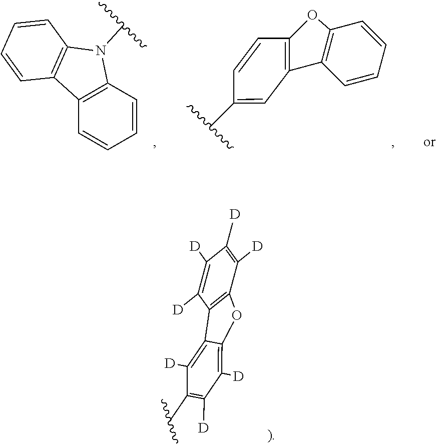 [SMILES: *n1c2ccccc2c2ccccc21 ; *c1ccc2oc3ccccc3c2c1 ; *c1c([2H])c([2H])c2oc3c([2H])c([2H])c([2H])c([2H])c3c2c1[2H]]

In some forms, R₄ can be hydrogen.

In some forms, the metal complexes can have the structure of Formula IV:

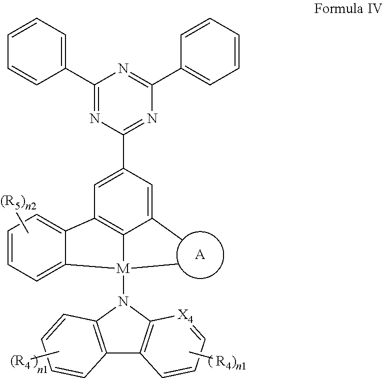

wherein: M, \textcircled{A}, X₄, n1, and R₄ can be as defined above for Formula III; n2 can be an integer from 0 to 4, from 0 to 3, from 0 to 2, or 0 or 1; each occurrence of R₅ can be independently hydrogen, deuterium, an unsubstituted C₁-C₆ alkyl,

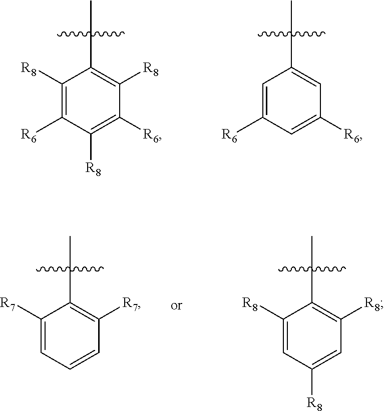

and each R₆, R₇, and R₈ can be independently hydrogen, deuterium, an unsubstituted C₁-C₁₂ alkyl, or an unsubstituted phenyl. In some forms, each R₅ can be independently an unsubstituted C₁-C₆ alkyl,

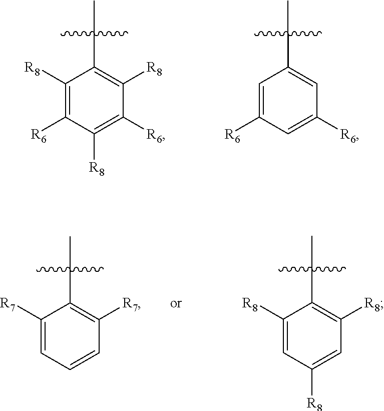

and each R₆, R₇, and R₈ can be independently hydrogen, deuterium, or an unsubstituted C₁-C₁₂ alkyl.

In some forms, the metal complexes can have the structure of Formula V:

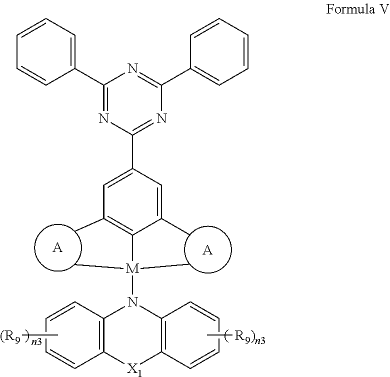

wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) each n3 can be independently an integer from 0 to 4, from 0 to 3, from 0 to 2, or 0 or 1; (iv) each occurrence of R₉ can be independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or two neighboring R₉ together with the carbon atom to which they are attached form a fused ring system; (v) X₁ can be —CR₁₀R₁₁, —C═R₁₂, O, S, or Se; (vi) R₁₀ and R₁₁ can be independently hydrogen, deuterium, a substituted alkyl, an unsubstituted alkyl, a substituted aryl (e.g., a substituted phenyl), an unsubstituted aryl (e.g., an unsubstituted phenyl), or a substituted heteroaryl; (vii) R₁₂ can be O, S or Se; and (viii) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

In some forms, each R₉ can be independently hydrogen, an unsubstituted alkyl, or an unsubstituted phenyl. In some forms, each R₉ can be independently hydrogen.

When two neighboring R₉ together with the carbon atom (and/or nitrogen atom when X₄ is nitrogen) to which they are attached form a fused ring system, the fused ring system can contain aromatic rings, non-aromatic rings, or a combination thereof, such as a polyaryl, an heteropolyaryl, a polyheteroaryl, a fused cycloalkyl, a fused cycloalkenyl, a fused cycloalkynyl, etc. For example, two neighboring R₉ together is

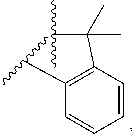 [SMILES: *c1ccccc1C(*)(C)C]

which can form a polyaryl together with the carbon atoms to which it attaches.

In some forms, R₁₀ and R₁₁ can be independently hydrogen, an unsubstituted alkyl, or an unsubstituted phenyl.

In some forms, the metal complexes can have the structure of Formula VI:

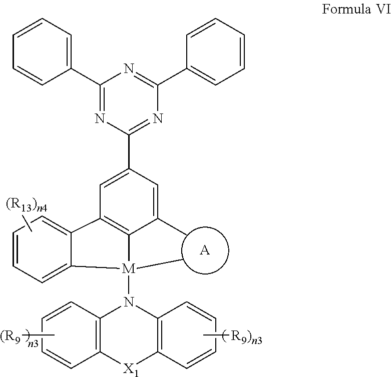

wherein: M, \textcircled{A}, X₁, n3, and R₉ can be as defined above for Formula V; n4 can be an integer from 0 to 4, from 0 to 3, from 0 to 2, or 0 or 1; each occurrence of R₁₃ can be independently hydrogen, deuterium, an unsubstituted C₁-C₆ alkyl,

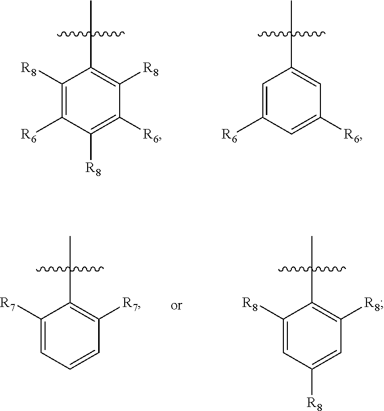

and each R₆, R₇, and R₈ can be independently hydrogen, deuterium, an unsubstituted C₁-C₁₂ alkyl, or an unsubstituted phenyl. In some forms, each R₁₃ can be independently an unsubstituted C₁-C₆ alkyl,

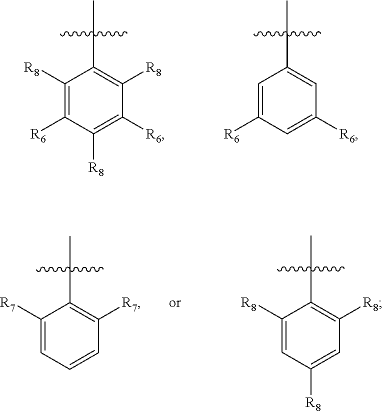

and each R₆, R₇, and R₈ can be independently hydrogen, deuterium, or an unsubstituted C₁-C₁₂ alkyl.

In some forms, each occurrence of R₁₃ can be independently hydrogen.

In some forms, the metal complexes can have the structure of Formula VII:

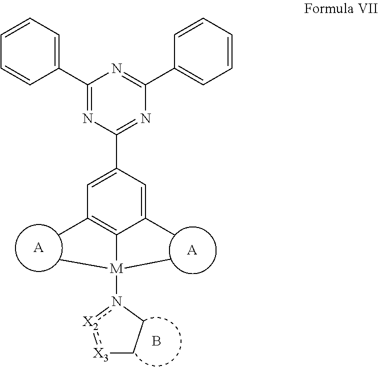

wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) X₂ and X₃ can be independently —CR₁₅R₁₆, —C═R₁₇, N, O, or S; (vi) R₁₅ and R₁₆ can be independently hydrogen, deuterium, substituted alkyl, an unsubstituted alkyl, a substituted aryl (e.g., a substituted phenyl), an unsubstituted aryl (e.g., an unsubstituted phenyl), or a substituted heteroaryl; (vii) R₁₇ can be O or S; (iii) B, when present, together with the carbon atoms to which it is attached, can form a substituted aryl or an unsubstituted aryl; (iv) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

In some forms, R₁₅ and R₁₆ can be independently hydrogen, an unsubstituted alkyl, or an unsubstituted phenyl.

In some forms, the metal complexes can have the structure of Formula VIII or IX:

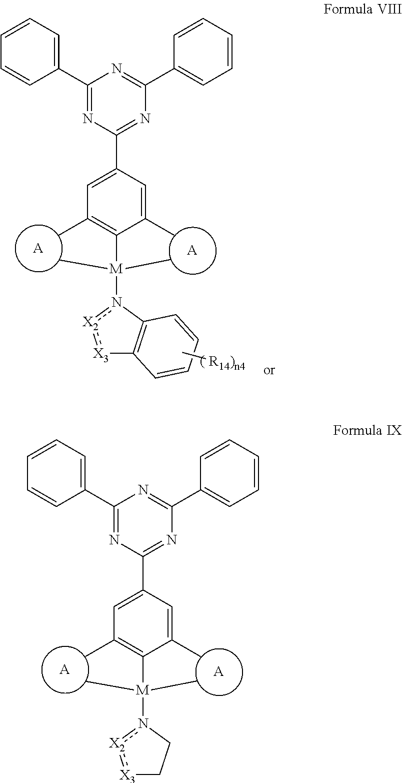

wherein: (i) M can be Pt, Pd, or Au; (ii) each \textcircled{A} can be independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring; (iii) X₂ and X₃ can be independently —CR₁₅R₁₆, —C═R₁₇, N, O, or S; (vi) R₁₅ and R₁₆ can be independently hydrogen, deuterium, a substituted alkyl, an unsubstituted alkyl, a substituted aryl (e.g., a substituted phenyl), or an unsubstituted aryl (e.g., an unsubstituted phenyl); (vii) R₁₇ can be O or S; (iii) n4 can be independently an integer from 0 to 4, from 0 to 3, from 0 to 2, or 0 or 1; (iv) each occurrence of R₁₄ can be independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or two neighboring R₁₄ together with the carbon atom to which they are attached can form a fused ring system; (v) the substituent(s), when present, can be independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

In some forms, each R₁₄ can be independently hydrogen, an unsubstituted alkyl, or an unsubstituted phenyl. In some forms, each R₁₄ can be independently hydrogen.

When two neighboring R₁₄ together with the carbon atom (and/or nitrogen atom when X₄ is nitrogen) to which they are attached form a fused ring system, the fused ring system can contain aromatic rings, non-aromatic rings, or a combination thereof, such as a polyaryl, an heteropolyaryl, a polyheteroaryl, a fused cycloalkyl, a fused cycloalkenyl, a fused cycloalkynyl, etc. For example, two neighboring R₁₄ together is

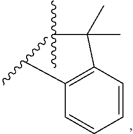 [SMILES: *c1ccccc1C(*)(C)C]

which can form a polyaryl together with the carbon atoms to which it attaches.

In some forms, X₂ and X₃ can be independently —CR₁₅R₁₆ or N; and R₁₅ and R₁₆ can be independently hydrogen, deuterium, an unsubstituted alkyl, or an unsubstituted aryl (e.g., an unsubstituted phenyl). In some forms, R₁₅ and R₁₆ can be independently hydrogen, an unsubstituted alkyl, or an unsubstituted phenyl. In some forms, R₁₅ and R₁₆ can be independently hydrogen or an unsubstituted phenyl.

In some forms, each

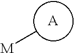

can be

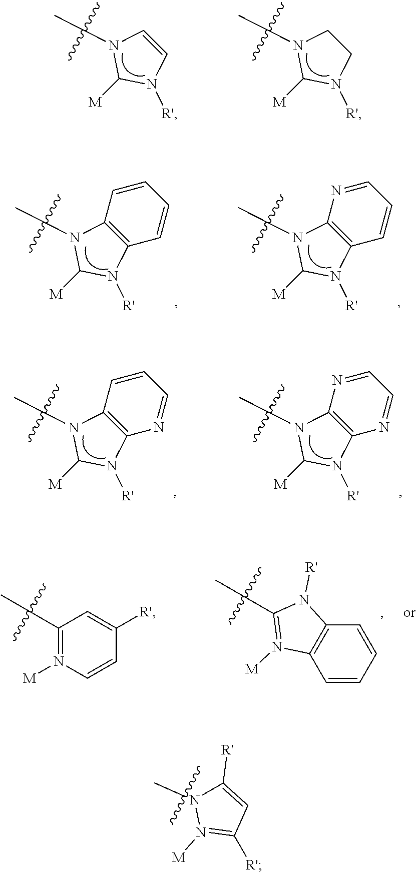

each R′ can be independently hydrogen, deuterium, a substituted C₁-C₆ alkyl, an unsubstituted C₁-C₆ alkyl, a substituted aryl, or an unsubstituted aryl; and the substituent(s), when present, can be independently a deuterium, an unsubstituted C₁-C₁₂ alkyl or an unsubstituted phenyl, such as an unsubstituted C₁-C₁₂ alkyl.

In some forms, each

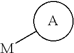

can be

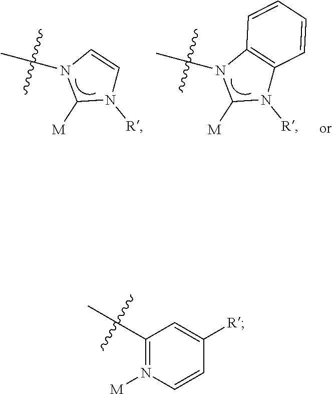

each R′ can be independently hydrogen, deuterium, a substituted C₁-C₆ alkyl, an unsubstituted C₁-C₆ alkyl, a substituted aryl, or an unsubstituted aryl; and the substituent(s), when present, can be independently a deuterium, an unsubstituted C₁-C₁₂ alkyl or an unsubstituted phenyl, such as an unsubstituted C₁-C₁₂ alkyl.

In some forms, each R′ can be independently hydrogen, deuterium, an unsubstituted C₁-C₆ alkyl,

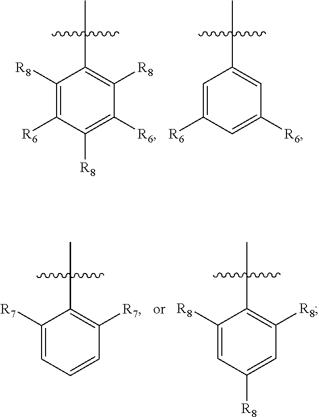

and each R₆, R₇, and R₈ can be independently hydrogen, deuterium, an unsubstituted C₁-C₁₂ alkyl, or an unsubstituted phenyl In some forms, each R′ can be independently an unsubstituted C₁-C₆ alkyl,

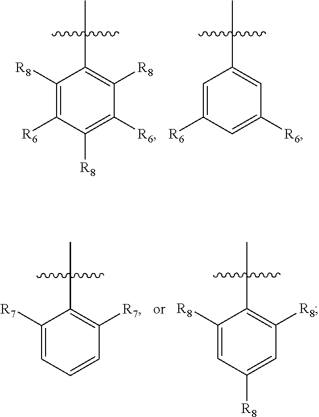

and each R₆, R₇, and R₈ can be independently hydrogen, deuterium, an unsubstituted C₁-C₁₂ alkyl, or an unsubstituted phenyl. In some forms, each R′ can be independently an unsubstituted C₁-C₆ alkyl,

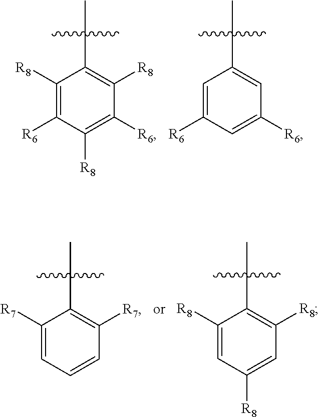

and each R₆, R₇, and R₈ can be independently hydrogen, deuterium, or an unsubstituted C₁-C₁₂ alkyl.

In some forms, each R′ can be independently

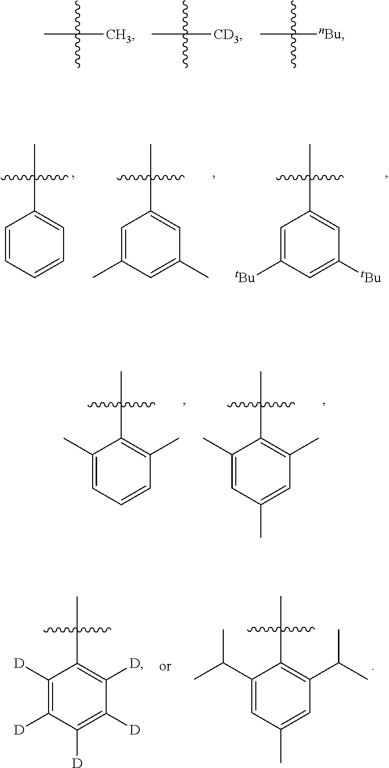

For any forms of the metal complex disclosed herein, the substituent(s) for a substituted functional group, when present, can be deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring.

For any forms of the metal complex disclosed herein, the substituent(s) for a substituted functional group, when present, can be an unsubstituted alkyl, a phenyl substituted by unsubstituted alkyl and/or unsubstituted phenyl (such as

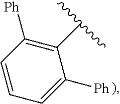 [SMILES: *c1c(-c2ccccc2)cccc1-c1ccccc1]

an unsubstituted phenyl, or an unsubstituted heteropolyaryl (such as

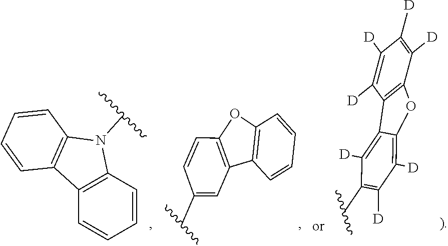

For any forms of the metal complex disclosed herein, the substituent(s) for a substituted functional group, when present, can be an unsubstituted C₁-C₆ alkyl,

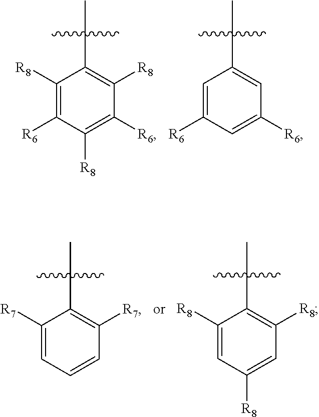

and each R₆, R₇, and R₈ can be independently hydrogen, deuterium, an unsubstituted C₁-C₁₂ alkyl, or an unsubstituted phenyl.

For any forms of the metal complex disclosed herein, the alkyl, aryl, polyaryl, heteroaryl, heteropolyaryl can be a regular alkyl, aryl, polyaryl, heteroaryl, or heteropolyaryl having hydrogen atoms, such as a regular methyl —CH₃; or a deuterium alkyl, aryl, polyaryl, heteroaryl, or heteropolyaryl having one or more deuterium in place of hydrogen, such as a deuterium methyl —CD₃. In some forms, the ligand of the metal complex contains one or more deuterium, such as deuterium heteropolyaryl, deuterium alkyl, and/or deuterium phenyl.

For any forms of the metal complex disclosed herein, the alkyl (when present) can be a linear alkyl, a branched alkyl, or a cyclic alkyl (either monocyclic or polycyclic). The terms “cyclic alkyl” and “cycloalkyl” are used interchangeably herein. Exemplary alkyl include a linear C₁-C₁₂ alkyl, a branched C₄-C₁₂ alkyl, a cyclic C₃-C₁₂ alkyl, a linear C₁-C₁₀ alkyl, a branched C₄-C₁₀ alkyl, a cyclic C₃-C₁₀ alkyl, a linear C₁-C₈ alkyl, a branched C₄-C₈ alkyl, a cyclic C₃-C₈ alkyl, a linear C₁-C₆ alkyl, a branched C₄-C₆ alkyl, a cyclic C₃-C₆ alkyl, a linear C₁-C₄ alkyl, cyclic C₃-C₄ alkyl, such as a linear C₁-C₁₀, C₁-C₉, C₁-C₈, C₁-C₇, C₁-C₆, C₁-C₅, C₁-C₄, C₁-C₃, or C₁-C₂ alkyl group, a branched C₃-C₉, C₃-C₉, C₃-C₈, C₃-C₇, C₃-C₆, C₃-C₅, or C₃-C₄ alkyl group, or a cyclic C₃-C₉, C₃-C₉, C₃-C₈, C₃-C₇, C₃-C₆, C₃-C₅, or C₃-C₄ alkyl group. The cyclic alkyl can be a monocyclic or polycyclic alkyl, such as a C₄-C₁₂, C₄-C₁₀, C₄-C₉, C₄-C₈, C₄-C₇, C₄-C₆, or C₄-C₅ monocyclic or polycyclic alkyl group. In some forms, the alkyl can be a methyl, an ethyl, an isopropyl, a n-propyl, a tert-butyl, an isobutyl, or a n-butyl.

For any forms of the metal complex disclosed herein, the alkenyl (when present) can be a linear alkenyl, a branched alkenyl, or a cyclic alkenyl (either monocyclic or polycyclic). The terms “cyclic alkenyl” and “cycloalkenyl” are used interchangeably herein. Exemplary alkenyl include a linear C₂-C₁₂ alkenyl, a branched C₄-C₁₂ alkenyl, a cyclic C₃-C₁₂ alkenyl, a linear C₂-C₁₀ alkenyl, a branched C₄-C₁₀ alkenyl, a cyclic C₃-C₁₀ alkenyl, a linear C₂-C₈ alkenyl, a branched C₄-C₈ alkenyl, a cyclic C₃-C₈ alkenyl, a linear C₂-C₆ alkenyl, a branched C₄-C₆ alkenyl, a cyclic C₃-C₆ alkenyl, a linear C₂-C₄ alkenyl, cyclic C₃-C₄ alkenyl, such as a linear C₂-C₁₀, C₂-C₉, C₂-C₈, C₂-C₇, C₂-C₆, C₂-C₅, C₂-C₄, C₂-C₃ alkenyl group, a branched C₃-C₉, C₃-C₉, C₃-C₈, C₃-C₇, C₃-C₆, C₃-C₅, C₃-C₄ alkenyl group, or a cyclic C₃-C₉, C₃-C₉, C₃-C₈, C₃-C₇, C₃-C₆, C₃-C₅, C₃-C₄ alkenyl group. The cyclic alkenyl can be a monocyclic or polycyclic alkenyl, such as a C₄-C₁₂, C₄-C₁₀, C₄-C₉, C₄-C₈, C₄-C₇, C₄-C₆, or C₄-C₅ monocyclic or polycyclic alkenyl group.

For any forms of the metal complex disclosed herein, the alkynyl (when present) can be a linear alkynyl, a branched alkynyl, or a cyclic alkynyl (either monocyclic or polycyclic). The terms “cyclic alkynyl” and “cycloalkynyl” are used interchangeably herein. Exemplary alkynyl include a linear C₂-C₁₂ alkynyl, a branched C₄-C₁₂ alkynyl, a cyclic C₃-C₁₂ alkynyl, a linear C₂-C₁₀ alkynyl, a branched C₄-C₁₀ alkynyl, a cyclic C₃-C₁₀ alkynyl, a linear C₂-C₈ alkynyl, a branched C₄-C₈ alkynyl, a cyclic C₃-C₈ alkynyl, a linear C₂-C₆ alkynyl, a branched C₄-C₆ alkynyl, a cyclic C₃-C₆ alkynyl, a linear C₁-C₄ alkynyl, cyclic C₃-C₄ alkynyl, such as a linear C₂-C₁₀, C₂-C₉, C₂-C₈, C₂-C₇, C₂-C₆, C₂-C₅, C₂-C₄, C₂-C₃ alkynyl group, a branched C₃-C₉, C₃-C₉, C₃-C₈, C₃-C₇, C₃-C₆, C₃-C₅, C₃-C₄ alkynyl group, or a cyclic C₃-C₉, C₃-C₉, C₃-C₈, C₃-C₇, C₃-C₆, C₃-C₅, C₃-C₄ alkynyl group. The cyclic alkynyl can be a monocyclic or polycyclic alkynyl, such as a C₄-C₁₂, C₄-C₁₀, C₄-C₉, C₄-C₈, C₄-C₇, C₄-C₆, or C₄-C₅ monocyclic or polycyclic alkynyl group.

For any forms of the metal complex disclosed herein, the aryl (when present) can be a C₄-C₃₀ aryl, a C₄-C₂₀ aryl, a C₄-C₁₂ aryl, a C₄-C₁₁ aryl, a C₄-C₉ aryl, a C₅-C₃₀ aryl, a C₅-C₂₀ aryl, a C₅-C₁₂ aryl, a C₅-C₁₁ aryl, a C₅-C₉ aryl, a C₆-C₂₀ aryl, a C₆-C₁₂ aryl, a C₆-C₁₁ aryl, or a C₆-C₉ aryl. It is understood that the aryl can be a heteroaryl, such as a C₄-C₃₀ heteroaryl, a C₄-C₂₀ heteroaryl, a C₄-C₁₂ heteroaryl, a C₄-C₁₁ heteroaryl, a C₄-C₉ heteroaryl, a C₅-C₃₀ heteroaryl, a C₅-C₂₀ heteroaryl, a C₅-C₁₂ heteroaryl, a C₅-C₁₁ heteroaryl, a C₅-C₉ heteroaryl, a C₆-C₃₀ heteroaryl, a C₆-C₂₀ heteroaryl, a C₆-C₁₂ heteroaryl, a C₆-C₁₁ heteroaryl, or a C₆-C₉ heteroaryl.

For any forms of the metal complex disclosed herein, the polyaryl group can be a C₈-C₃₀ polyaryl, a C₈-C₂₀ polyaryl, a C₈-C₁₂ polyaryl, a C₈-C₁₁ polyaryl, a C₁₀-C₃₀ polyaryl, a C₁₀-C₂₀ polyaryl, a C₁₀-C₁₂ polyaryl, a C₁₀-C₁₁ polyaryl, or a C₁₂-C₂₀ polyaryl. It is understood that the aryl can be a heteropolyaryl, such as a C₁₀-C₃₀ heteropolyaryl, a C₁₀-C₂₀ heteropolyaryl, a C₁₀-C₁₂ heteropolyaryl, a C₁₀-C₁₁ heteropolyaryl, or a C₁₂-C₂₀ heteropolyaryl.

Exemplary metal complexes are presented below.

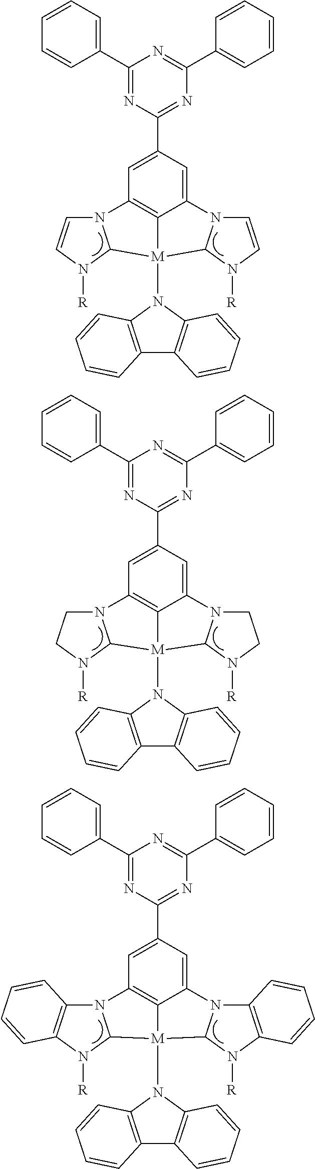

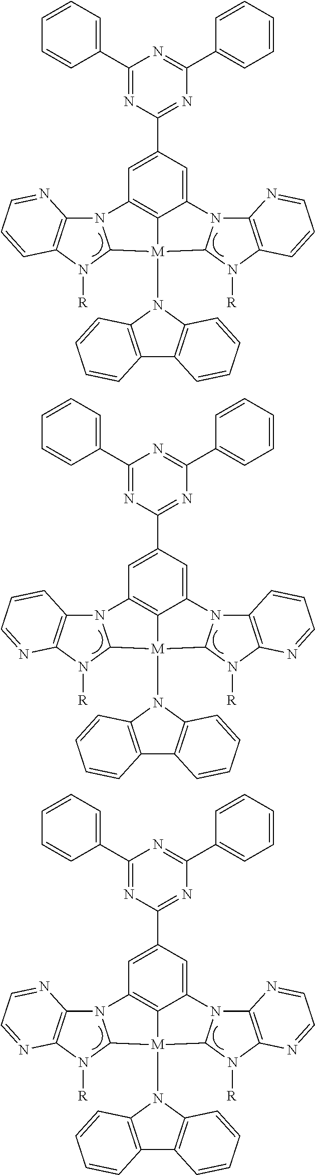

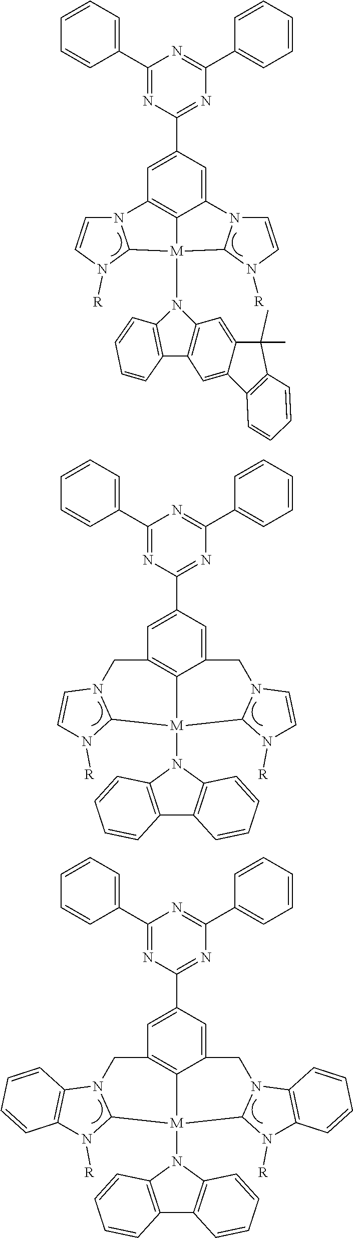

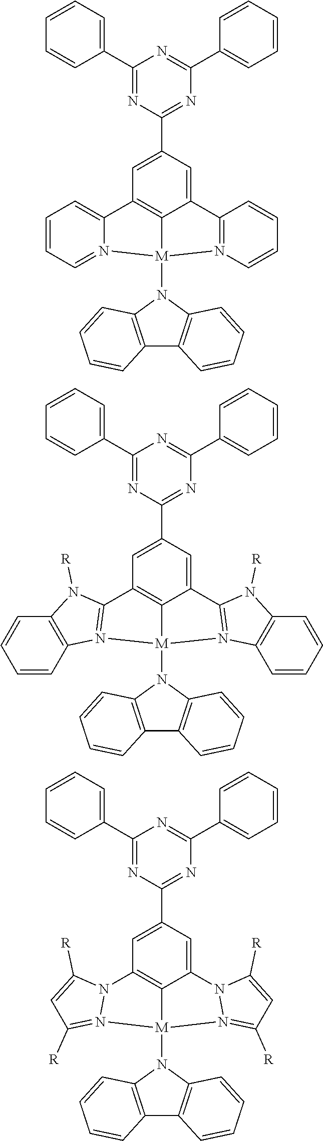

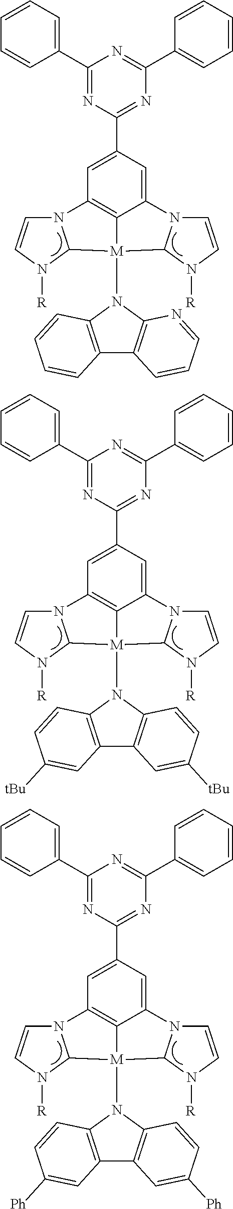

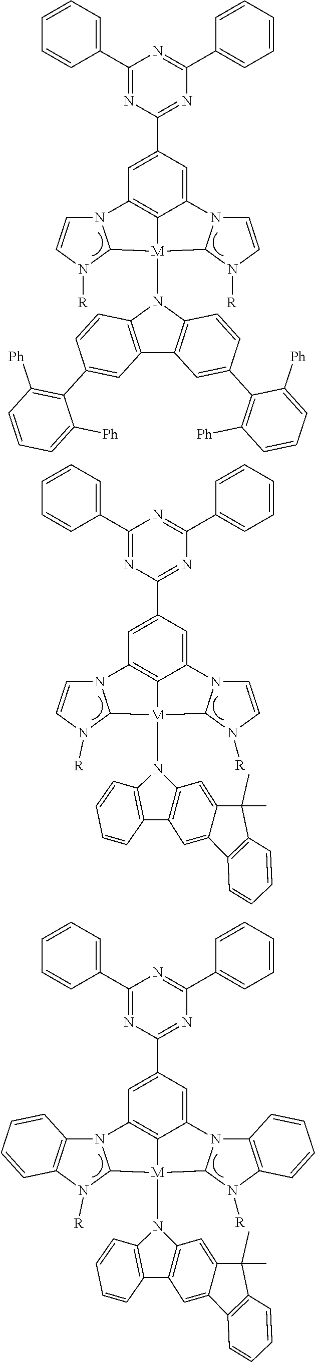

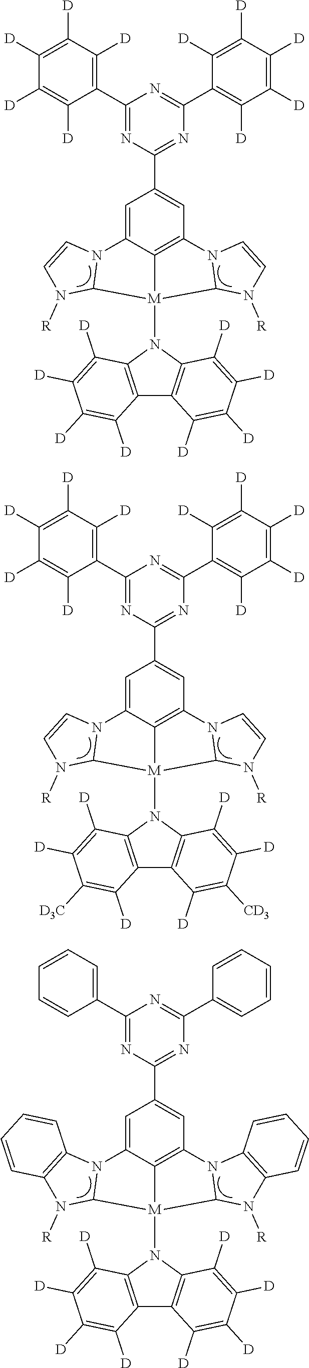

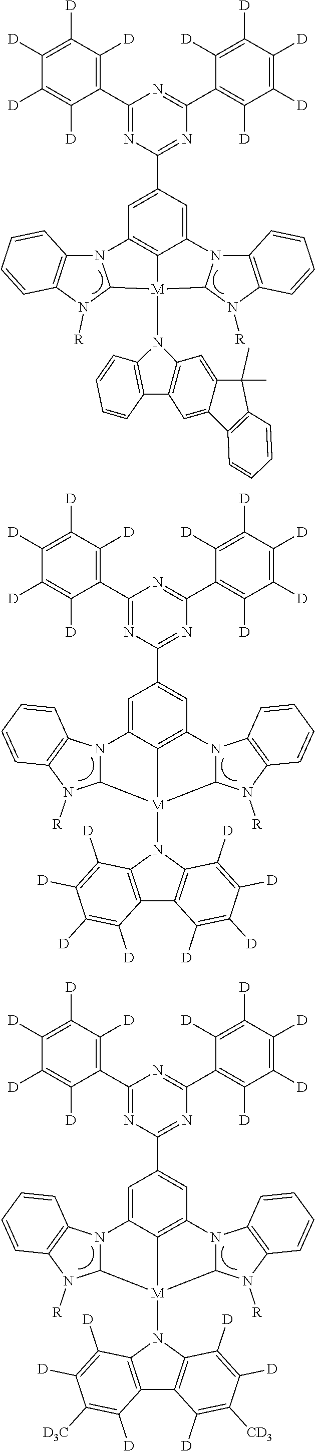

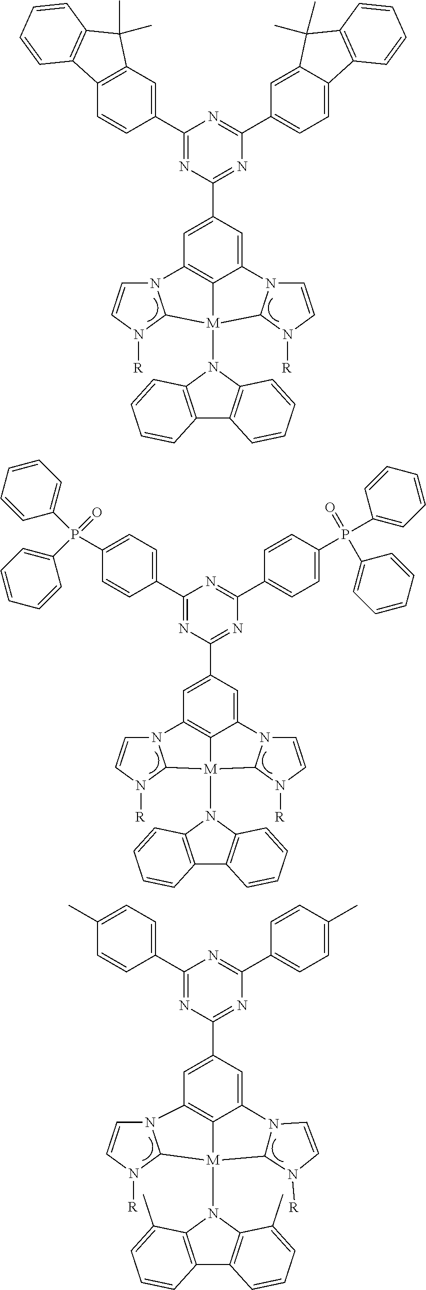

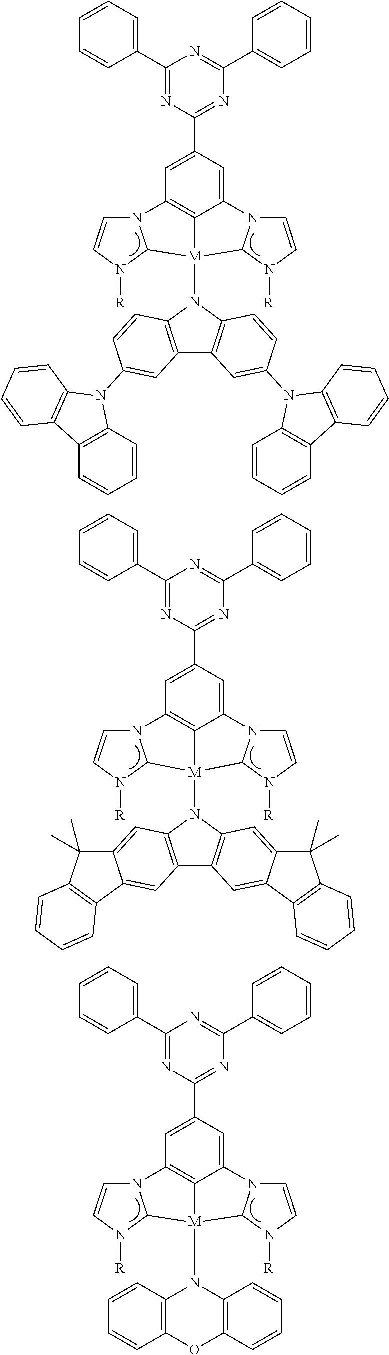

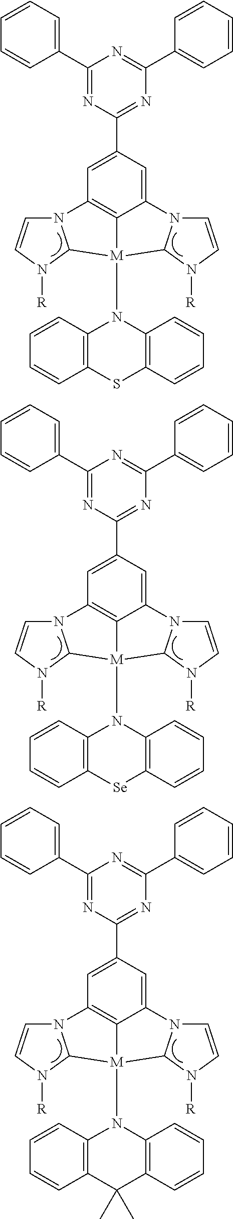

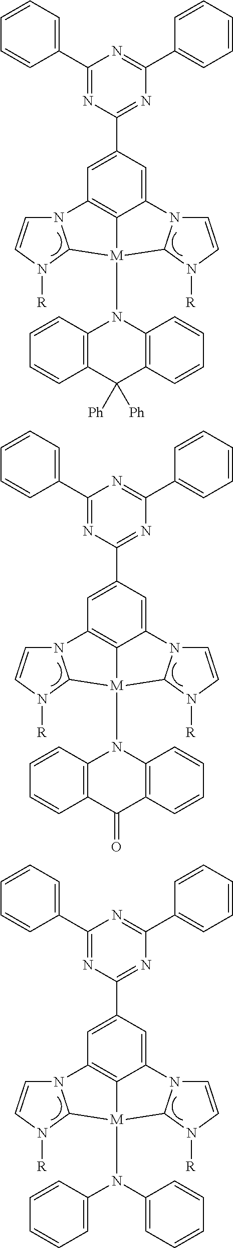

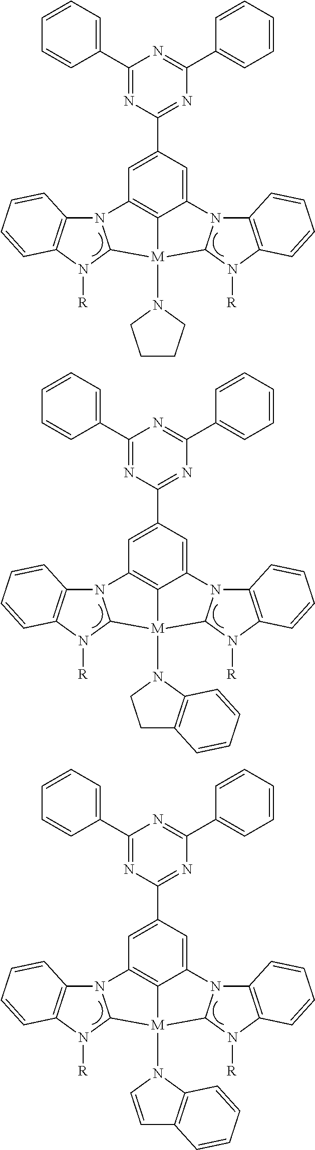

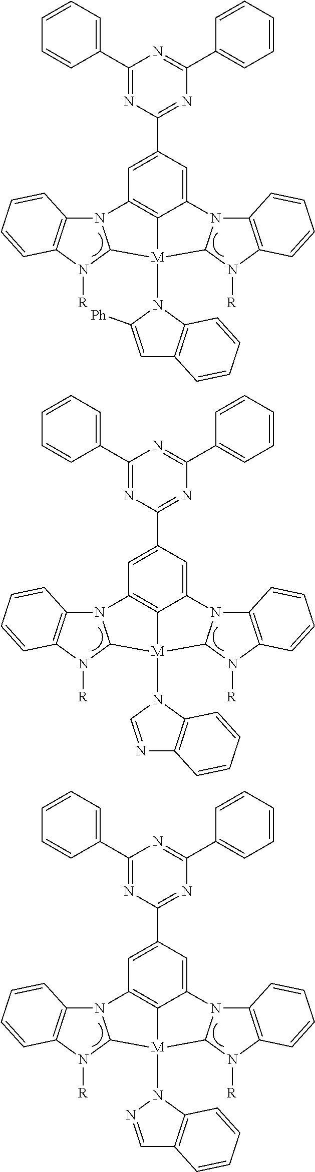

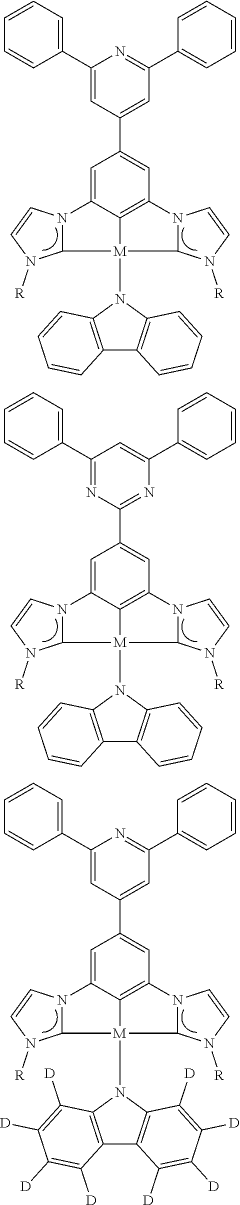

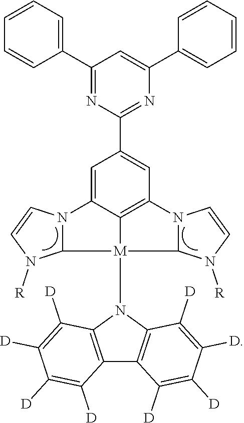

wherein M can be Pt, Pd, or Au, each R can be independently a substituted C₁-C₆ alkyl, an unsubstituted C₁-C₆ alkyl, a substituted phenyl, or an unsubstituted phenyl; and the substituent(s), when present, can be independently an unsubstituted C₁-C₁₂ alkyl. In some forms, each R can be independently an unsubstituted C₁-C₆ alkyl,

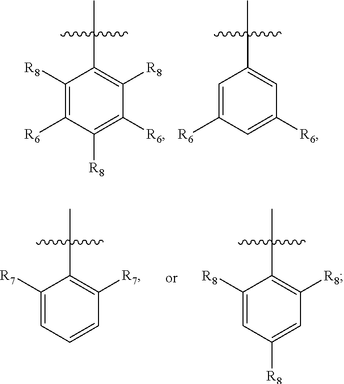

and each R₆, R₇, and R₈ can be independently hydrogen, deuterium, or an unsubstituted C₁-C₁₂ alkyl. In some forms, each R can be independently

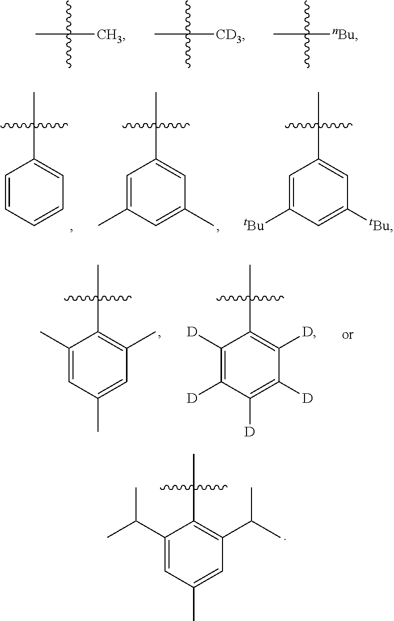

Additional exemplary Pt and Pd complexes are presented below.

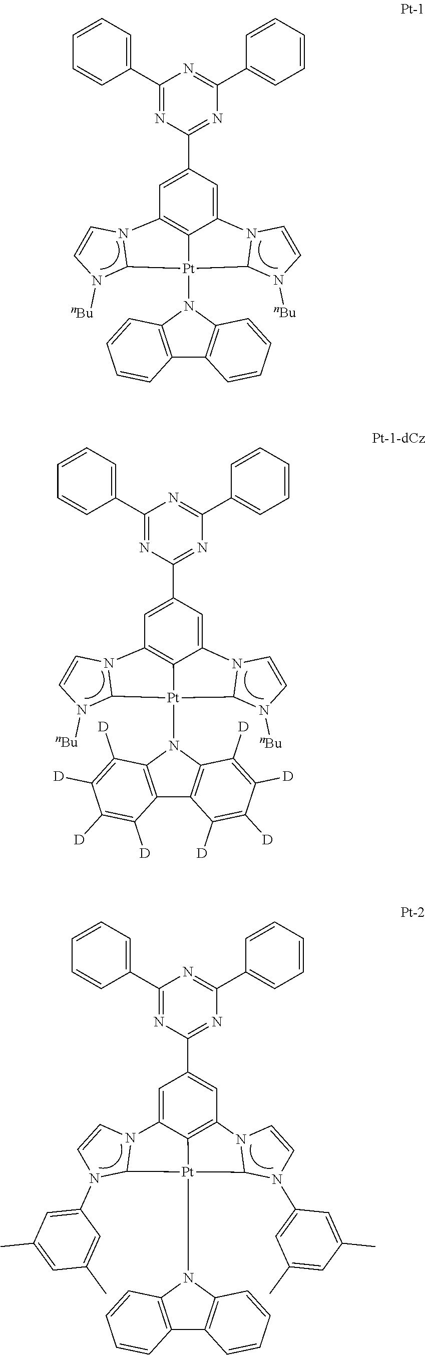

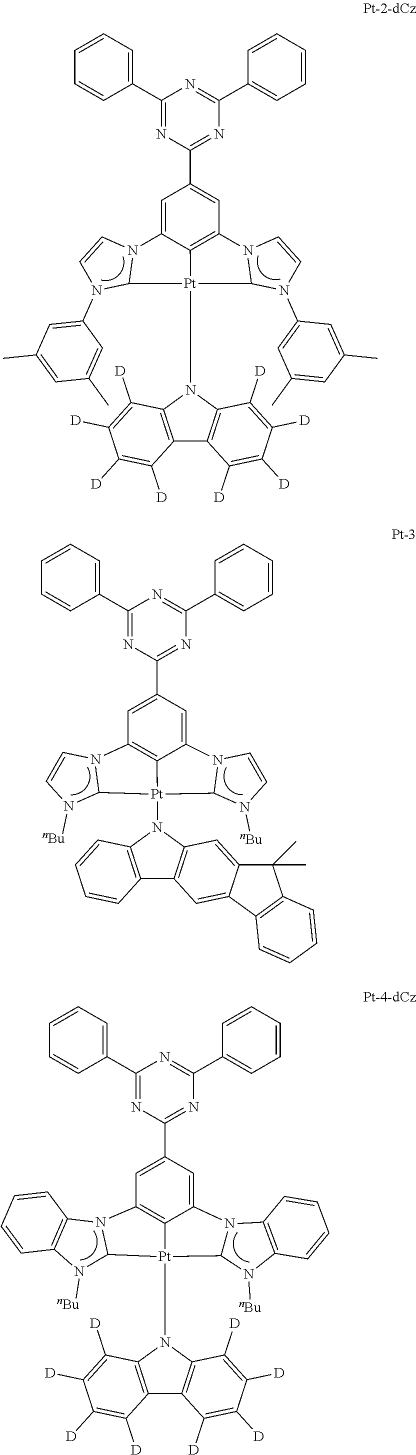

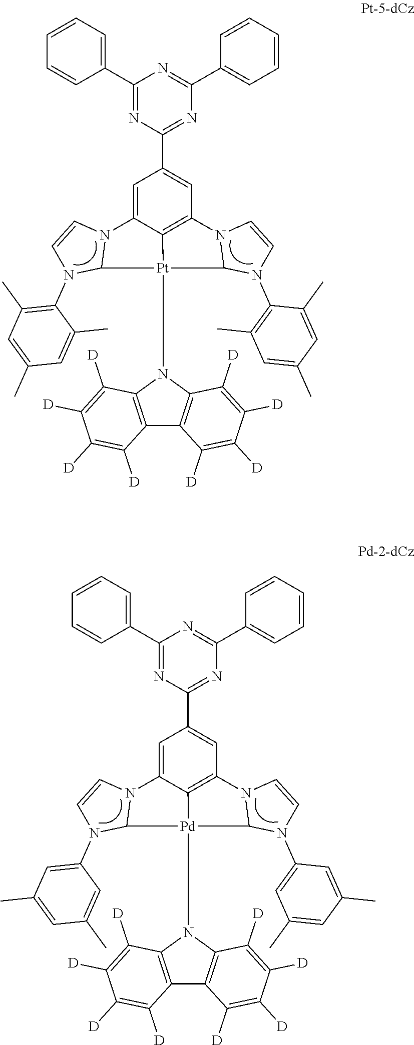

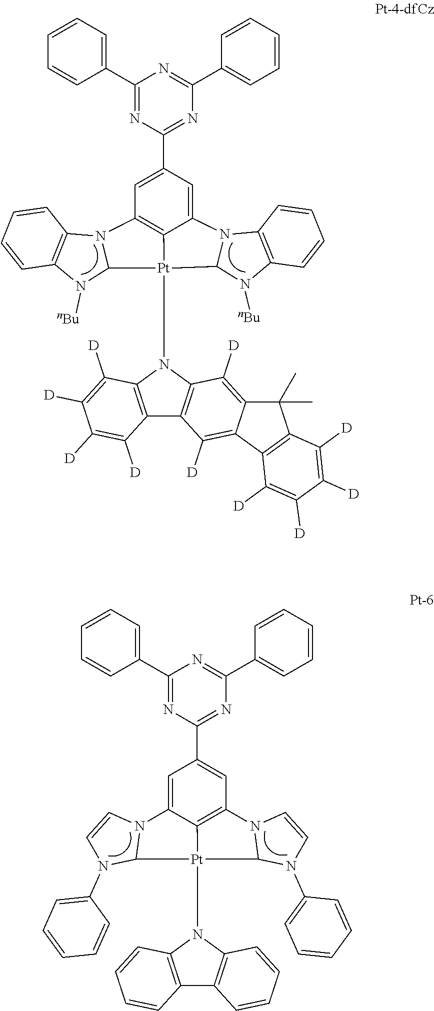

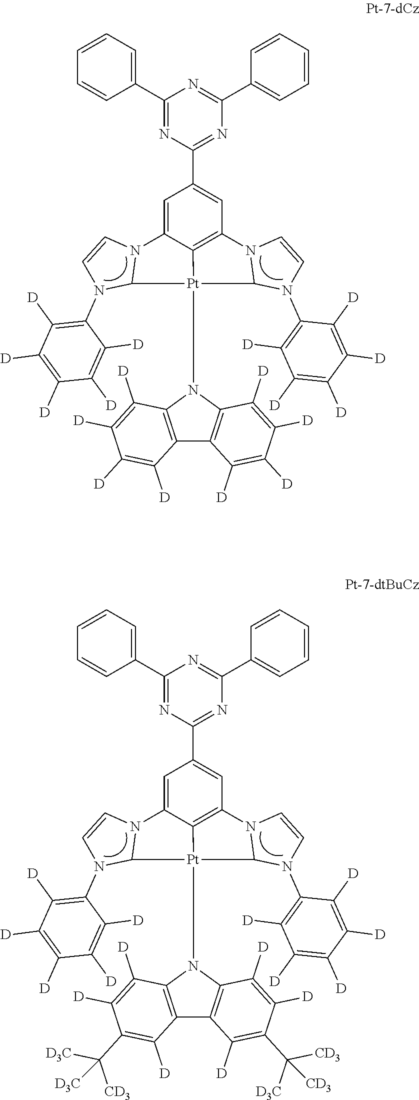

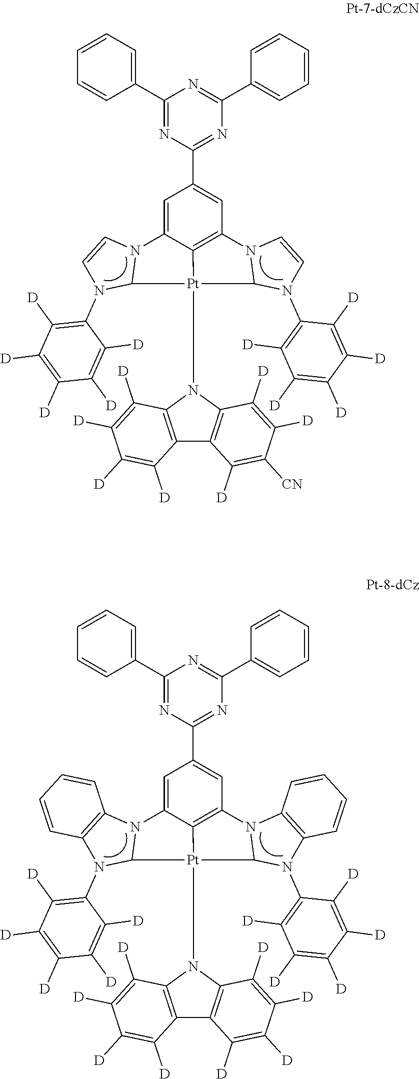

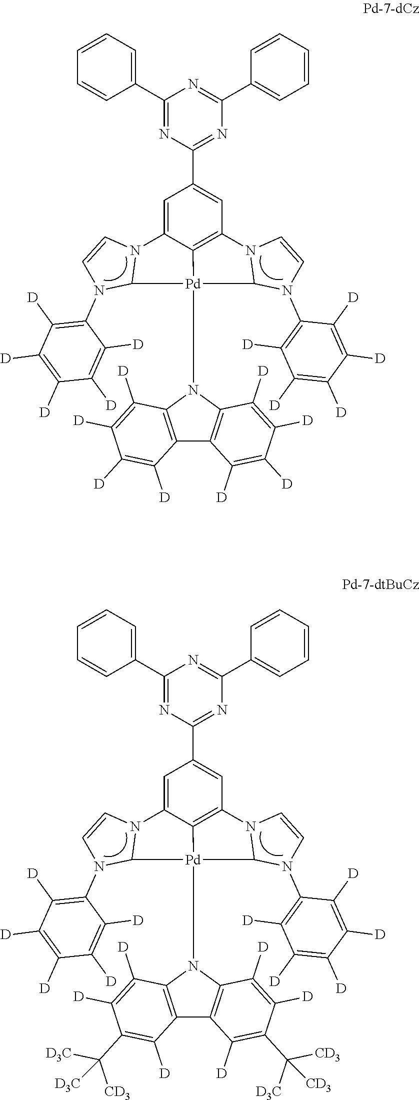

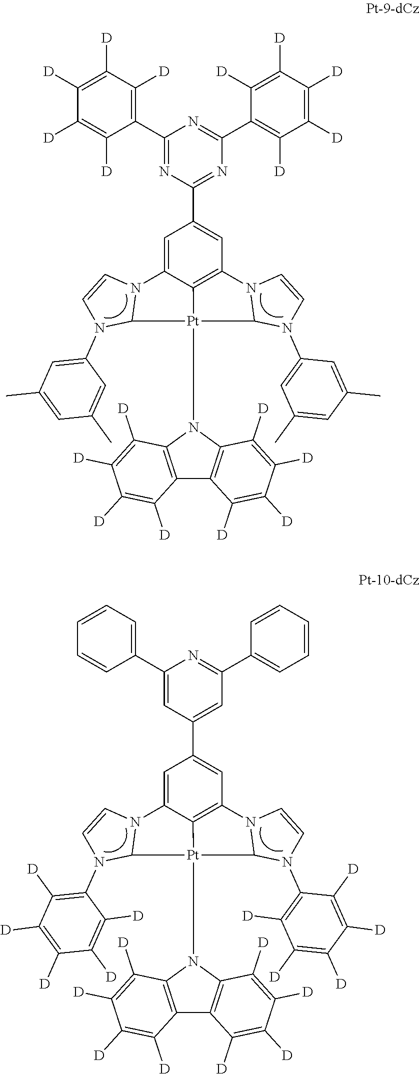

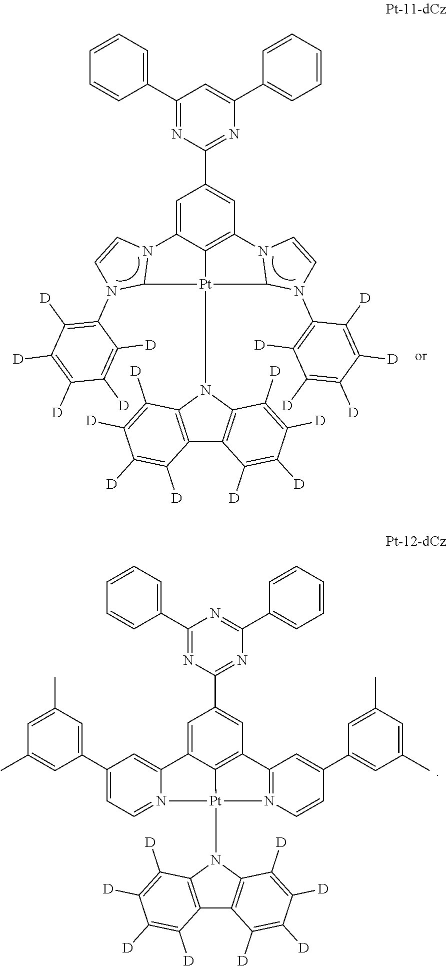

Additional exemplary Au complexes are presented below.

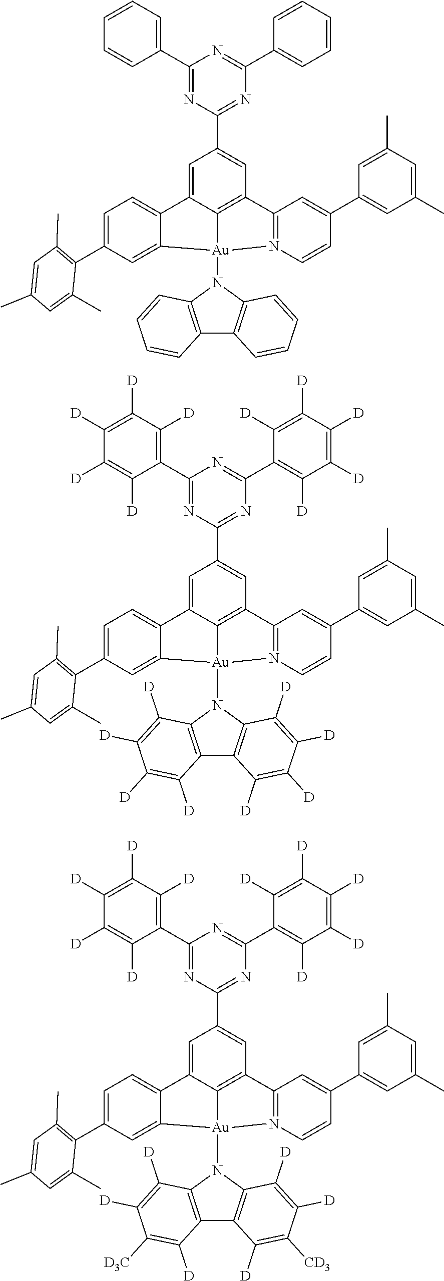

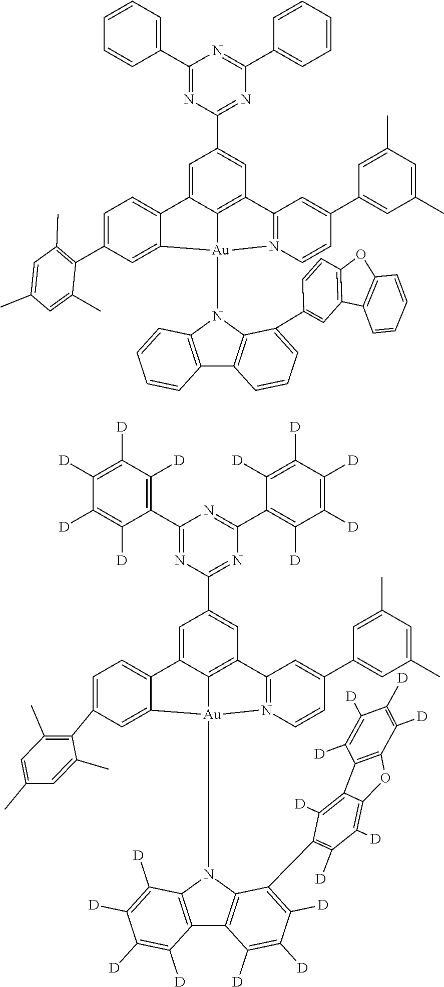

### 1. Photophysical Properties

The photophysical properties of the metal complexes disclosed herein can be evaluated by a number of parameters, such as emission lifetime (“τₑₘ” or “τ”), radiative decay rate constant (“kᵣ”), emission quantum yield (“Φₑₘ”), and/or maximum emission wavelength (“λₘₐₓ”).

Techniques for measuring the τₑₘ, kᵣ, Φₑₘ, and λₘₐₓ of the metal complexes are known. These parameters can be obtained by conducting photophysical measurement of a metal complex. For example, based on the measured emission decay graph, the τₑₘ of the metal complex can be obtained as follows: (i) monitor the intensity of emission decay as a function of time using a Quanta Ray GCR 150-10 pulsed Nd:YAG laser system (pulse output: 355 nm), and (ii) determine the τₑₘ by fitting the exponential decay of formula (1) using Origin software, where I₀ is the initial emission intensity, I(t) is the emission intensity at time t, τ is the emission lifetime, and t is the time.

$$I ( t ) = {I}_{0} {e}^{- t / τ} \qquad formula ( 1 )$$

The kᵣ of the metal complex can be obtained using kᵣ=Φₑₘ/τₑₘ. The Φₑₘ values of these metal complexes can be measured by known methods, such as direct measurements or relative methods. For example, the Φₑₘ of the metal complexes in solutions or thin films, can be directly obtained by absolute measurement using Hamamatsu C11347 Quantaurus-QY Absolute PL quantum yield spectrometer (PL stands for photoluminescence). For example, the values for Φₑₘ are directly given by the software provided with the instrument. The λₘₐₓ of the metal complexes can be directly measured from the emission spectra.

Exemplary solutions suitable for measuring the τₑₘ, kᵣ, Φₑₘ, and/or λₘₐₓ of the metal complexes include those that contain an organic solvent. Exemplary organic solvents suitable for use to form the measurement solutions include, but are not limited to, dichloromethane, chloroform, tetrahydrofuran, N,N-dimethylformamide, chlorobenzene, and toluene, and a combination thereof. Optionally, the solutions for measuring the τₑₘ, kᵣ, Φₑₘ, and/or λₘₐₓ of the metal complexes is degassed with an inert gas, such as nitrogen, argon, or helium, or a combination thereof. Optionally, the solutions for measuring the τₑₘ, kᵣ, Φₑₘ, and/or λₘₐₓ of the metal complexes is deoxygenated by the known freeze-pump-thaw method.

Suitable thin films for measuring the τₑₘ, kᵣ, Φₑₘ, and/or λₘₐₓ of the metal complexes include films having a thickness between 10 nm and 50 μm, inclusive, between 10 nm and 10 μm, inclusive, between 10 nm and 5 μm, inclusive, between 10 nm and 1 μm, inclusive, between 10 nm and 500 nm, inclusive, or between 10 nm and 200 nm, inclusive. The films can also contain organic compounds as host materials. Exemplary organic compounds that can be used as a host material in the films include, but are not limited to, 1,3-bis(N-carbazolyl)benzene (mCP), 3,3′-di(9H-carbazol-9-yl)-1,1′-biphenyl (mCBP), poly(methyl methacrylate) (PMMA), polystyrene (PS), 2,8-bis(diphenylphosphoryl)dibenzo[b,d]furan (PPF), bis[2-(diphenylphosphino)phenyl]ether oxide (DPEPO).

The metal complexes are strongly emissive in thin film, such as with an emission maximum at 562-650 nm, an emission quantum yield up to 89%, and/or an emission lifetime below 2.3 μs. The emission color of these metal complexes can be tuned by changing the metal ion, the wingtip of NHC moiety, and the amide ligand. For example, platinum(II) complexes can be strongly emissive in thin film with emission maxima at 562-624 nm, emission quantum yield up to 89%, and emission lifetime below 1.25 μs.

The metal complexes show a high radiative decay rate constant (kᵣ). Without being bound to any theories, it is believed that the increased kᵣ is attributed to the through-bond charge transfer character of the donor-acceptor configuration of the metal complexes. For example, platinum(II) complexes can have a radiative decay rate constant of up to 1.6×10⁶ s⁻¹, which is significantly higher than the kᵣ values (about 2 to 5×10⁵ s⁻¹) of reported mononuclear platinum(II) emitters. Accordingly, the high radiative decay rate constant of the metal complexes can solve the problem of limited radiative decay rate constants of mononuclear platinum(II) emitters. For example, using the metal complexes disclosed herein, the OLED device degradation processes caused by long-lived triplet excited state can be avoided, leading to operationally stable OLEDs.

In some forms, the metal complexes disclosed herein can have a maximum emission wavelength (λₘₐₓ) in a range from 540 nm to 660 nm, from 550 nm to 660 nm, from 540 nm to 650 nm, from 550 nm to 650 nm, from 560 nm to 650 nm, or from 560 nm to 625 nm, optionally based on the emission spectra of the metal complexes as described above.

In some forms, the metal complexes disclosed herein can have an emission quantum yield (Φₑₘ) of at least 50%, at least 55%, at least 60%, at least 65%, at least 70%, at least 75%, at least 80%, at least 85%, in a range from 50% to 90%, from 55% to 90%, from 60% to 90%, from 65% to 90%, or from 70% to 90%, measured in films, at room temperature, optionally based on the emission spectra of the metal complexes as described above.

In some forms, the metal complexes disclosed herein can have an emission lifetime (τₑₘ) of ≤2.5 μs, ≤2.3 μs, ≤2.0 μs, ≤1.5 μs, ≤1.3 μs, in a range from 0.3 μs to 2.5 μs, from 0.3 μs to 2.3 μs, from 0.3 μs to 2.0 μs, from 0.3 μs to 1.5 μs, or from 0.3 μs to 1.3 μs, measured in films, at room temperature, optionally based on the emission spectra of the metal complexes as described above.

In some forms, the metal complexes disclosed herein can have a radiative decay rate constant (kᵣ) of at least 5.5×10⁵ s⁻¹, at least 6.0×10⁵ s⁻¹, at least 8.0×10⁵ s⁻¹, at least 1.0×10⁶ s⁻¹, in a range from 5.5×10⁵ s⁻¹ to 1.6×10⁶ s⁻¹, measured in films, at room temperature, optionally based on the emission spectra of the metal complexes as described above.

In some forms, the metal complexes disclosed herein can have a τₑₘ, a kᵣ, a Φₑₘ, and/or a λₘₐₓ in any one of the above-described ranges.

### B. Devices Containing the Metal Complexes

Organic light-emitting components, such as light-emitting diodes (OLEDs) or light-emitting electrochemical cell (“LEEC”), containing one or more of the metal complexes are described. Devices containing one or more OLEDs containing one or more of the metal complexes include, but are not limited to, stationary visual display units, mobile visual display units, and illumination devices, such as smart phones, televisions, monitors, digital cameras, tablet computers, and lighting fixtures that usually operate at room temperatures, wearable devices, and medical monitoring devices.

In some forms, the metal complexes can be incorporated in a light-emitting layer. The light-emitting layer may further contain one or more luminescent organic dyes, optionally as terminal emitters. When organic dye is present along with the metal complex(es), the metal complex(es) can act as a sensitizer to transfer energy to the organic dye. When an organic dye is incorporated in the light-emitting layer, the metal complexes and the dye can have any suitable weight ratios, such as 4:1, 8:1, 10:1, 12:1, 15:1, or 20:1.

In some forms, the light-emitting layer can be incorporated in an organic light-emitting component, such as an OLED. Organic light-emitting components can contain one or more light-emitting layers, where each light-emitting layer can contain one or more the metal complexes. In some forms, when two or more light-emitting layers are included in the organic light-emitting component, the light-emitting layer or each light-emitting layer further includes one or more host materials, such as those described above. The total concentration of the one or more host materials can be greater than the total concentration of the one or more metal complexes in the light-emitting layer or each light-emitting layer of the two or more light-emitting layers. The term “total concentration of the one or more metal complexes” refers to the sum of the weight of the one or more metal complexes relative to the sum of the weights of all of the materials used in one light-emitting layer in an organic light-emitting device, such as an OLED. The term “total concentration of the one or more one or more host materials” refers to the sum of the weight of the one or more host materials relative to the sum of the weights of all of the materials used in one light-emitting layer in an organic light-emitting device, such as an OLED.

The organic light-emitting devices can contain a suitable amount of the metal complexes in the light-emitting layer or each light-emitting layer of the two or more light-emitting layers of the device. For example, the total concentration of the one or more metal complexes in the light-emitting layer or each light-emitting layer of the two or more light-emitting layers is from about 1 wt % to about 20 wt %, from about 1 wt % to about 10 wt %, from about 2 wt % to about 20 wt %, from about 2 wt % to about 16 wt %, from about 2 wt % to about 10 wt %, or from about 2 wt % to about 8 wt %, such as about 2 wt %, about 4 wt %, about 6 wt %, or about 8 wt %.

In some forms, the organic light-emitting component, such as an OLED, can further include an anode, a cathode, a hole transport region, and/or an electron transport region. The hole transport region can include a hole injection layer and/or a hole transport layer, and optionally an electron blocking layer. The electron transport region can include an electron transport layer and/or an electron injection layer, and optionally a hole blocking layer. The light-emitting layer can be located in between the anode and the cathode. The hole transport region can be located in between the anode and the light-emitting layer. The electron transport region can be located in between the cathode and the light-emitting layer. The specific components and arrangement of the components in each of the hole transport region and the electron transport region depend on the specific use.

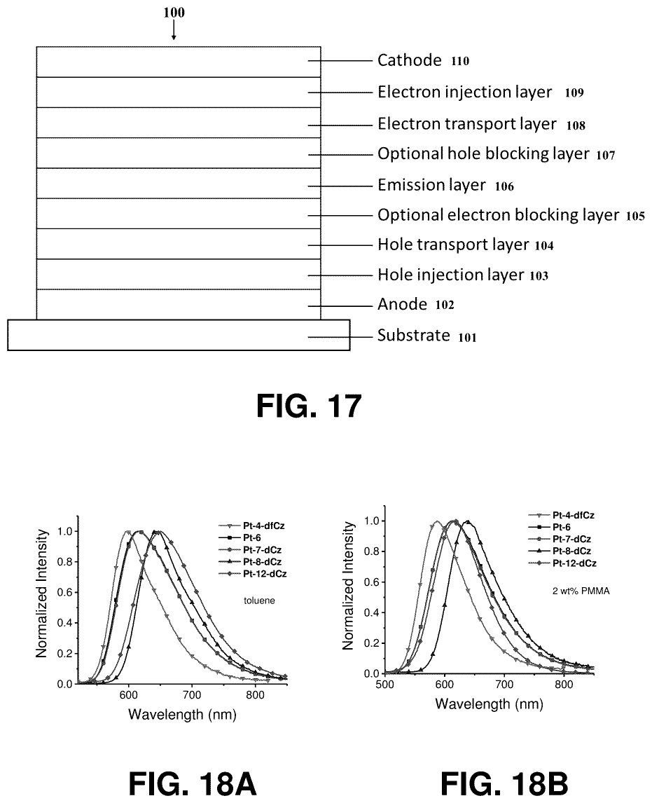

An exemplary OLED containing the disclosed metal complexes is illustrated in FIG. 17. As shown in FIG. 17, the exemplary OLED 100 includes multiple layers, which are, from bottom to top, a substrate 101, an anode 102, a hole injection layer 103, a hole transport layer 104, an optional electron blocking layer 105, an emission layer 106, an optional hole blocking layer 107, an electron transport layer 108, an electron injection layer 109, and a cathode 110. The emission layer 106 is formed by one or more of the metal complexes disclosed herein. Suitable materials for forming the anode, the hole injection layer, the hole transport layer, the optional electron blocking layer, the optional hole blocking layer, the electron transport layer, the electron injection layer, and the cathode are known in the art, see, for example, those described in Hong, et al., Adv. Mater. 2021, U.S. Pat. No. 2,005,630; Lee, et al., InfoMat. 2021, 3, 61-81; and Jou, et al., J. Mater. Chem. C, 2015, 3, 2974-3002. The dimensions of each layer in the OLED, such as the shape, the length, the width, and/or the thickness of each layer can be varied depending on the specific use of the OLED. More specific exemplary OLEDs are described in the Examples below.

These organic light-emitting devices containing the disclosed metal complexes can emit in different color regions, such as emit at λₘₐₓ in a range from 530 nm to 660 nm, from 530 nm to 650 nm, from 530 nm to 640 nm, from 540 nm to 660 nm, from 540 nm to 650 nm, from 540 nm to 640 nm, from 540 nm to 630 nm, from 540 nm to 620 nm, from 540 nm to 610 nm, or from 540 nm to 600 nm, such as from 554 nm to 637 nm or from 541 nm to 599 nm. The performance of OLEDs containing the disclosed metal complexes can be evaluated using known parameters, such as maximum quantum efficiency (EQE) and operational lifetime LT₉₅ at 1000 cd m⁻².

Techniques for measuring the maximum quantum efficiency and LT₉₅ are known. For example, maximum EQE of a light-emitting device can be obtained by using a Keithley 2400 source-meter and an absolute external quantum efficiency measurement system (C9920-12, Hamamatsu Photonics), where all devices can be encapsulated in a 200-nm-thick Al₂O₃ thin film deposited by atomic layer deposition (ALD) in a Kurt J. Lesker SPECTROS ALD system before measurements. For example, LT₉₅ of a light emitting device can be obtained by measuring the time required for the luminance of a light-emitting device decaying to a level of 95% of the initial luminance (for example, it can be 1000 cd m⁻², 3000 cd m⁻², 5000 cd m⁻² or 10000 cd m⁻² or higher). The LT₉₅ at a particular luminance can be estimated by using the formula LT(L₁)=LT(L₀)(L₀/L₁)ⁿ, where L₁ is a particular luminance and L₀ is the initial luminance. LT(L₁) and LT(L₀) are the operational lifetimes at a particular luminance (L₁) and L₀ (initial luminance), respectively. n is the acceleration factor, which is assumed to be 1.7.

In some forms, OLEDs containing from 1 wt % to 10 wt % f the disclosed metal complexes can emit at λₘₐₓ ranging from 530 nm to 660 nm, from 540 nm to 650 nm, or from 540 nm to 600 nm, with a maximum EQE of at least 12%, at least 15%, in a range from 12% to 30%, from 12% to 25%, from 15% to 30%, from 15% to 25%, or from 20% to 30%, such as about 25.5% or about 21.4%.

In some forms, OLEDs containing from 1 wt % to 10 wt % f the disclosed metal complexes can emit at λₘₐₓ ranging from 530 nm to 660 nm, from 540 nm to 650 nm, or from 540 nm to 600 nm, with LT₉₅ of at least 1000 hours, at least 2000 hours, at least 3000 hours, at least 4000 hours, at least 5000 hours, in a range from 1000 cd m⁻² to 7500 cd m⁻², from 1000 cd m⁻² to 7000 cd m⁻², from 1000 cd m⁻² to 6000 cd m⁻², from 2000 cd m⁻² to 7500 cd m⁻², from 2000 cd m⁻² to 7000 cd m⁻², from 2000 cd m⁻² to 6000 cd m⁻², from 3000 cd m⁻² to 7500 cd m⁻², from 3000 cd m⁻² to 7000 cd m⁻², from 3000 cd m⁻² to 6000 cd m⁻², from 4000 cd m⁻² to 7500 cd m⁻², from 4000 cd m⁻² to 7000 cd m⁻², or from 4000 cd m⁻² to 6000 cd m⁻², at 1000 cd m⁻², such as about 7300 hours or about 6660 hours, at 1000 cd m⁻²

In some forms, OLEDs containing from 1 wt % to 10 wt % f the disclosed metal complexes can emit at λₘₐₓ ranging from 530 nm to 660 nm, from 540 nm to 650 nm, or from 540 nm to 600 nm, such as from 554 nm to 637 nm or from 541 nm to 599 nm, with a maximum EQE and LT₉₅ at 1000 cd/m² in any of the ranges described above.

More specific examples of the maximum external quantum efficiency and LT₉₅ of exemplary OLEDs containing exemplary metal complexes are described in the Examples below.

### III. Methods of Making the Metal Complexes

### A. Metal Complexes

The metal complexes and the ligands described herein can be synthesized using methods known in the art of organic chemical synthesis. For example, ligands can be purchased from commercial chemical manufacturers or may be prepared according to procedures reported and/or adapted from the literature. The selection of appropriate synthetic conditions, reagents, reaction workup conditions, purification techniques (as needed) are known to those in the field of synthesis.

Syntheses of exemplary ligands and exemplary metal complexes Pt-1, Pt-1-dCz, Pt-2, Pt-2-dCz, Pt-3, Pt-4-dCz, Pt-5-dCz, Pd-2-dCz are shown in Schemes 1-8 and described in the Examples below.

### B. Organic Light-Emitting Devices

Also described are methods of making organic light-emitting components, such as OLEDs, containing one or more metal complexes described herein. Methods of preparing OLEDs containing one or more metal complexes, as described above, are well-known in the art of organic electronics. Such method of making OLEDs can involve vacuum deposition or solution processing techniques, such as spin-coating and ink-jet printing. The selection of suitable materials (anode, cathode, hole transport layer, electron transport layer, etc.) and fabrication parameters (such as deposition conditions or solvent selections) needed to fabricate OLEDs containing the metal complexes described herein are known in the art. In some forms, preparation of the OLEDs can be via vacuum deposition or solution processing techniques such as spin-coating and ink printing (such as, ink-jet printing or roll-to-roll printing). An exemplary and non-limiting method of making an OLED containing one or more metal complexes is described in the Examples.

### IV. Methods of Using the Metal Complexes

Organic light-emitting devices fabricated using the metal complexes disclosed herein, such as organic light-emitting diodes (“OLEDs”), can result in high performance devices. For example, vapor-deposited OLEDs are fabricated with platinum/palladium(II) complexes to attain electroluminescence (EL) emission maxima of 554-637 nm and maximum EQE up to 30%, such as about 25.5%. For example, vapor-deposited OLEDs fabricated with the Pt(II) complexes can attain EL emission maxima of 554-637 nm and a maximum EQE up to 25.5%. Further, OLEDs fabricated using the metal complexes can exhibit long operational lifetime, such as an unprecedentedly operational lifetime with LT₉₅ of up to 7289 hours at 1000 cd m⁻². For example, vapor-deposited OLEDs fabricated with the Pt(II) complexes can exhibit an unprecedentedly long operational lifetime with LT₉₅ of up to 6660 hours at 1000 cd m⁻². In some forms, the operational lifetimes of OLEDs using metal complexes with deuterated ligands can further extend the operational lifetimes of the OLEDs by more than 4-fold, compared to OLEDs fabricated using Pt-1 and Pt-1-dCz.

Such OLEDs can be used in commercial applications such smart phones, televisions, monitors, digital cameras, tablet computers, lighting fixtures that usually operate at room temperatures, a fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliances, and office appliances.

The disclosed metal complexes, devices, and methods can be further understood through the following numbered paragraphs.
Paragraph 1. A metal complex having a structure of:

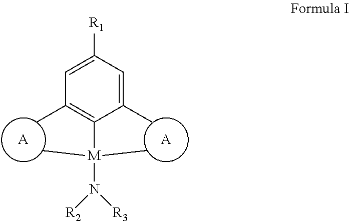

wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) R₁ is

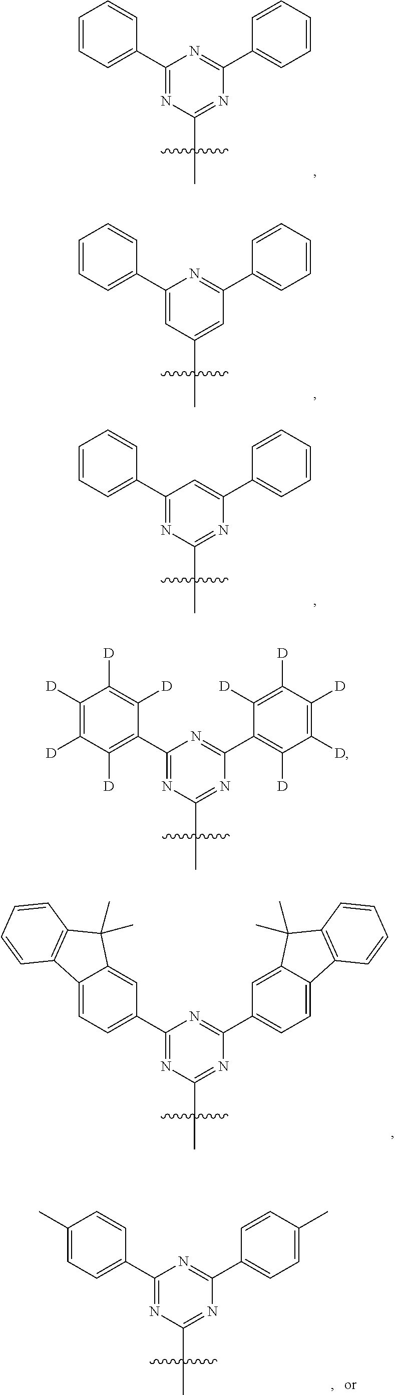

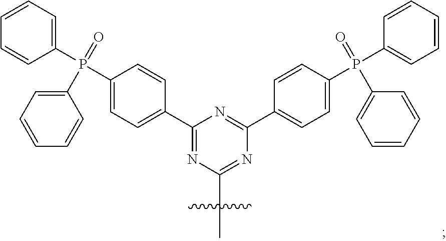 [SMILES: *c1nc(-c2ccc(P(=O)(c3ccccc3)c3ccccc3)cc2)nc(-c2ccc(P(=O)(c3ccccc3)c3ccccc3)cc2)n1]

(iv) R₂ and R₃ are independently a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
   R₂ and R₃ together with the nitrogen atom to which they are attached form a fused ring system; and
(v) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.
Paragraph 2. The metal complex of paragraph 1, having a structure of:

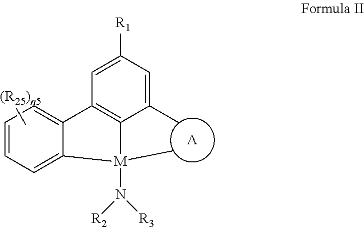

wherein: n5 is an integer from 0 to 4, from 0 to 3, from 0 to 2, or 0 or 1; each occurrence of R₂₅ is independently hydrogen, deuterium, an unsubstituted C₁-C₆ alkyl,

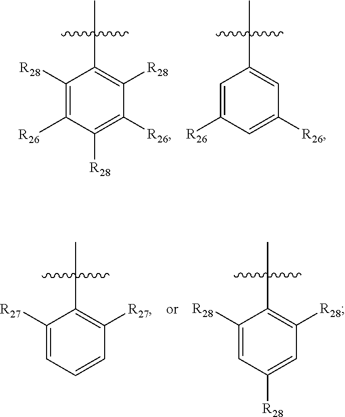

and each R₂₆, R₂₇, and R₂₈ is independently hydrogen, deuterium, or an unsubstituted C₁-C₁₂ alkyl.
Paragraph 3. The metal complex of paragraph 1 or 2, wherein R₁ is

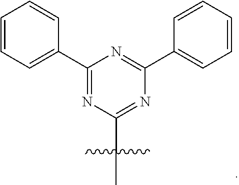 [SMILES: *c1nc(-c2ccccc2)nc(-c2ccccc2)n1]

Paragraph 4. The metal complex of paragraph 1 or 3, having a structure of:

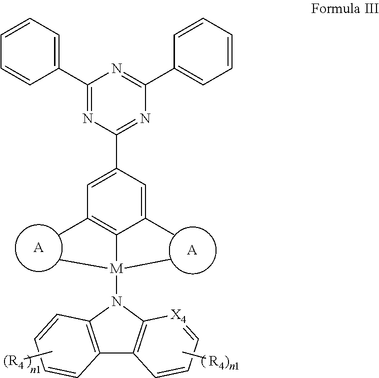

wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) X₄ is C or N;
(iv) each n1 is independently an integer from 0 to 4, from 0 to 3, from 0 to 2, or 0 or 1;
(v) each occurrence of R₄ is independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
   two neighboring R₄ together with the carbon atom to which they are attached form a fused ring system;
(vi) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.
Paragraph 5. The metal complex of paragraph 4, having a structure of:

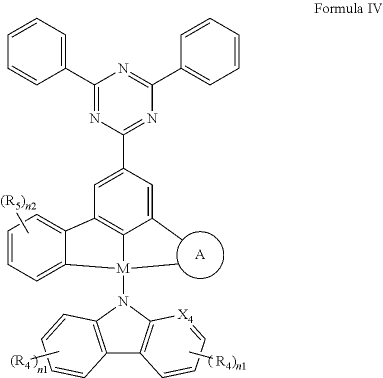

wherein: n2 is an integer from 0 to 4, from 0 to 3, from 0 to 2, or 0 or 1; each occurrence of R₅ is independently hydrogen, deuterium, an unsubstituted C₁-C₆ alkyl,

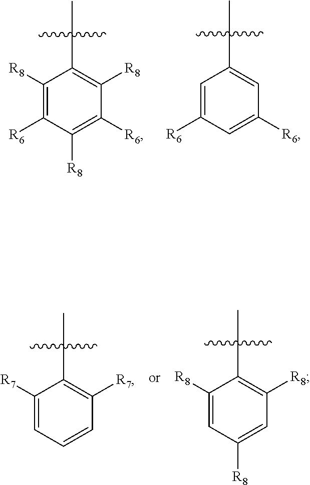

and each R₆, R₇, and R₈ is independently hydrogen, deuterium, or an unsubstituted C₁-C₁₂ alkyl.
Paragraph 6. The metal complex of paragraph 1 or 3, having a structure of:

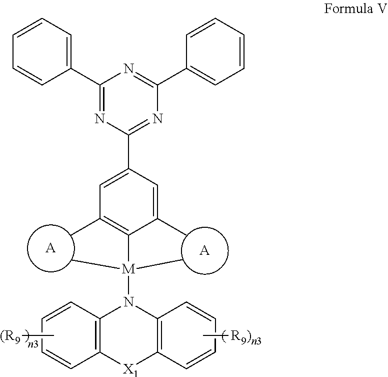

wherein:
(i) M is Pt, Pd, or Au;
(ii) each \textcircled{A}is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) each n3 is independently an integer from 0 to 4, from 0 to 3, from 0 to 2, or 0 or 1;
(iv) each occurrence of R₉ is independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
   two neighboring R₉ together with the carbon atom to which they are attached form a fused ring system;
(v) X₁ is —CR₁₀R₁₁, —C═R₁₂, O, S, or Se;
(vi) R₁₀ and R₁₁ are independently hydrogen, deuterium, a substituted alkyl, an unsubstituted alkyl, a substituted aryl (e.g., a substituted phenyl), an unsubstituted aryl (e.g., an unsubstituted phenyl), or a substituted heteroaryl;
(vii) R₁₂ is O, S or Se; and
(viii) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.
Paragraph 7. The metal complex of paragraph 6, having a structure of:

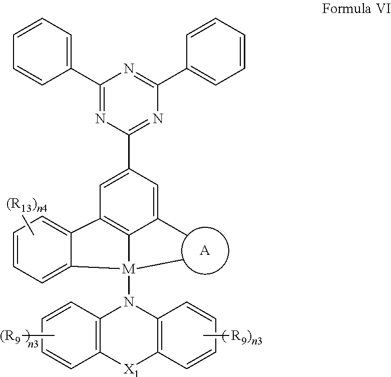

wherein: n4 is an integer from 0 to 4, from 0 to 3, from 0 to 2, or 0 or 1; each occurrence of R₁₃ is independently hydrogen, deuterium, an unsubstituted C₁-C₆ alkyl,

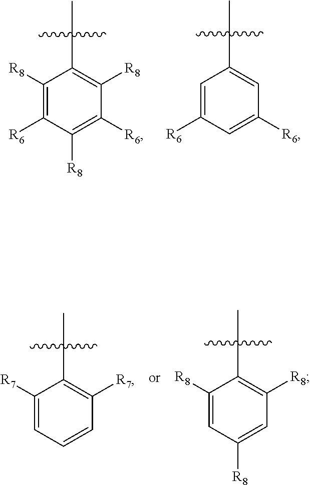

and each R₆, R₇, and R₈ is independently hydrogen, deuterium, or an unsubstituted C₁-C₁₂ alkyl.
Paragraph 8. The metal complex of paragraph 1 or 3, having a structure of:

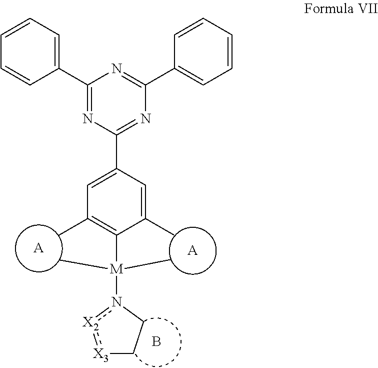

wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) X₂ and X₃ are independently —CR₁₅R₁₆, —C═R₁₇, N, O, or S;
(vi) R₁₅ and R₁₆ are independently hydrogen, deuterium, substituted alkyl, an unsubstituted alkyl, a substituted aryl (e.g., a substituted phenyl), an unsubstituted aryl (e.g., an unsubstituted phenyl), or a substituted heteroaryl;
(vii) R₁₇ is O or S;
(iii) B, when present, together with the carbon atoms to which it is attached, form a substituted aryl or an unsubstituted aryl;
(iv) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.
Paragraph 9. The metal complex of paragraph 1 or 3, having a structure of:

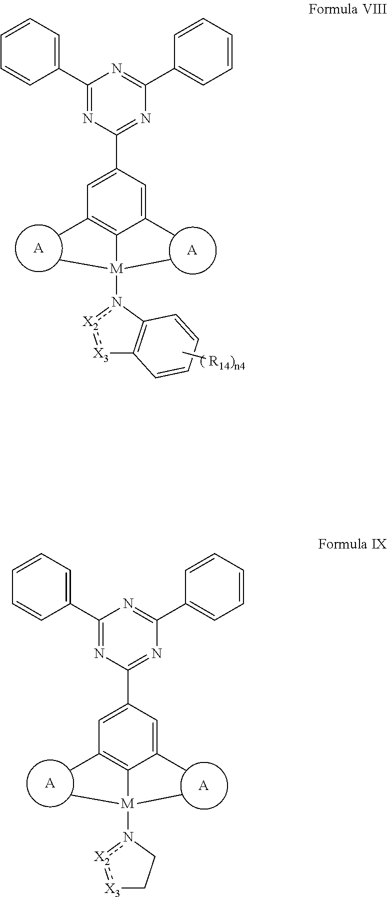

wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) X₂ and X₃ are independently —CR₁₅R₁₆, —C═R₁₇, N, O, or S;
(vi) R₁₅ and R₁₆ are independently hydrogen, deuterium, a substituted alkyl, an unsubstituted alkyl, a substituted aryl (e.g., a substituted phenyl), or an unsubstituted aryl (e.g., an unsubstituted phenyl);
(vii) R₁₇ is O or S;
(iii) n4 is independently an integer from 0 to 4, from 0 to 3, from 0 to 2, or 0 or 1;
(iv) each occurrence of R₁₄ is independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
   two neighboring R₁₄ together with the carbon atom to which they are attached form a fused ring system;
(v) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.
Paragraph 10. The metal complex of paragraph 8 or 9, wherein X₂ and X₃ are independently —CR₁₅R₁₆ or N; and R₁₅ and R₁₆ are independently hydrogen, deuterium, an unsubstituted alkyl, or an unsubstituted aryl (e.g., an unsubstituted phenyl).
Paragraph 11. The metal complex of paragraph 1 or 3, wherein R₂ and R₃ are independently a substituted alkyl, an unsubstituted alkyl, a substituted aryl (e.g., a substituted phenyl), or an unsubstituted aryl (e.g., an unsubstituted phenyl).
Paragraph 12. The metal complex of any one of paragraphs 1-11, wherein each

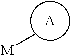

is

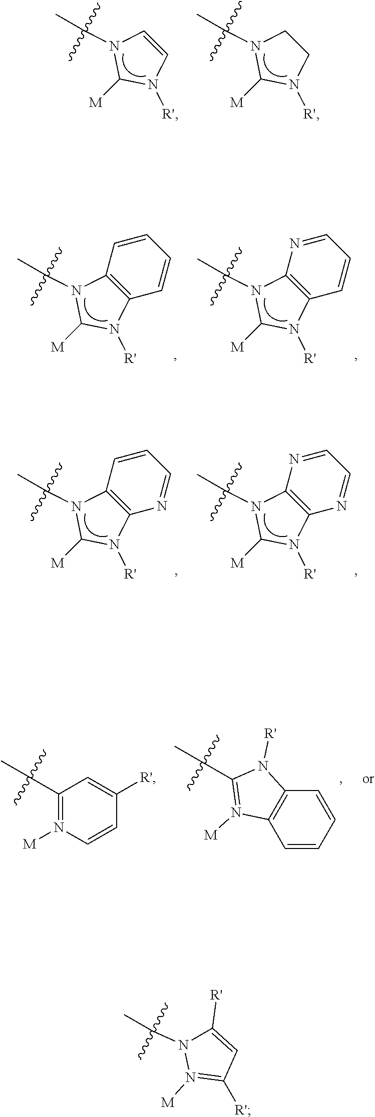

each R′ is independently a substituted C₁-C₆ alkyl, an unsubstituted C₁-C₆ alkyl, a substituted aryl, or an unsubstituted aryl; and the substituent(s), when present, are independently an unsubstituted C₁-C₁₂ alkyl.
Paragraph 13. The metal complex of any one of paragraphs 1-12, wherein each

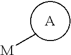

is

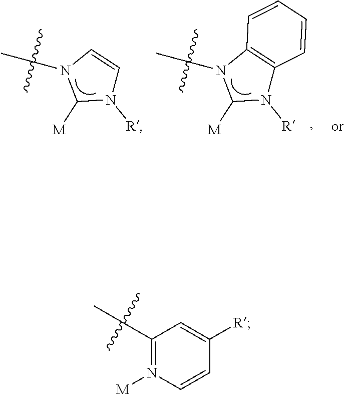

each R′ is independently a substituted C₁-C₆ alkyl, an unsubstituted C₁-C₆ alkyl, a substituted aryl, or an unsubstituted aryl; and the substituent(s), when present, are independently a deuterium or an unsubstituted C₁-C₁₂ alkyl.
Paragraph 14. The metal complex of paragraph 12 or 13, wherein each R′ is independently hydrogen, deuterium, an unsubstituted C₁-C₆ alkyl,

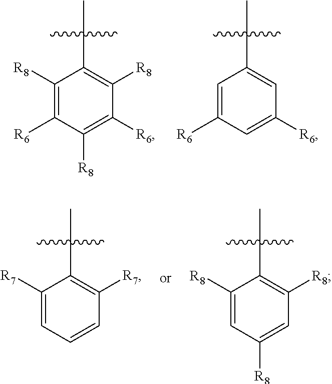

and each R₆, R₇, and R₈ is independently hydrogen, deuterium, or an unsubstituted C₁-C₁₂ alkyl.
Paragraph 15. The metal complex of any one of paragraphs 12-14, wherein each R′ is independently

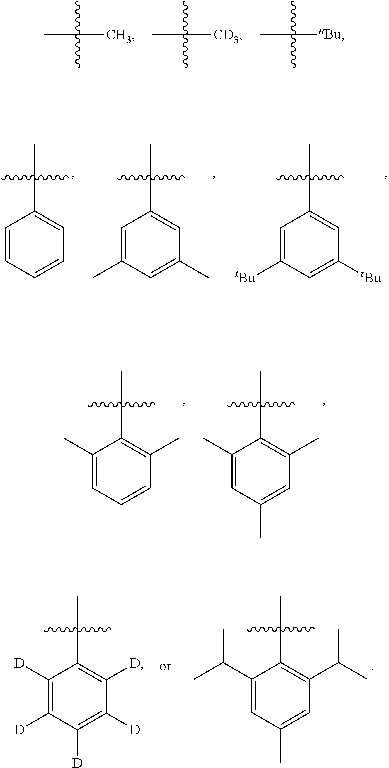

Paragraph 16. The metal complex of paragraph 1, having any one of the following structures:

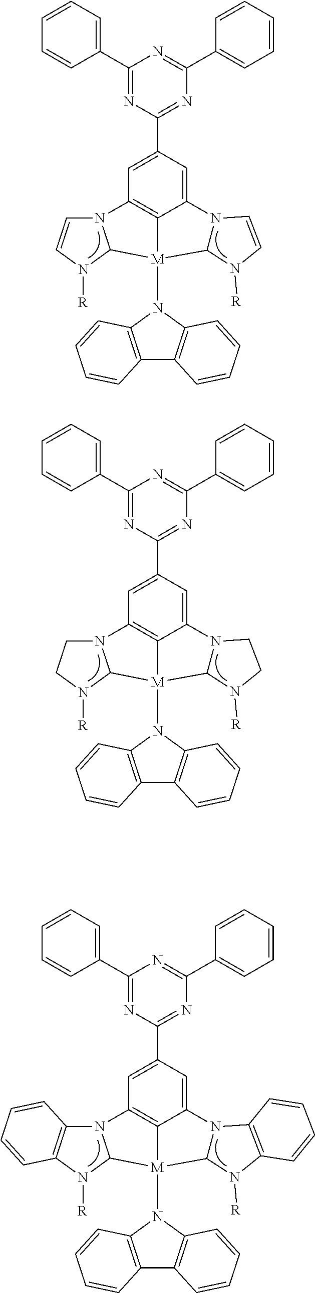

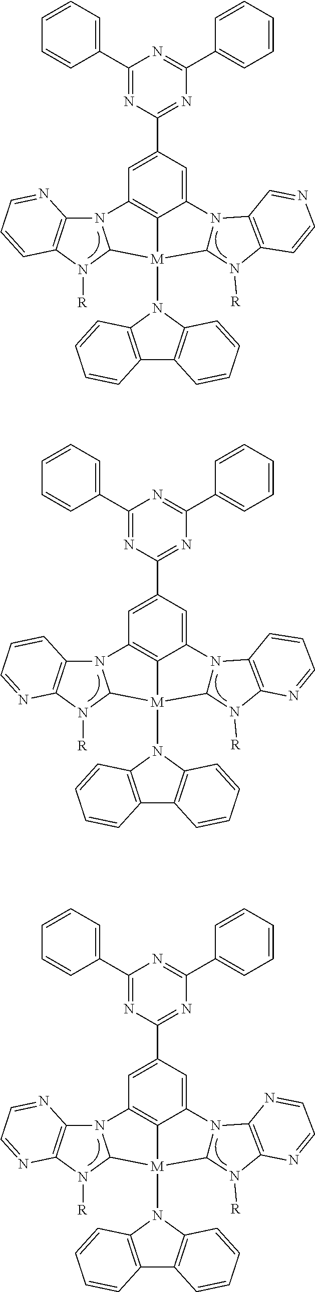

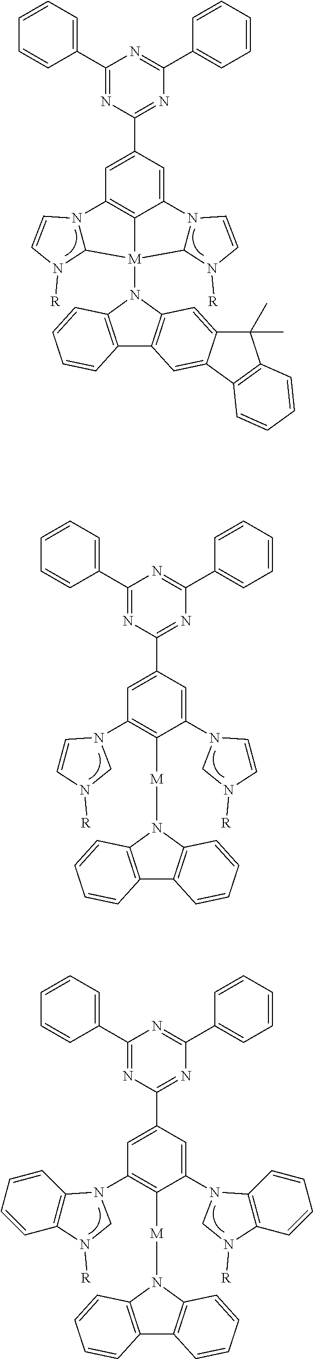

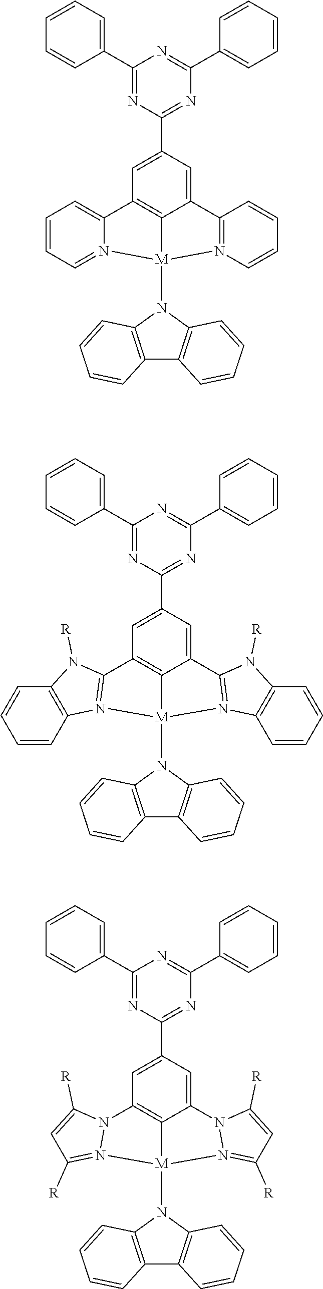

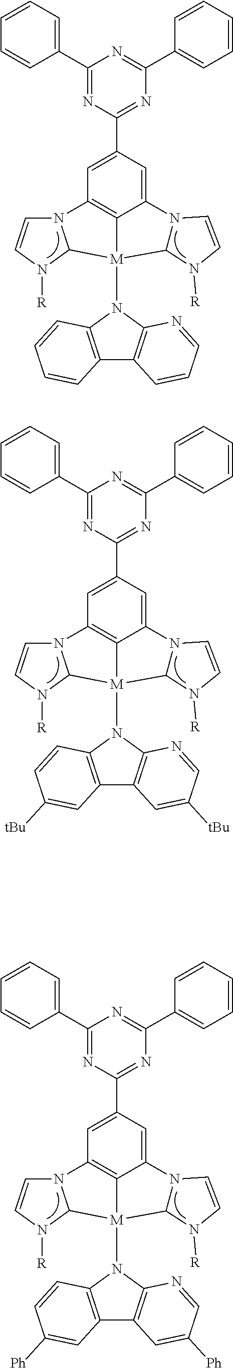

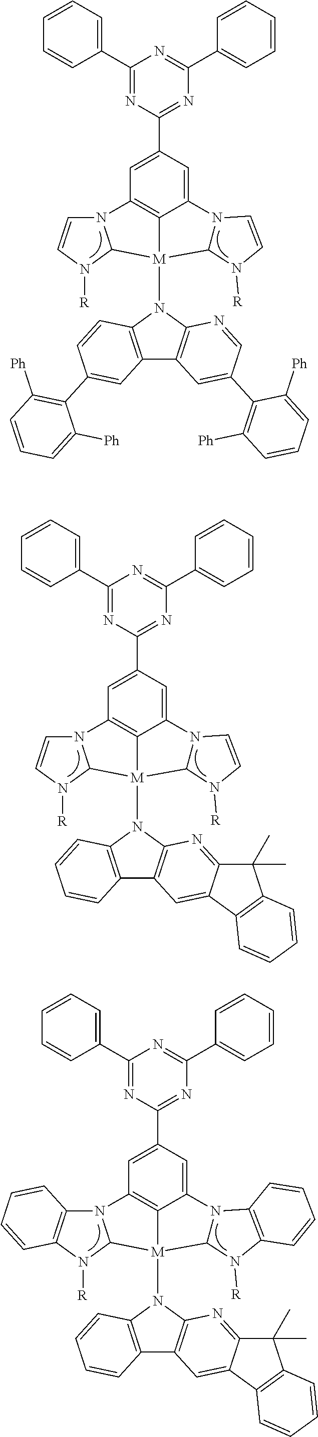

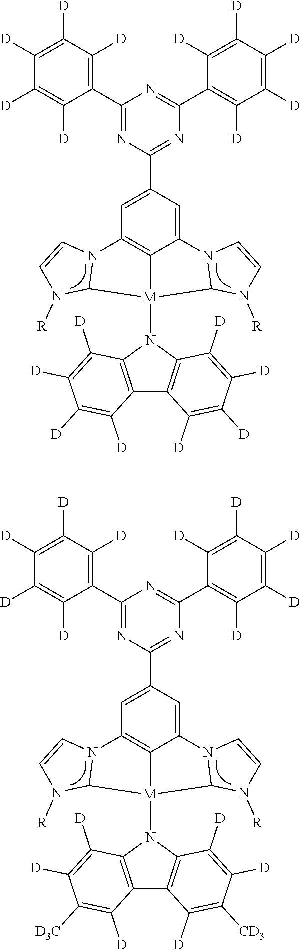

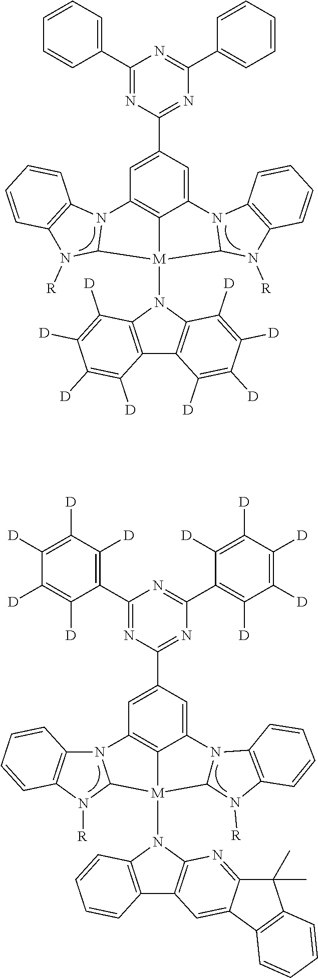

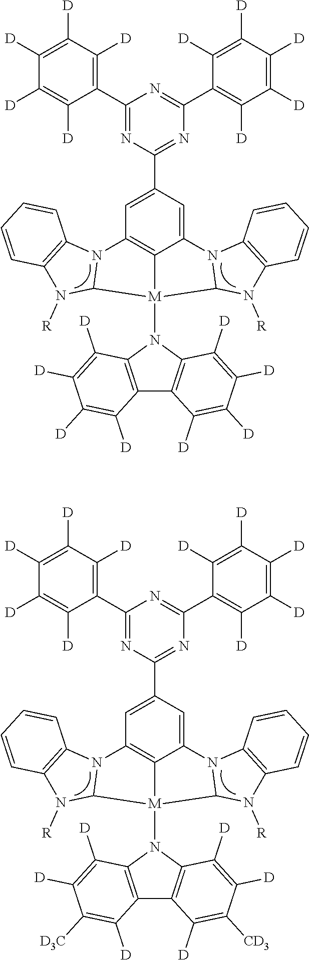

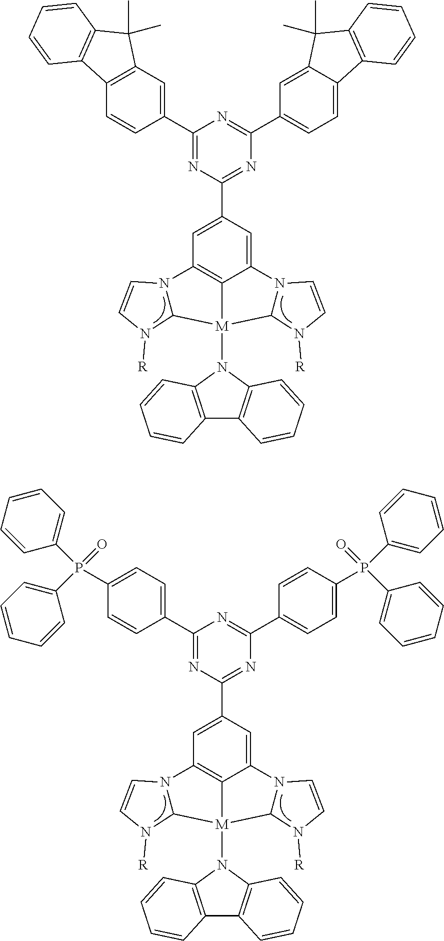

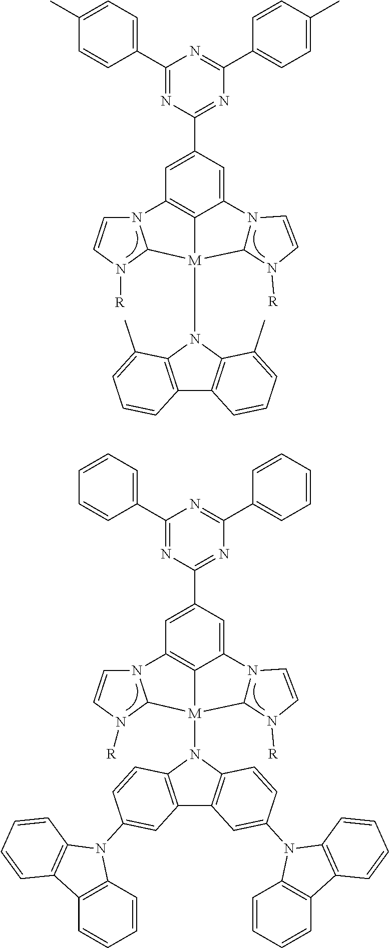

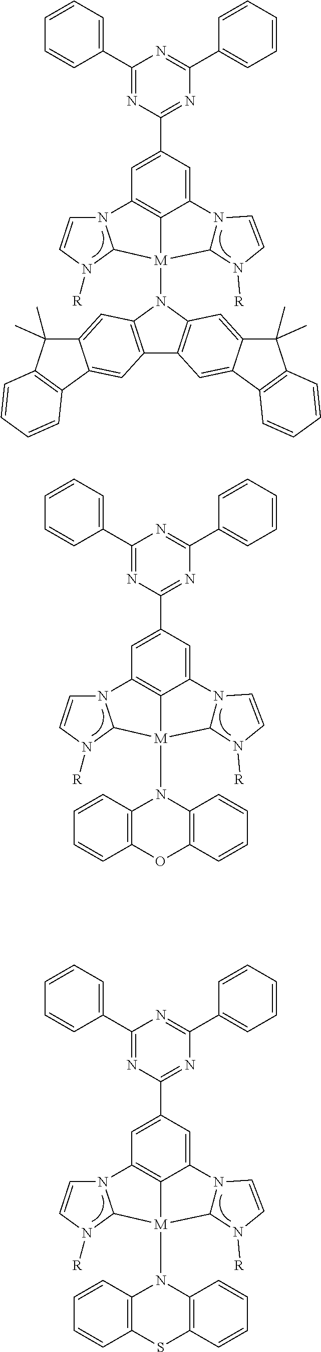

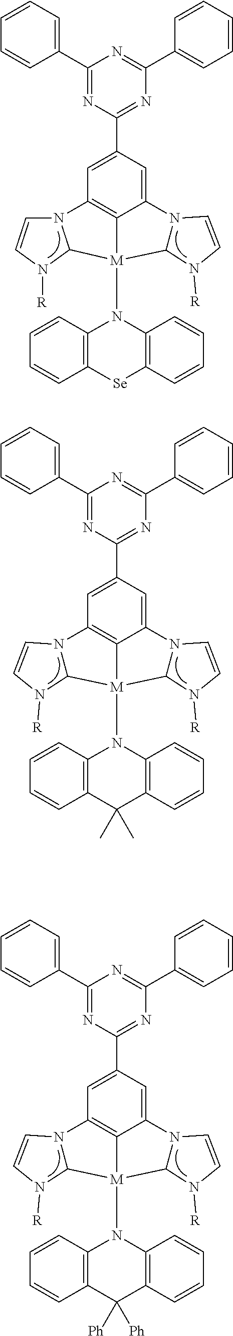

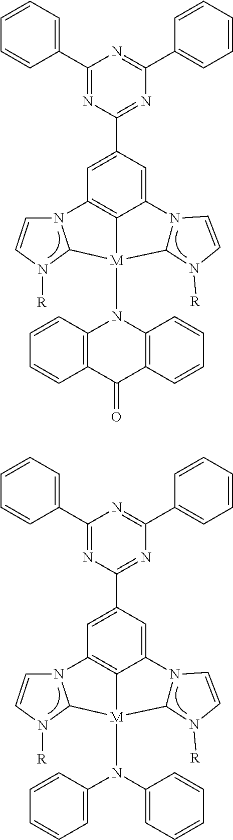

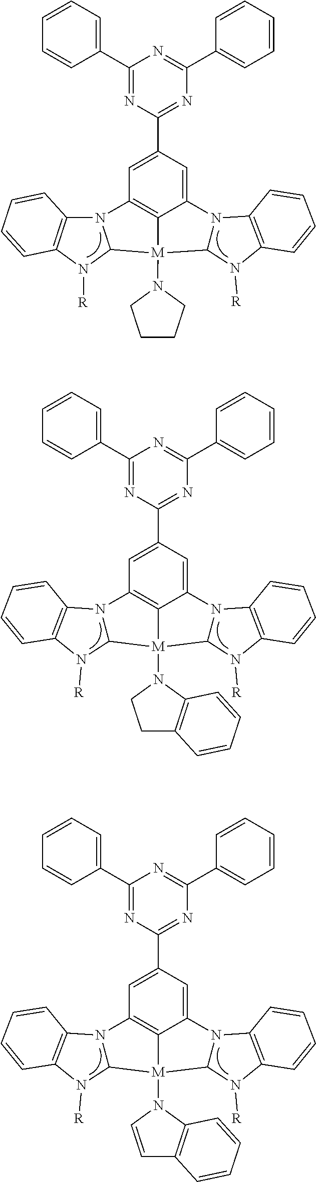

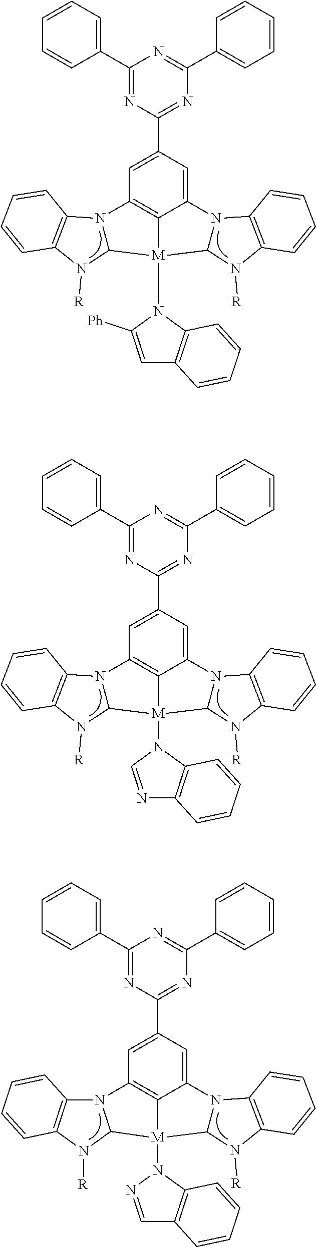

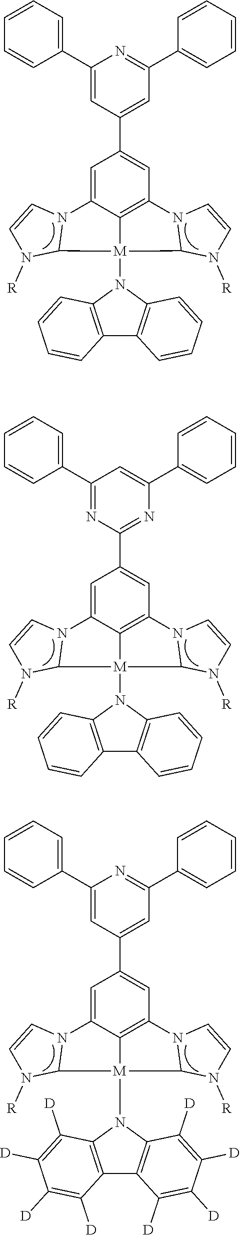

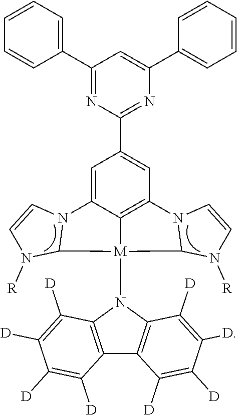

wherein M is Pt, Pd, or Au; each R is independently a substituted C₁-C₆ alkyl, an unsubstituted C₁-C₆ alkyl, a substituted phenyl, or an unsubstituted phenyl; and the substituent(s), when present, are independently an unsubstituted C₁-C₁₂ alkyl.
Paragraph 17. The metal complex of paragraph 16, wherein each R is independently an unsubstituted C₁-C₆ alkyl,

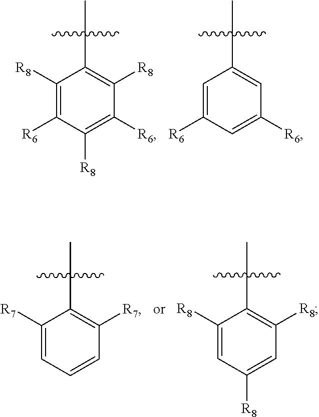

and each R₆, R₇, and R₈ is independently hydrogen, deuterium, or an unsubstituted C₁-C₁₂ alkyl.
Paragraph 18. The metal complex of paragraph 16 or 17, wherein each R is independently

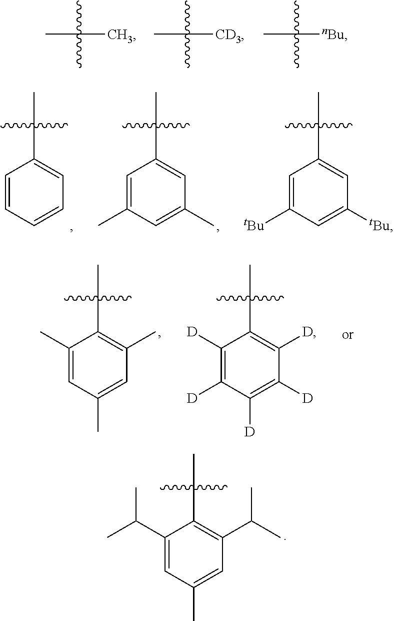

Paragraph 19. The metal complex of any one of paragraphs 16-18, having a structure of:

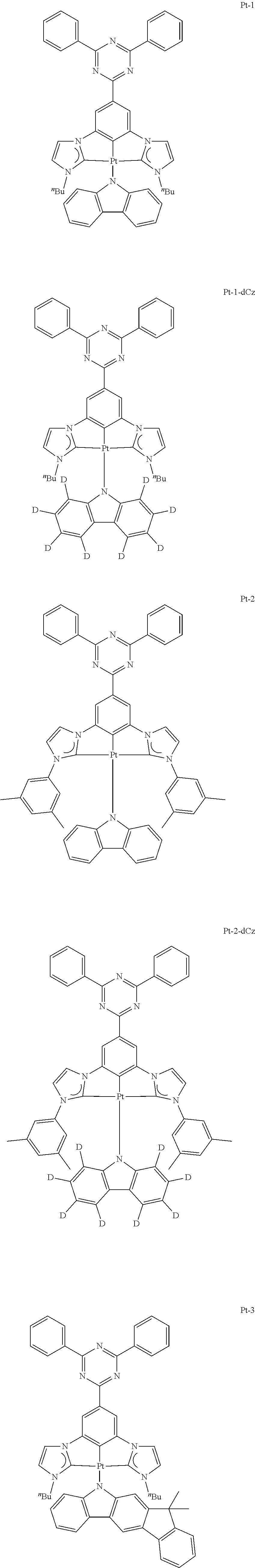

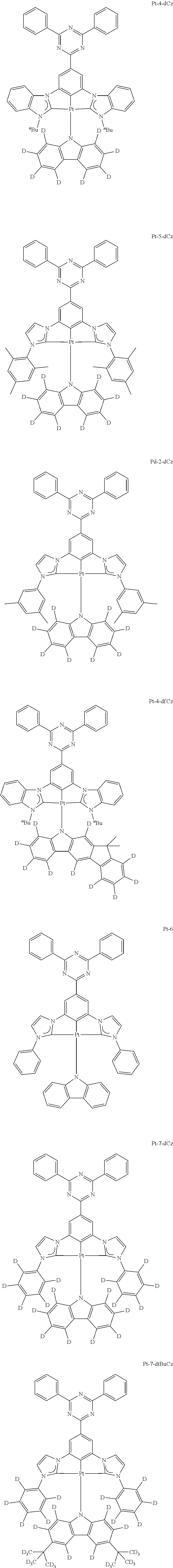

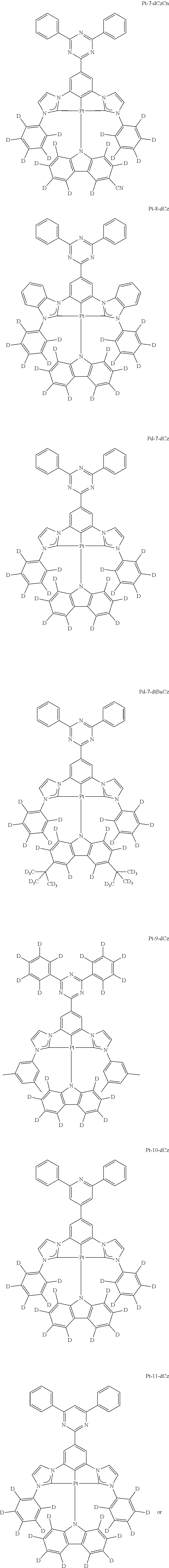

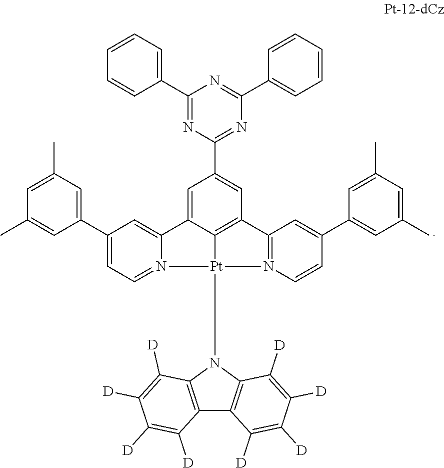

Paragraph 20. The metal complex of paragraph 1, having any one of the following structures:

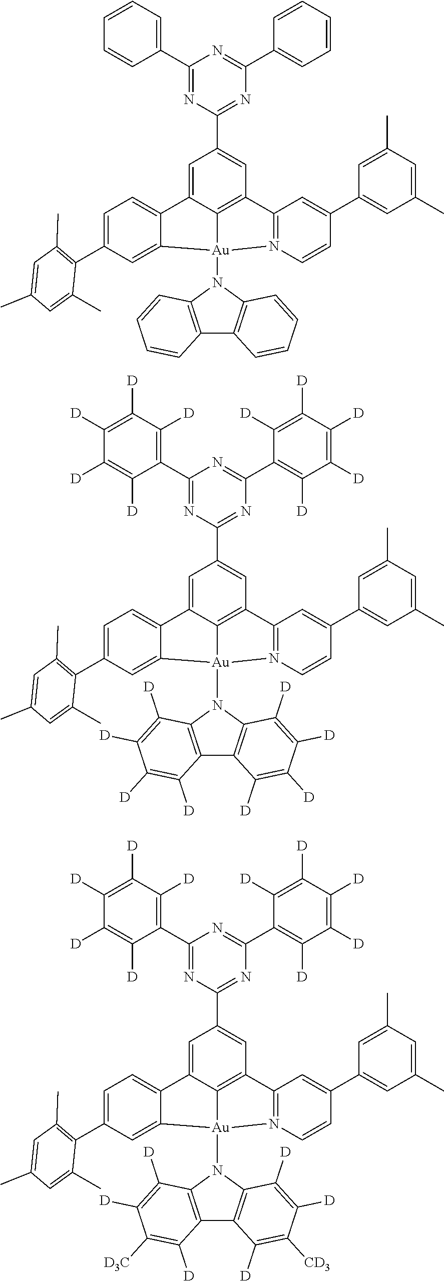

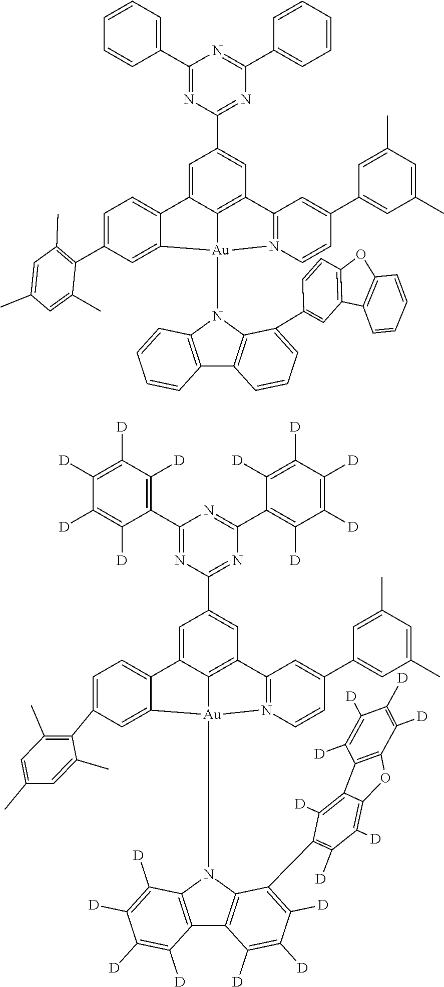

Paragraph 21. The metal complex of any one of paragraphs 1-20, having a maximum emission wavelength (λₘₐₓ) in a range from 540 nm to 660 nm or from 560 nm to 625 nm.
Paragraph 22. The metal complex of any one of paragraphs 1-21, having an emission quantum yield (Φₑₘ) of at least 50%, at least 55%, at least 60%, at least 65%, at least 70%, at least 75%, at least 80%, at least 85%, in a range from 50% to 90%, from 55% to 90%, from 60% to 90%, from 65% to 90%, or from 70% to 90%, measured in films, at room temperature.
Paragraph 23. The metal complex of any one of paragraphs 1-22, having an emission lifetime (τₑₘ) of <2.5 μs, 2.3 μs, 2.0 μs, <1.5 μs, <1.3 μs, in a range from 0.3 μs to 2.5 μs, from 0.3 μs to 2.3 μs, from 0.3 μs to 2.0 μs, from 0.3 μs to 1.5 μs, or from 0.3 μs to 1.3 μs, measured in films, at room temperature.
Paragraph 24. The metal complex of any one of paragraphs 1-23, having a radiative decay rate constant (kᵣ) of at least 5.5×10⁵ s⁻¹, at least 6.0×10⁵ s⁻¹, at least 8.0×10⁵ s⁻¹, at least 1.0×10⁶ s⁻¹, in a range from 5.5×10⁵ s⁻¹ to 1.6×10⁶ s⁻¹, measured in films, at room temperature.
Paragraph 25. An organic light-emitting component comprising a light-emitting layer or two or more light-emitting layers, wherein the light-emitting layer or each light-emitting layer of the two or more light-emitting layers comprises one or more metal complex of any one of paragraphs 1-24.
Paragraph 26. The organic light-emitting component of paragraph 25, wherein the total concentration of the one or more metal complexes in the light-emitting layer or each light-emitting layer of the two or more light-emitting layers is from about 1 wt % to about 20 wt %, from about 1 wt % to about 10 wt %, from about 2 wt % to about 20 wt %, from about 2 wt % to about 16 wt %, from about 2 wt % to about 10 wt %, or from about 2 wt % to about 8 wt %, such as about 2 wt %, about 4 wt %, about 6 wt %, or about 8 wt %.
Paragraph 27. The organic light-emitting component of paragraph 25 or 26 further comprising an anode, a cathode, a hole transport region, and an electron transport region,
   wherein the hole transport region comprises a hole injection layer and/or a hole transport layer, and optionally an electron blocking layer,
   wherein the electron transport region comprises an electron transport layer and/or an electron injection layer, and optionally a hole blocking layer,
   wherein the light emitting layer is located in between the anode and the cathode,
   wherein the hole transport region is located in between the anode and the light-emitting layer, and
   wherein the electron transport region is located in between the cathode and the light emitting layer.
Paragraph 28. The organic light-emitting component of any one of paragraphs 25-27, wherein the organic light-emitting component emits light at λₘₐₓ in a range from 530 nm to 660 nm or from 540 nm to 600 nm, such as from 554 nm to 637 nm or from 541 nm to 599 nm.
Paragraph 29. The organic light-emitting component of any one of paragraphs 25-28, wherein the organic light-emitting component has a maximum quantum efficiency (EQE) of at least 12%, at least 15%, in a range from 12% to 30%, from 12% to 25%, from 15% to 30%, from 15% to 25%, or from 20% to 30%, such as about 25.5% or about 21.4%.
Paragraph 30. The organic light-emitting component of any one of paragraphs 25-29, wherein the organic light-emitting component has a LT₉₅ of at least 1000 hours, at least 2000 hours, at least 3000 hours, at least 4000 hours, at least 5000 hours, in a range from 1000 cd m⁻² to 7500 cd m⁻², from 1000 cd m⁻² to 7000 cd m⁻², from 1000 cd m⁻² to 6000 cd m⁻², from 2000 cd m⁻² to 7500 cd m⁻², from 2000 cd m⁻² to 7000 cd m⁻², from 2000 cd m⁻² to 6000 cd m⁻², from 3000 cd m⁻² to 7500 cd m⁻², from 3000 cd m⁻² to 7000 cd m⁻², from 3000 cd m⁻² to 6000 cd m⁻², from 4000 cd m⁻² to 7500 cd m⁻², from 4000 cd m⁻² to 7000 cd m⁻², or from 4000 cd m⁻² to 6000 cd m⁻², at 1000 cd m⁻², such as about 7300 hours or about 6660 hours, at 1000 cd m⁻².
Paragraph 31. The organic light-emitting component of any one of paragraphs 25-30, wherein the light emitting layer or one or more light-emitting layers of the two or more light-emitting layers (such as each light-emitting layer) further comprises an organic dye, and optionally wherein the one or more metal complex(es) act(s) as a sensitizer to transfer energy to the organic dye.
Paragraph 32. The organic light-emitting component of any one of paragraphs 25-31, wherein the organic light-emitting component is an organic light-emitting diode (“OLED”) or a light-emitting electrochemical cell (“LEEC”).
Paragraph 33. The organic light-emitting component of any one of paragraphs 25-32, wherein the light-emitting layer or each light-emitting layer of the two or more light-emitting layers is formed by vacuum-evaporation deposition, spin-coating, ink-printing, or roll-to-roll printing.
Paragraph 34. A device comprising one or more organic light-emitting components of any one of paragraphs 25-33, wherein the device is a stationary visual display unit, a mobile visual display unit, an illumination device, a wearable device, a phototherapy device, or a medical monitoring device.

The present invention will be further understood by reference to the following non-limiting examples.

### EXAMPLES

### Example 1. Synthesis of Exemplary Pt(II) and Pd(II) Complexes

### Materials and Methods

The chemical reagents used for synthesis were purchased from commercial sources such as Dieckmann, Tiv Scientific, J & K Scientific, BLDpharm, Bidepharm, Strem Chemicals. They were directly used without further processing. The solvents used for synthesis were purchased from Duksan, RCI Labscan, Scharlau, etc. They were directly used without further processing. ¹H and ¹³C NMR spectra were recorded on DPX-400, DPX-500 or DPX-600 Bruker FT-NMR spectrometer. The chemical shift of proton or carbon signals are calibrated by the corresponding solvent residual signals.

### Synthesis of Phadim

Imidazole (1.50 g, 22 mmol), phadf (1.90 g, 22 mmol) and K₃PO₄ (4.66 g, 22 mmol) were mixed and dissolved in 100 mL DMF (Dimethylformamide). The solution was heated at 150° C. for 48 h. When the reaction mixture was cooled down to room temperature, the DMF was removed by distillation under low pressure to get an off-white solid and purified by column chromatography on silica gel with CH₂Cl₂/MeOH (10:1) as an eluent to obtain a white solid. Yield: 2.06 g (85%). ¹H NMR (500 MHz, Chloroform-d) δ 8.82 (d, J=2.1 Hz, 2H), 8.79-8.75 (m, 4H), 8.13 (s, 2H), 7.70-7.65 (m, 3H), 7.65-7.59 (m, 4H), 7.52-7.48 (m, 2H), 7.35 (t, J=1.1 Hz, 2H).

### Synthesis of Phadimb

The phadim (0.88 g, 2 mmol) and 1-bromobutane (2.74 g, 20 mmol) in 50 mL DMF was refluxed at 150° C. for 48 h. When the reaction mixture was cooled down to room temperature, the DMF was removed by distillation under low pressure to get an oily solid. Then NH₄PF₆ (1.63 g, 10 mmol), 25 mL MeOH and 25 mL H₂O was added, and stirred for 3 h at room temperature. The mixture was filtered and washed with diethyl ether to get white solid. Yield: 1.55 g (92%). ¹H NMR (500 MHz, DMSO-d₆) δ 10.11 (s, 2H), 9.23 (d, J=2.1 Hz, 2H), 8.91-8.85 (m, 4H), 8.58 (s, 1H), 8.56-8.53 (m, 2H), 8.19 (t, J=1.8 Hz, 2H), 7.78 (t, J=7.2 Hz, 2H), 7.71 (t, J=7.5 Hz, 4H), 4.37 (t, J=7.3 Hz, 4H), 1.94 (p, J=7.4 Hz, 4H), 1.40 (h, J=7.5 Hz, 4H), 0.98 (t, J=7.4 Hz, 6H). A synthetic scheme for conversion for phadimb is provided below.

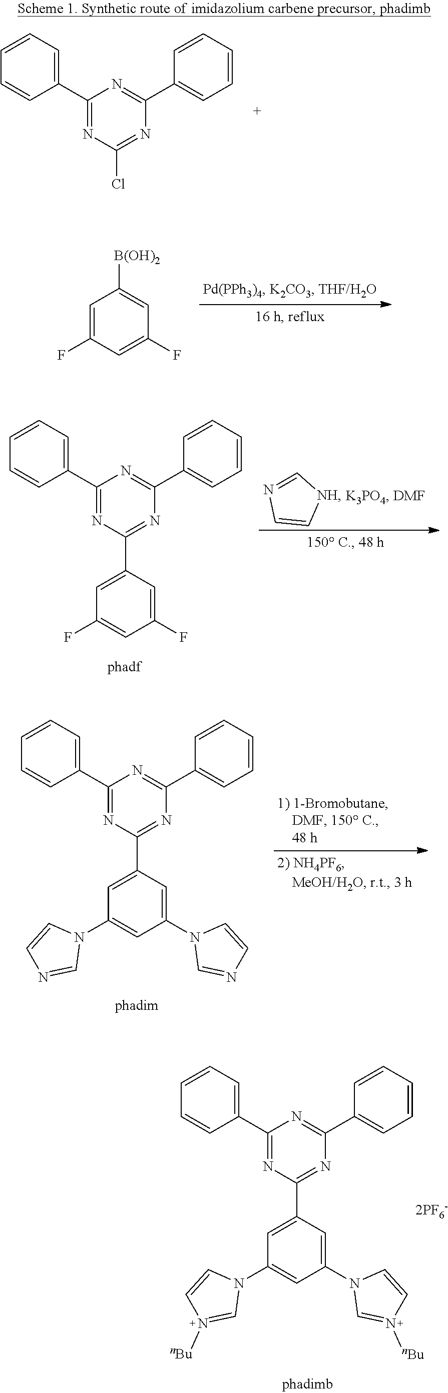

### Synthesis of PhadimAr

The phadim (0.66 g, 1.5 mmol), (3,5-dimethylphenyl)(mesityl)iodonium (3.75 g, 7.5 mmol) and copper (II) acetate (19 mg, 0.1 mmol) were mixed and dissolved in 50 mL DMF at 130° C. After 20 h the reaction was removed from the heat and passed through Celite. The solvent was removed under reduced pressure resulting in brown oil. Then 50 mL diethyl ether was added and the mixture was stirred at room temperature for 1 h to form a solid and precipitate gradually. And then filtered and washed with excess diethyl ether, and dried under reduced pressure to get a white solid. Yield: 1.03 g (72%). ¹H NMR (400 MHz, DMSO-d₆) δ 10.66 (t, J=1.6 Hz, 2H), 9.41 (d, J=2.1 Hz, 2H), 8.95-8.88 (m, 4H), 8.78 (t, J=1.9 Hz, 2H), 8.76 (t, J=2.1 Hz, 1H), 8.71 (t, J=1.9 Hz, 2H), 7.81-7.76 (m, 2H), 7.75-7.69 (m, 4H), 7.63 (s, 4H), 7.35 (s, 2H), 2.46 (s, 12H). The synthesis scheme for phadimAr is provided below as Scheme 2.

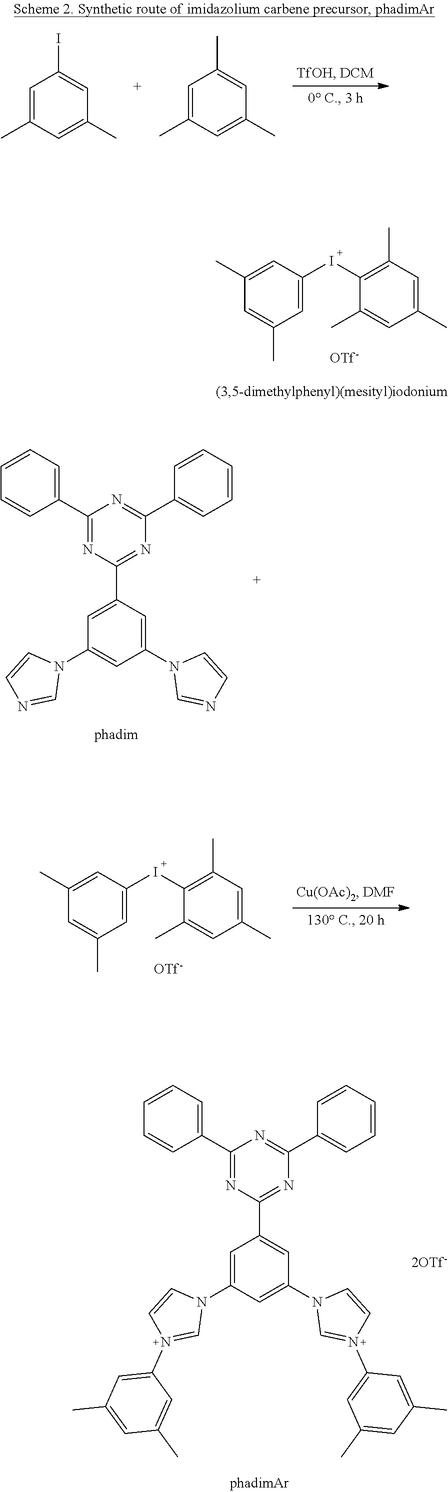

Synthesis of tatmN

Tris(dibenzylideneacetone)dipalladium (1.10 g, 1.20 mmol), DPEPhos (1.94 g, 3.60 mmol), tBuONa (2.88 g, 30 mmol), phadbr (2.80 g, 6 mmol) and tmNH (2.98 g, 13.2 mmol) were added to a flame-dried flask. Under argon, 100 mL dry toluene was added. After stirring at 100° C. for 18 h, the mixture was allowed to cool to room temperature. The toluene was evaporated, and the residue was purified by column chromatography on silica gel, eluting with hexanes/ethyl acetate (10:1) to get a yellow-green solid. Yield: 1.63 mg (36%). ¹H NMR (400 MHz, Chloroform-d) δ 8.74-8.68 (m, 4H), 7.79 (d, J=2.1 Hz, 2H), 7.62-7.51 (m, 6H), 7.30-7.26 (m, 2H), 7.02-6.95 (m, 2H), 6.89 (s, 4H), 6.77 (td, J=7.5, 1.4 Hz, 2H), 6.54 (s, 1H), 6.28 (dd, J=8.0, 1.4 Hz, 2H), 5.54 (s, 4H), 2.28 (s, 6H), 2.12 (s, 12H).

### Synthesis of Tabitmp

The tatmN (1.24 g, 1.62 mmol) was dissolved in 10 mL triethyl orthoformate. Concentrated hydrochloric acid (37% w/w, 0.45 mL, 4.86 mmol) was added, which resulted in the formation of a white suspension. The mixture was stirred at 80° C. for 30 minutes. The reaction mixture was cooled to room temperature and diluted with 50 mL diethyl ether, and then filtered and washed with excess diethyl ether to get an off-white solid. Yield: 0.99 g (72%). ¹H NMR (400 MHz, DMSO-d₆) δ 10.88 (s, 2H), 9.62 (d, J=2.0 Hz, 2H), 9.11 (s, 1H), 8.88-8.81 (m, 4H), 8.39 (d, J=8.4 Hz, 2H), 7.95-7.89 (m, 2H), 7.87-7.81 (m, 2H), 7.79-7.74 (m, 2H), 7.73-7.62 (m, 6H), 7.33 (s, 4H), 2.44 (s, 6H), 2.17 (s, 12H). The synthesis scheme for tabitmp is provided below as Scheme 3.

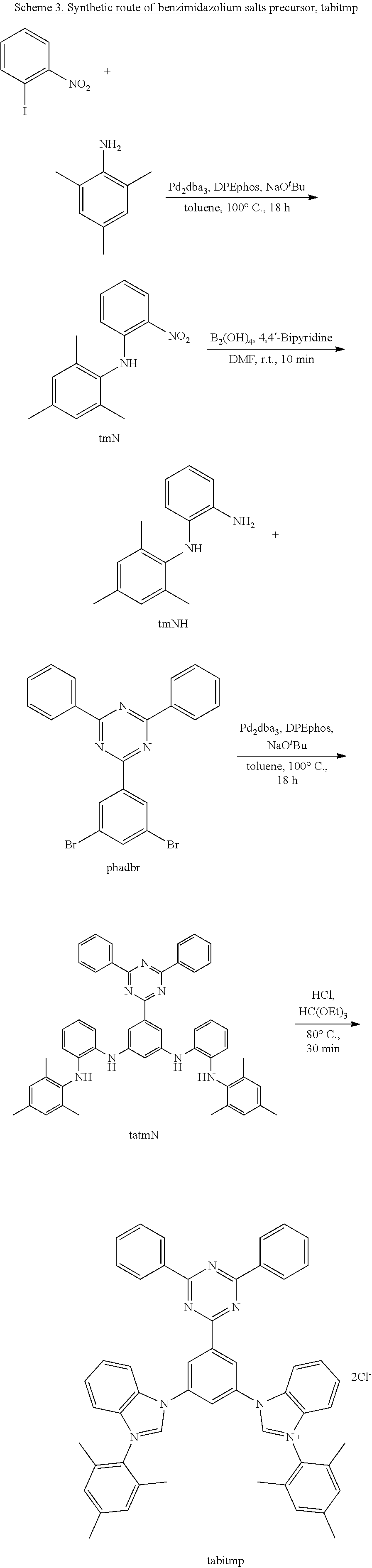

### Synthesis of (3,5-dimethylphenyl)(mesityl)iodonium

meta-chloroperoxybenzoic acid (11.4 g, 66 mmol) was dissolved in 300 mL dichloromethane in a round bottom flask. Then 1-iodo-3,5-dimethylbenzene (13.9 g, 60 mmol) and mesitylene (7.9 g, 66 mmol) were added to the mixture. Then, trifluoromethanesulfonic acid (18 g, 12 mmol) was added to the solution dropwise at 0° C., and the solution gradually turned black. When the reaction was stirred at room temperature for 3 h, the solvent was removed by vacuum rotary evaporator to get a black oily solid. Then 100 mL diethyl ether was added and the mixture was stirred at room temperature for 1 h to form a solid and precipitate gradually. And then filtered and washed with excess diethyl ether, and dried under reduced pressure to get a gray solid. Yield: 20.4 g (68%). ¹H NMR (400 MHz, DMSO-d₆) δ 7.64 (s, 2H), 7.27 (s, 1H), 7.21 (s, 2H), 2.61 (s, 6H), 2.29 (s, 3H), 2.28 (s, 6H).

Synthesis of phaCCCPtCl

As depicted in Scheme 4, the C\hat{ }C\hat{ }C—Pt—Cl precursor with imidazolium carbene (phaCCCPtCl) was prepared at room temperature by in situ metalation using Zr(NMe₂)₄, followed by transmetalation. The phadimb (337 mg, 0.4 mmol), Zr(NMe₂)₄ (266 mg, 1 mmol) and 5 mL dry dichloromethane were stirred for 1 h under argon at room temperature to afford a yellow solution. And then Pt(COD)Cl₂ (150 mg, 0.4 mmol) was added, the solution turned orange and the mixture was stirred at room temperature overnight. The resulting mixture was filtered through Celite®. The solvent was removed in vacuum to get a yellow-green solid and purified by column chromatography on silica gel with hexanes/dichloromethane (1:1) as an eluent to obtain a green solid. Yield: 181 mg (58%). ¹H NMR (500 MHz, Methylene Chloride-d₂) δ 8.81-8.74 (m, 4H), 8.33 (t, J=8.4 Hz, 2H), 7.68-7.57 (m, 8H), 7.07 (d, J=2.1 Hz, 2H), 4.72 (t, J=7.4 Hz, 4H), 1.90 (p, J=7.5 Hz, 4H), 1.49 (h, J=7.5 Hz, 4H), 1.00 (t, J=7.4 Hz, 6H).

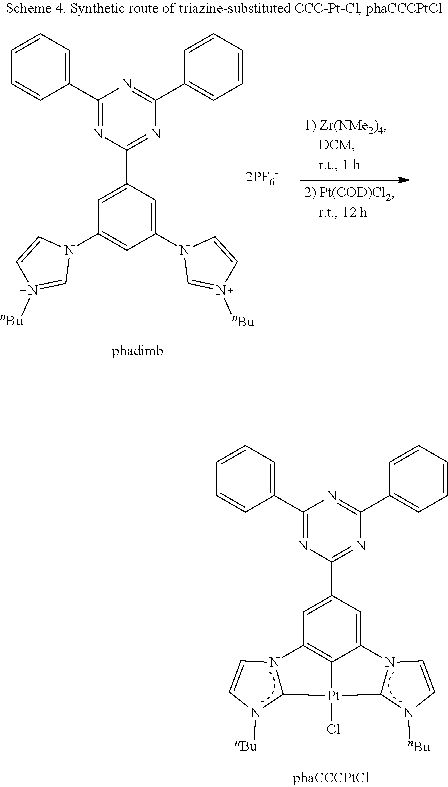

Synthesis of bitmPtCl

For the C\hat{ }C\hat{ }C—Pt—Cl precursor with benzimidazolium carbene (bitmPtCl), a high temperature of 150° C. was needed for the direct metalation process (Scheme 5). The tabitmp (765 mg, 0.9 mmol), PtCl₂ (240 mg, 0.9 mmol) and KOAc (potassium acetate) (351 mg, 3.6 mmol) were added to a round-bottom flask and evacuated and back-filled with argon, followed by the addition of 10 mL dry DMF. The mixture was stirred at 150° C. under argon for 3 days. After cooling to room temperature, the solvent was passed through Celite® and removed under reduced pressure resulting in a black oily solid, and then purified by column chromatography on silica gel, eluting with hexanes/ethyl acetate (1:1) to get a yellow solid. The yield was about 226 mg (25%).

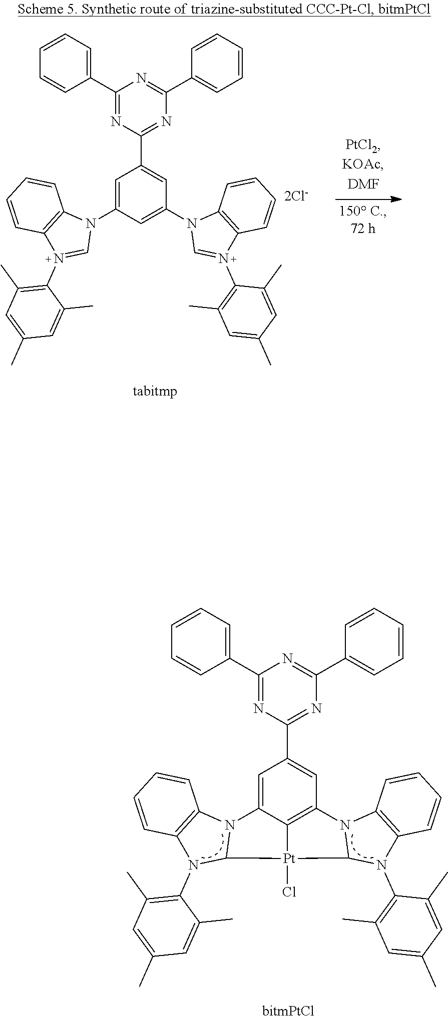

### Synthesis of ArPdCl

Similar to the platinum(II) analogue, the C\hat{ }C\hat{ }C—Pd—Cl precursor with imidazolium carbene (ArPdCl) was prepared at room temperature by in situ metalation using Zr(NMe₂)₄, followed by transmetalation (Scheme 6). The phadimAr (852 mg, 0.9 mmol), Zr(NMe₂)₄ (600 mg, 2.25 mmol) and 10 mL dry dichloromethane were stirred for 1 h under argon at room temperature to afford an orange solution. And then Pd(COD)Cl₂ (257 mg, 0.6 mmol) was added, the solution turned orange-red and the mixture was stirred at room temperature overnight. The resulting mixture was filtered through Celite®. The solvent was removed in vacuum to get an orange-red solid and purified by column chromatography on silica gel with hexanes/ethyl acetate (1:1) as an eluent to obtain an orange solid. The yield was about 200 mg (28%).

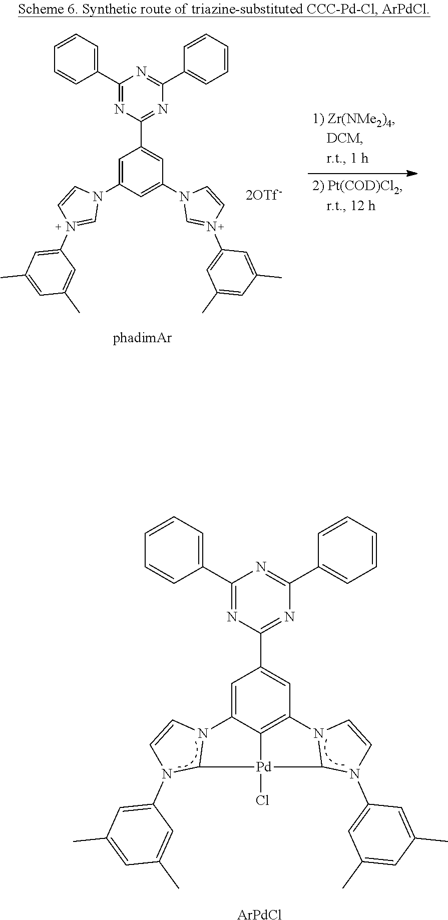

### Synthesis of Pt-1

As shown in Scheme 7, the Pt(II) complex was synthesized by reacting using the C\hat{ }C\hat{ }C—Pt—Cl precursor with the (deuterated or non-deuterated) carbazole in the presence of tBuONa at room temperature. Carbazole (37 mg, 0.22 mmol), tBuONa (38 mg, 0.40 mmol) were dissolved in 10 mL dry THF (tetrahydrofuran) and stirred for 1 h under argon at room temperature. Then the phaCCCPtCl (157 mg, 0.20 mmol) was added and the mixture was stirred at room temperature overnight. The resulting mixture was filtered through Celite®. After removing the solvent in vacuum, a red solid was obtained. The solid was recrystallized from acetone, collected by filtration, and dried under reduced pressure to obtain an orange red solid. The yield was about 132 mg (72%).

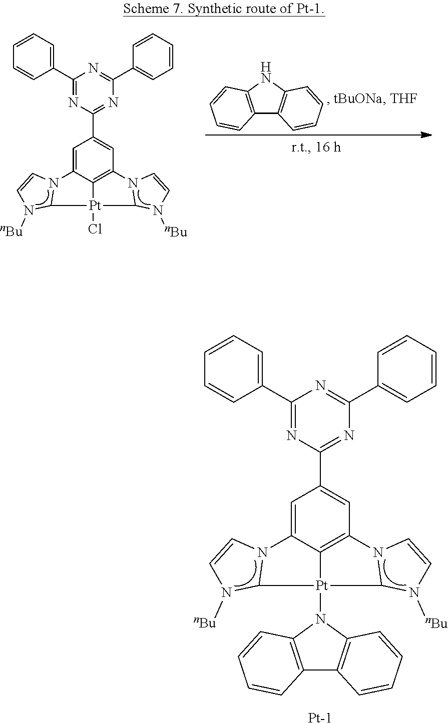

### Synthesis of Pd-2-dCz

As shown in Scheme 8, the exemplary Pd(II) complex was synthesized by reacting using the C\hat{ }C\hat{ }C—Pt—Cl precursor with the (deuterated or non-deuterated) carbazole in the presence of tBuONa at room temperature. Carbazole-d8 (39 mg, 0.22 mmol), tBuONa (38 mg, 0.40 mmol) were dissolved in 10 mL dry THF and stirred for 1 h under argon at room temperature. Then the ArPdCl (158 mg, 0.20 mmol) was added and the mixture was stirred at room temperature overnight. The resulting mixture was filtered through Celite®. After removing the solvent in vacuum, red solid was obtained. The solid was recrystallized from acetone, collected by filtration, and dried under reduced pressure to obtain a red solid. Yield: 117 mg (63%).

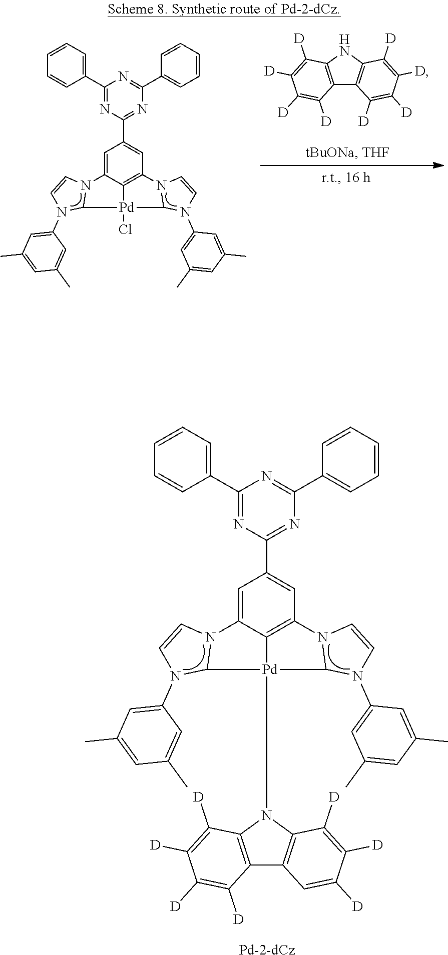

### Characterization of Pt(H) Complexes

Pt-1: ¹H NMR (500 MHz, Methylene Chloride-d₂) δ 8.87-8.83 (m, 4H), 8.53 (s, 2H), 8.13 (d, J=7.9 Hz, 2H), 7.74 (d, J=2.1 Hz, 2H), 7.69-7.63 (m, 6H), 7.59 (d, J=8.2 Hz, 2H), 7.23 (t, J=7.4 Hz, 2H), 6.98 (t, J=7.3 Hz, 2H), 6.93 (d, J=2.0 Hz, 2H), 3.16 (t, J=8.2 Hz, 4H), 1.14-1.07 (m, 4H), 0.30 (t, J=7.1 Hz, 6H), 0.25-0.18 (m, 4H).

Pt-1-dCz: ¹H NMR (400 MHz, DMSO-d₆) δ 8.95-8.91 (m, 4H), 8.71 (s, 2H), 8.55 (d, J=2.0 Hz, 2H), 7.79-7.74 (m, 2H), 7.73-7.68 (m, 4H), 7.47 (d, J=2.1 Hz, 2H), 3.11 (t, J=8.2 Hz, 4H), 1.09-0.98 (m, 4H), 0.19 (t, J=7.2 Hz, 6H), 0.13-0.00 (m, 4H).

Pt-2: ¹H NMR (500 MHz, Benzene-d₆) δ 9.10-9.06 (m, 4H), 8.73 (s, 2H), 7.98 (d, J=7.6 Hz, 2H), 7.50-7.44 (m, 6H), 7.39 (t, J=7.3 Hz, 2H), 7.22 (t, J=7.4 Hz, 2H), 7.04 (t, J=7.3 Hz, 2H), 6.71 (d, J=2.0 Hz, 2H), 6.26 (s, 4H), 6.18 (d, J=2.0 Hz, 2H), 6.16 (s, 2H), 1.56 (s, 12H).

Pt-2-dCz: ¹H NMR (500 MHz, Benzene-d₆) δ 9.08-9.05 (m, 4H), 8.72 (s, 2H), 7.47 (t, J=7.6 Hz, 4H), 7.39 (t, J=7.3 Hz, 2H), 6.70 (d, J=2.0 Hz, 2H), 6.25 (s, 4H), 6.17 (d, J=2.0 Hz, 2H), 6.15 (s, 2H), 1.55 (s, 12H). ¹H NMR (600 MHz, THF-d₈) δ 8.94-8.91 (m, 4H), 8.79-8.76 (m, 2H), 8.23 (t, 2H), 7.68-7.61 (m, 6H), 7.28 (t, J=1.7 Hz, 2H), 6.27 (s, 4H), 6.02 (s, 2H), 1.37 (s, 12H).

Pt-3: ¹H NMR (500 MHz, Acetone-d₆) δ 8.94-8.91 (m, 4H), 8.81 (s, 2H), 8.52 (s, 1H), 8.23 (d, J=2.0 Hz, 2H), 8.17 (d, J=7.8 Hz, 1H), 7.83 (d, J=7.6 Hz, 1H), 7.74-7.70 (m, 2H), 7.69-7.65 (m, 5H), 7.62 (d, J=7.9 Hz, 1H), 7.40 (d, J=7.3 Hz, 1H), 7.37 (d, J=2.0 Hz, 2H), 7.29 (t, J=7.4 Hz, 1H), 7.23-7.18 (m, 1H), 7.15-7.10 (m, 1H), 6.96 (t, J=7.3 Hz, 1H), 3.32-3.26 (m, 4H), 1.47 (s, 6H), 1.19-1.11 (m, 4H), 0.29-0.22 (m, 4H), 0.22-0.17 (m, 6H).

Pt-4-dCz: ¹H NMR (600 MHz, Methylene Chloride-d₂) δ 9.04 (s, 2H), 8.91-8.88 (m, 4H), 8.34 (d, J=8.2 Hz, 2H), 7.70-7.67 (m, 6H), 7.62 (t, J=7.7 Hz, 2H), 7.42 (t, J=7.6 Hz, 2H), 7.33 (d, J=8.1 Hz, 2H), 3.48-3.40 (m, 4H), 1.19-1.13 (m, 4H), 0.31 (t, J=7.4 Hz, 6H), 0.18-0.11 (m, 4H).

Pt-5-dCz: ¹H NMR (500 MHz, THF-d₈) δ 9.27 (s, 2H), 9.01-8.96 (m, 4H), 8.55 (d, J=8.3 Hz, 2H), 7.73-7.68 (m, 8H), 7.38 (t, J=7.6 Hz, 2H), 6.92 (d, J=8.0 Hz, 2H), 5.59 (s, 4H), 1.78 (s, 6H), 1.60 (s, 12H).

Pt-4-dfCz: ¹H NMR (600 MHz, THF-d₈) δ 9.12-9.08 (m, 2H), 8.94-8.90 (m, 4H), 8.39 (d, J=8.4 Hz, 2H), 7.69-7.64 (m, 8H), 7.48-7.42 (m, 4H), 3.58-3.54 (m, 4H), 1.45 (s, 6H), 1.25-1.19 (m, 4H), 0.30-0.26 (m, 4H), 0.26-0.21 (m, 6H).

Pt-6: ¹H NMR (500 MHz, THF-d₈) δ 8.93-8.90 (m, 4H), 8.79 (s, 2H), 8.28 (d, J=2.1 Hz, 2H), 7.66-7.60 (m, 6H), 7.58 (d, J=7.7 Hz, 2H), 7.39 (d, J=2.1 Hz, 2H), 6.99 (d, J=8.0 Hz, 2H), 6.83-6.79 (m, 2H), 6.68 (d, J=7.6 Hz, 4H), 6.61 (t, J=7.3 Hz, 2H), 6.34 (t, J=7.5 Hz, 2H), 6.00 (t, J=7.8 Hz, 4H).

Pt-7-dCz: ¹H NMR (600 MHz, THF-d₈) δ 8.93-8.90 (m, 4H), 8.76 (s, 2H), 8.25-8.22 (m, 2H), 7.65-7.60 (m, 6H), 7.37 (d, J=1.9 Hz, 2H).

Pt-7-dtBuCz: ¹H NMR (600 MHz, Methylene Chloride-d₂) δ 8.89-8.86 (m, 4H), 8.57 (s, 2H), 7.80 (d, J=2.0 Hz, 2H), 7.68-7.63 (m, 6H), 7.09 (d, J=2.0 Hz, 2H).

Pt-8-dCz: ¹H NMR (600 MHz, THF-d₈) δ 9.26 (s, 2H), 8.99-8.92 (m, 4H), 8.52 (d, J=8.3 Hz, 2H), 7.72-7.66 (m, 8H), 7.39 (t, J=7.4 Hz, 2H), 7.18 (d, J=8.1 Hz, 2H).

Pt-9-dCz: ¹H NMR (600 MHz, THF-d₈) δ 8.79 (s, 2H), 8.25 (d, J=2.0 Hz, 2H), 7.30 (d, J=2.0 Hz, 2H), 6.28 (s, 4H), 6.02 (s, 2H), 1.36 (s, 12H).

Pt-10-dCz: ¹H NMR (500 MHz, THF-d₈) δ 8.37 (dd, J=7.3, 1.7 Hz, 4H), 8.30 (s, 2H), 8.16 (d, J=2.1 Hz, 2H), 7.94 (s, 2H), 7.53 (t, J=7.6 Hz, 4H), 7.44 (t, J=7.3 Hz, 2H), 7.35 (d, J=2.0 Hz, 2H).

### Example 2. Emission Quantum Yield of Platinum (II) Complexes

### Materials and Methods

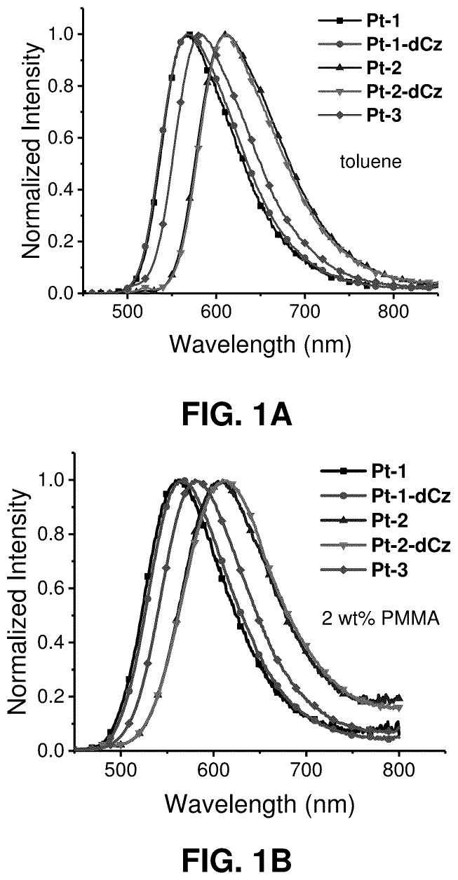

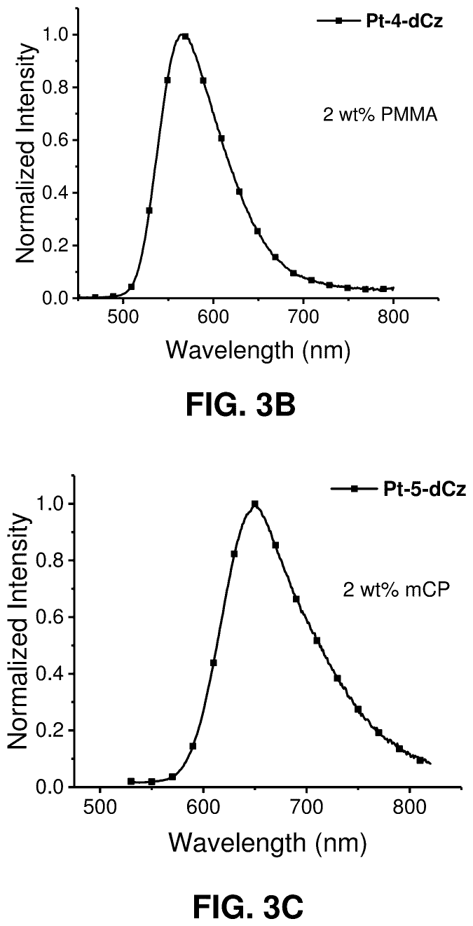

The measurements of emission quantum yield and other parameters of Pt(II) complexes have been described in the methods of making section above. The emission maxima λₑₘ (nm) of the complexes in solutions or films are directly obtained from the emission spectra shown in FIGS. 1A-1B and 3A-3C.

### Results

### Photophysical Properties

The emission data and related photophysical data of exemplary Pt(II) complexes (Pt-1, Pt-1-dCz, Pt-2, Pt-2-dCz, Pt-3, Pt-4-dCz, Pt-5-dCz) are shown in Tables 1-2. These Pt(II) complexes display yellow, orange and red photoluminescence in toluene and PMMA films, with λₘₐₓ at 562-667 nm. In PMMA films, the platinum(II) complexes display quantum yields of 0.63-0.87, and short emission lifetimes of 0.43-1.54 μs. The calculated radiative decay rate constants (kᵣ) of the platinum(II) complexes are high, in the range of 5.5×10⁵ s⁻¹-16.3×10⁵ s⁻¹.

The emission spectra FIG. 1A is a graph showing the emission spectra of Pt-1, Pt-1-dCz, Pt-2, Pt-2-dCz and Pt-3 in deaerated toluene. FIG. 1B is a graph showing the emission spectra of Pt-1, Pt-1-dCz, Pt-2, Pt-2-dCz and Pt-3 doped in PMMA films at a concentration of 2 wt %.

FIG. 3A is a graph showing the emission spectra of Pt-4-dCz and Pt-5-dCz in deaerated toluene. FIG. 3B is a graph showing the emission spectrum of Pt-4-dCz doped in PMMA film at a concentration of 2 wt %. FIG. 3C is a graph showing the emission spectrum of Pt-5-dCz doped in mCP film at a concentration of 2 wt %.

TABLE 1
Emission data of Pt(II) complexes (measured at room temperature)

| | | | | | kᵣ | kₙᵣ |
|---|---|---|---|---|---|---|
| | | λₑₘ | τ | Φ | (10⁵ | (10⁵ |
| Complex | Medium | (nm) | (μs) | (%) | s⁻¹) | s⁻¹) |
| Pt-1 | Toluene | 568 | 0.79 | 66 | 8.4 | 4.3 |
| | 2 wt % PMMA# | 562 | 1.23 | 84 | 6.8 | 1.3 |
| Pt-1-dCz | Toluene | 568 | 0.92 | 72 | 7.8 | 3.0 |
| | 2 wt % PMMA# | 567 | 1.14 | 86 | 7.5 | 1.2 |
| Pt-2 | Toluene | 611 | 0.56 | 67 | 12.0 | 5.9 |
| | 2 wt % PMMA# | 610 | 0.43 | 70 | 16.3 | 7.0 |
| Pt-2-dCz | Toluene | 612 | 0.59 | 68 | 11.5 | 5.4 |
| | 2 wt % PMMA# | 610 | 0.51 | 70 | 13.7 | 5.9 |
| Pt-3 | Toluene | 581 | 0.84 | 78 | 9.3 | 2.6 |
| | 2 wt % PMMA# | 580 | 0.84 | 87 | 10.4 | 1.5 |

#measured under ambient air.

TABLE 2
Emission data of Exemplary Pt(II) complexes
(measured at room temperature)

| | | | | | kᵣ | kₙᵣ |
|---|---|---|---|---|---|---|
| | | λₑₘ | τ | Φ | (10⁵ | (10⁵ |
| Complex | Medium | (nm) | (μs) | (%) | s⁻¹) | s⁻¹) |
| Pt-4-dCz | Toluene | 585 | 2.28 | 64 | 2.8 | 1.6 |
| | 2 wt % PMMA# | 565 | 1.54 | 85 | 5.5 | 1.0 |
| Pt-5-dCz | Toluene | 667 | 1.44 | 55 | 3.8 | 3.1 |
| | 2 wt % mCP# | 650 | 0.91 | 63 | 6.9 | 4.1 |

#measured under ambient air

### Example 3. Emission Quantum Yield of Palladium (II) Complexes

### Materials and Methods

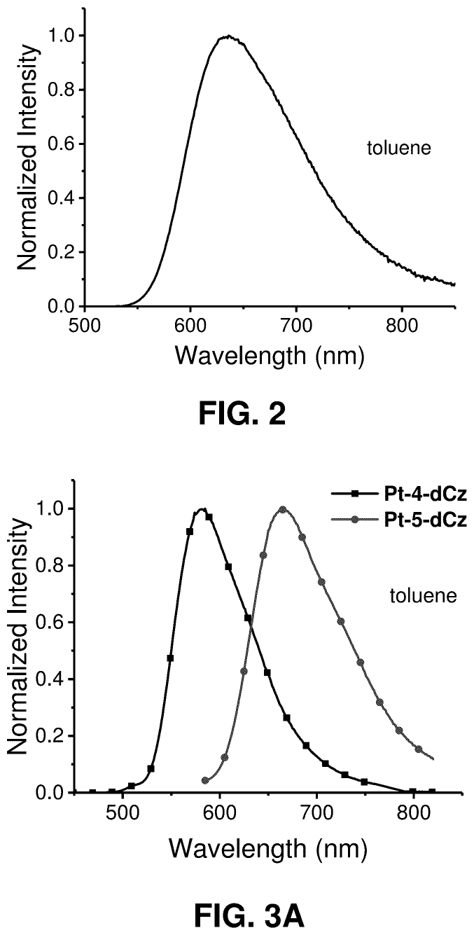

The measurements of emission quantum yield and other parameters of Pd(II) complexes have been described in the methods of making section above. The emission maximum λₑₘ (nm) of Pd-2-dCz in toluene is directly obtained from the emission spectra shown in FIG. 2.

### Results

### Photophysical Properties

The emission data of a palladium complex (Pd-2-dCz) in toluene and PMMA film measured at room temperature are provided in Table 3. Pd-2-dCz displayed red photoluminescence in toluene and PMMA film with emission peak at 636 and 617 nm, respectively. Pd-2-dCz exhibited a high quantum yield of 0.64 and a short emission lifetime of 0.52 μs in solid PMMA film. Thus, the calculated radiative decay rate constant (kᵣ) reaches 12.3×10⁵ s⁻¹. FIG. 2 is a graph showing the emission spectrum of Pd-2-dCz in deaerated toluene.

TABLE 3
Emission data of an Exemplary Pd(II) complex
(measured at room temperature)

| | | | | | kᵣ | kₙᵣ |
|---|---|---|---|---|---|---|
| | | λₑₘ | τ | Φ | (10⁵ | (10⁵ |
| Complex | Medium | (nm) | (μs) | (%) | s⁻¹) | s⁻¹) |
| Pd-2-dCz | Toluene | 636 | 0.30 | 25 | 8.3 | 25.0 |
| | 2 wt % PMMA# | 617 | 0.52 | 64 | 12.3 | 6.9 |

#measured under ambient air

### Example 4. OLED Devices Containing the Pt(II) or Pd(II) Complexes

### Materials and Methods

Indium-tin-oxide (ITO) coated glass with a sheet resistance of 10 Ω/sq was used as the anode substrate. Before film deposition, patterned ITO substrates were cleaned with detergent, rinsed in de-ionized water, acetone, and isopropanol, and then dried in an oven for 1 h in a cleanroom. The slides were then treated in an ultraviolet-ozone chamber for 5 min. The OLEDs were fabricated in a Kurt J. Lesker SPECTROS vacuum deposition system with a base pressure of 10⁷ mbar. In the vacuum chamber, organic materials were thermally deposited in sequence at a rate of 0.5 Å s⁻¹. The doping process in the EMLs was realized using co-deposition technology. Afterward, LiF (1.2 nm) and Al (100 nm) were thermally deposited at rates of 0.02 and 0.2 nm s⁻¹, respectively. The film thicknesses were determined in situ with calibrated oscillating quartz-crystal sensors.

An exemplary OLED device structure is as follows: ITO/Hole Injecting Layer (10 nm)/Hole Transporting Layer (80 nm)/Electron or Exciton Blocking Layer (5 nm)/Host: OLED emitter (40 nm)/Hole or Exciton Blocking Layer (5 nm)/Electron Transporting Layer (35 nm)/Yb (1 nm)/Ag (100 nm). ITO is used as anode, while Yb (1 nm)/Ag (100 nm) was used as bilayer cathode.

Current density-brightness-voltage characteristics, EL spectra, and EQE of EL device were obtained by using a Keithley 2400 source-meter and an absolute external quantum efficiency measurement system (C9920-12, Hamamatsu Photonics). All devices were encapsulated in a 200-nm-thick Al₂O₃ thin film deposited by atomic layer deposition (ALD) in a Kurt J. Lesker SPECTROS ALD system before measurements.

### Results

### OLED Performance

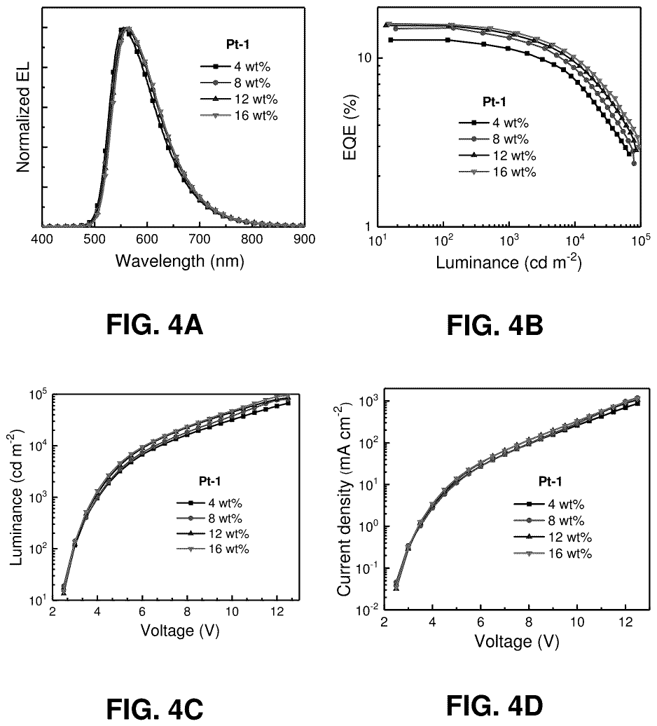

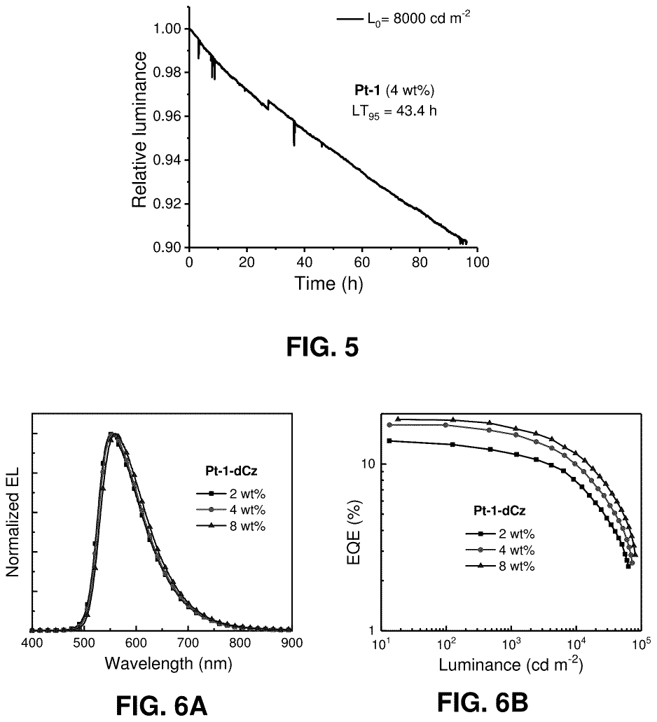

Vacuum-deposited devices fabricated with Pt-1 exhibited yellow to orange electroluminescence with λₘₐₓ at 555 and 564 nm at doping concentrations of 4-16 wt % (FIGS. 4A-4D). The external quantum efficiency (“EQE”) and current efficiency (“CE”) of the device doped with 16 wt % Pt-1 were 14.5% and 39.3 cd/A, respectively, at 1000 cd m⁻². The maximum luminance (“L”) of the device doped with 16 wt % Pt-1 was 94400 cd m⁻². The performance data of the device with Pt-1 are shown in Table 4. The operational lifetime of device fabricated with 4 wt % Pt-1 is shown in FIG. 5 and summarized in Table 5.

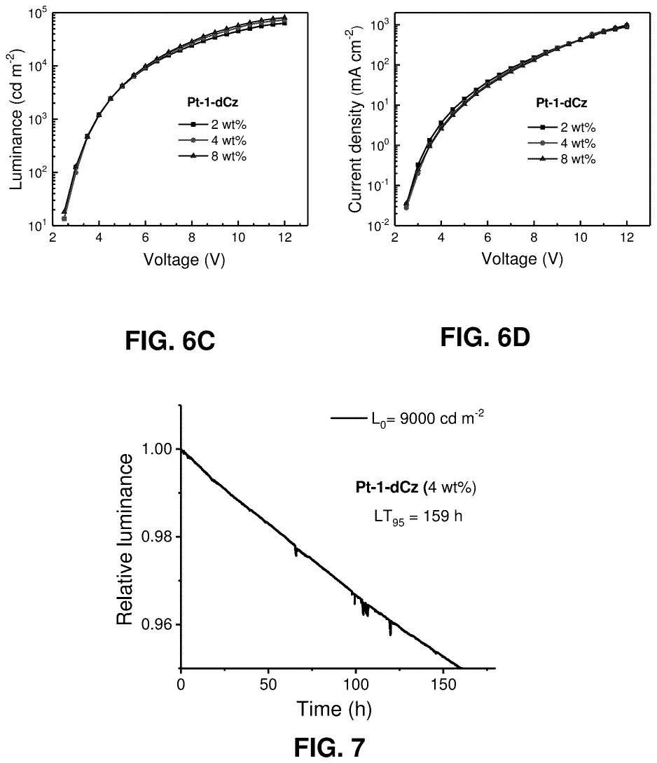

Vacuum-deposited devices fabricated with Pt-1-dCz exhibited yellow to orange electroluminescence with λₘₐₓ at 554-560 nm at doping concentrations of 2-8 wt % (FIGS. 6A-6D). The external quantum efficiency (“EQE”) and current efficiency (“CE”) of the device doped with 16 wt % Pt-1 were 16.4% and 46.8 cd/A, respectively, at 1000 cd m⁻². The maximum luminance (“L”) of the device doped with 8 wt % Pt-1-dCz was 80800 cd m⁻². The performance data of the device with Pt-1-dCz are shown in Table 6. The operational lifetime of device based on 4 wt % Pt-1-dCz is shown in FIG. 7 and summarized in Table 7.

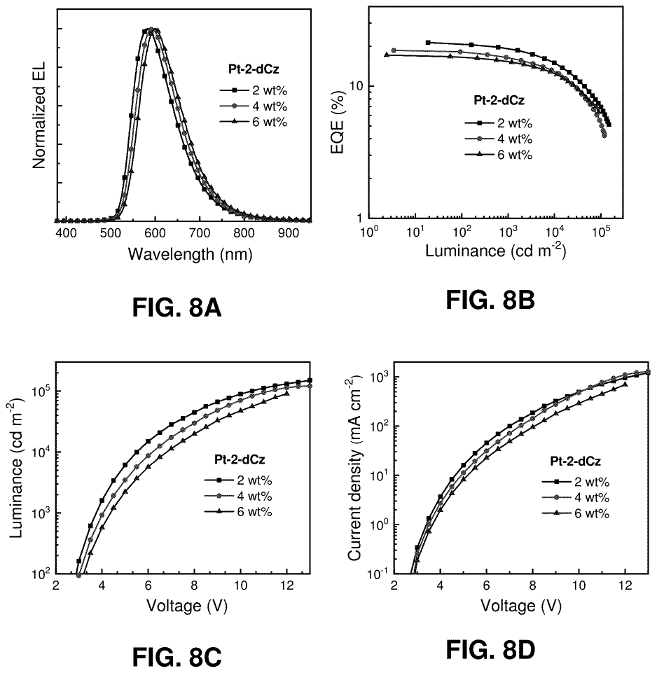

Vacuum-deposited devices fabricated with Pt-2-dCz exhibited orange electroluminescence with λₘₐₓ at 583-599 nm at doping concentrations of 2-6 wt % (FIGS. 8A-8D). The EQE and CE of the device doped with 4 wt % Pt-2-dCz was 19.3% and 45.1%, respectively, at 1000 cd m⁻². The maximum luminance (“L”) of the device doped with 2 wt % Pt-1 was 149700 cd m⁻². The performance data of the device with Pt-2-dCz are shown in Table 8.

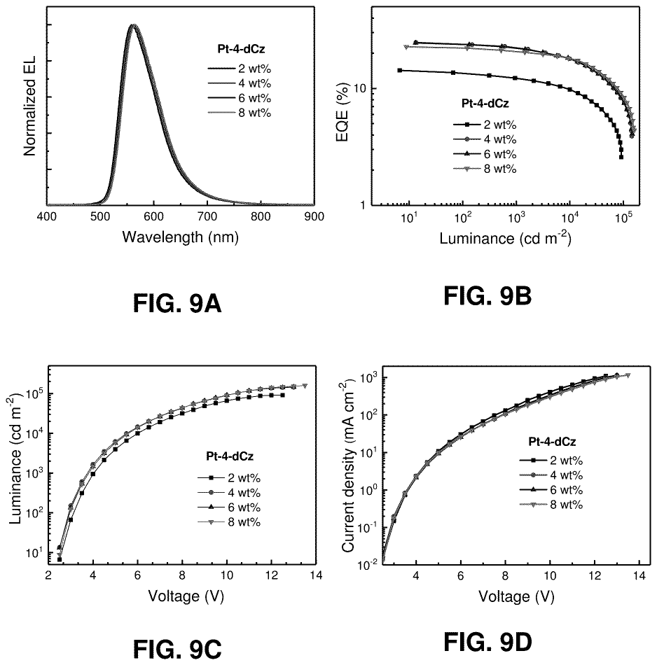

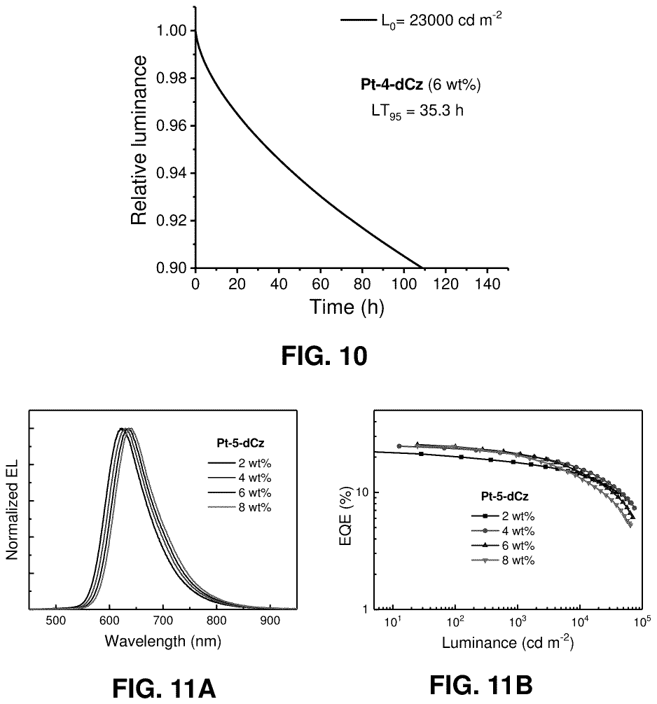

Vacuum-deposited devices fabricated with Pt-4-dCz exhibited yellow to orange electroluminescence with λₘₐₓ at 558-566 nm at doping concentrations of 2-8 wt % (FIGS. 9A-9D). The EQE and CE of the device doped with 4 wt % Pt-4-dCz was 22.5% and 72.8%, respectively, at 1000 cd m⁻². The maximum luminance (“L”) of the device doped with 8 wt % Pt-4-dCz was 160000 cd m⁻². The performance data of the device with Pt-4-dCz are shown in Table 9. The operational lifetime of device based on 6 wt % Pt-4-dCz is shown in FIG. 10 and summarized in Table 10.

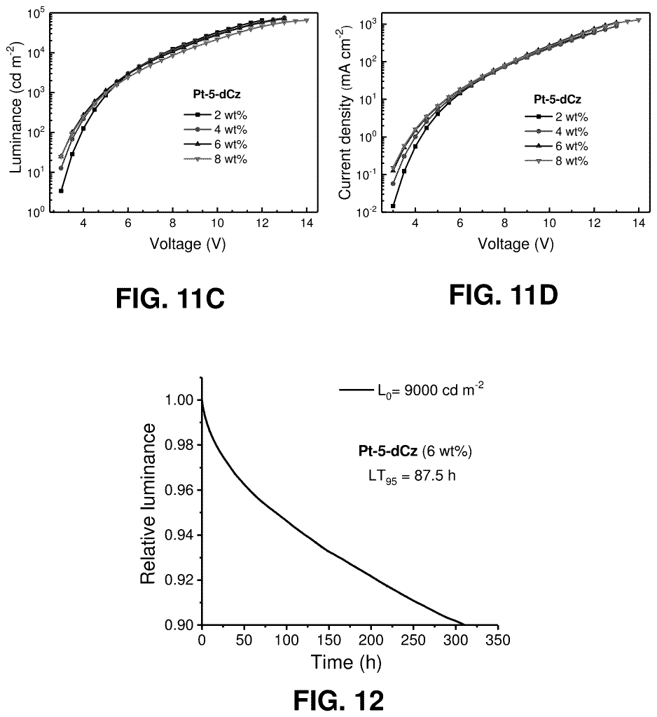

Vacuum-deposited devices fabricated with Pt-5-dCz exhibited red electroluminescence with λₘₐₓ at 623-637 nm at doping concentrations of 2-8 wt % (FIGS. 11A-11D). The EQE and CE of the device doped with 6 wt % Pt-5-dCz was 21.3% and 17.5%, respectively, at 1000 cd m⁻². The maximum luminance (“L”) of the device doped with 4 wt % Pt-5-dCz was 75000 cd m⁻². The performance data of the device with Pt-5-dCz are shown in Table 11. The operational lifetime of device based on 6 wt % Pt-5-dCz is shown in FIG. 12 and summarized in Table 12.

The operational lifetime of the devices based on these Pt emitters, presented as LT₉₅ at 1000 cd m⁻², is up to 7289 hours, which is a new record high for OLEDs based on pincer type Pt emitters in the literature.

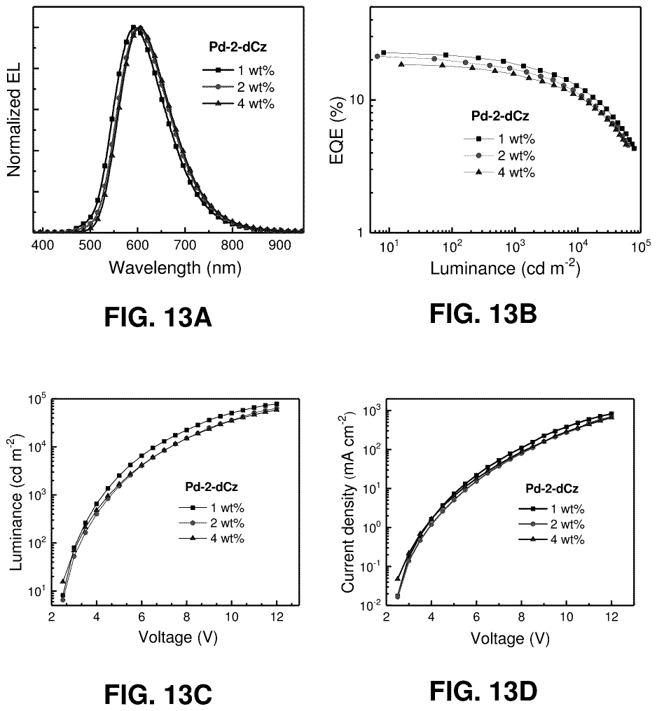

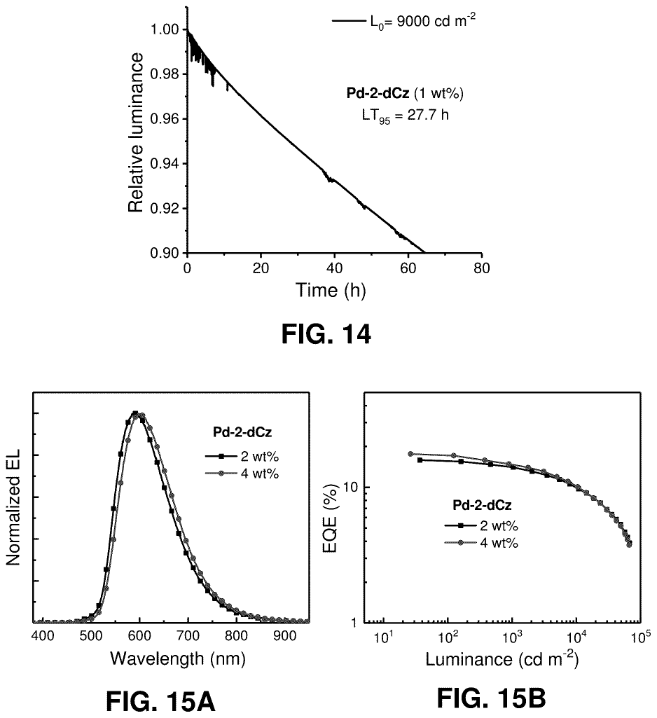

Vacuum-deposited devices fabricated with Pd-2-dCz (Device structure A) exhibited orange-red electroluminescence with λₘₐₓ at 594-604 nm at doping concentrations of 1-4 wt % (FIGS. 13A-13D). The EQE and CE of the device doped with 1 wt % Pd-2-dCz was 19.2% and 38.7%, respectively, at 1000 cd m⁻². The maximum luminance (“L”) of the device doped with 1 wt % Pd-2-dCz was 78300 cd m⁻². The performance data of the device with Pd-2-dCz are shown in Table 13. The device lifetime data of the device fabricated with 1 wt % Pd-2-dCz (Device structure A) is shown in FIG. 14 and summarized in Table 14.

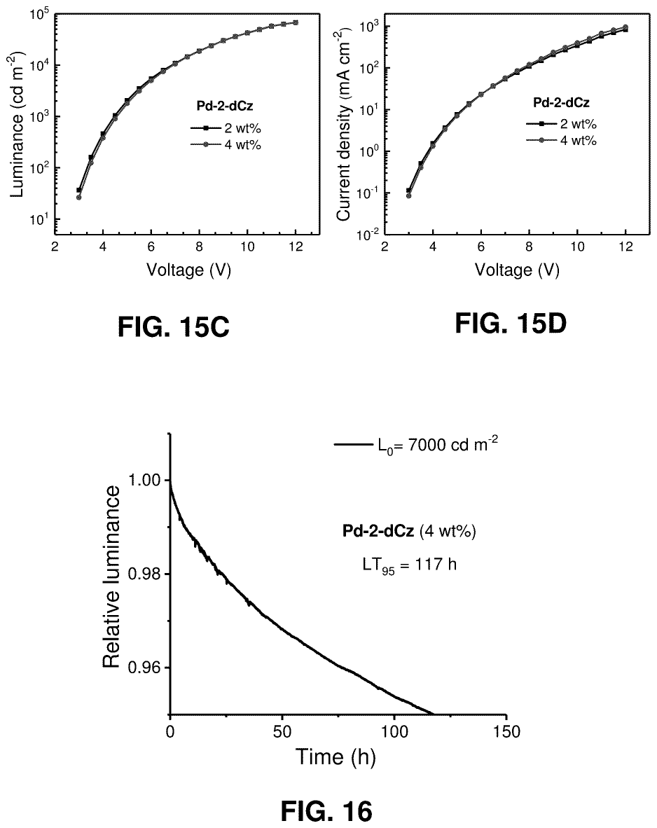

Vacuum-deposited devices fabricated with Pd-2-dCz (Device structure B) exhibited orange electroluminescence with λₘₐₓ at 591-603 nm at doping concentrations of 2-4 wt % (FIGS. 15A-15D). The EQE and CE of the device doped with 4 wt % Pd-2-dCz was 14.8% and 26.7%, respectively, at 1000 cd m⁻². The maximum luminance (“L”) of the device doped with 2 wt % Pd-2-dCz was 67300 cd m⁻². The performance data of the device with Pd-2-dCz are shown in Table 15. The device lifetime data of the device fabricated with 4 wt % Pd-2-dCz (Device structure B) is shown in FIG. 16 and summarized in Table 16.

TABLE 4
Device* data of Pt(II) Complex, Pt-1

| | | | CE [cd A⁻¹] | | | PE [Im W⁻¹] | | | EQE [%] | | CIE [(x, y)] | | | |
|---|---|---|---|---|---|---|---|---|---|---|---|---|---|---|
| | | L | | at 1000 | at 10000 | | at 1000 | at 10000 | | at 1000 | at 10000 | | FWHM | λₘₐₓ |
| Pt-1 | | [cd m⁻²] | Max | cd m⁻² | cd m⁻² | Max | cd m⁻² | cd m⁻² | Max | cd m⁻² | cd m⁻² | | [nm] | [nm] |
| 4 | wt % | 67000 | 36.4 | 32.7 | 21.7 | 45.7 | 25.7 | 10.1 | 12.8 | 11.4 | 7.48 | 0.46, 0.53 | 102 | 555 |
| 8 | wt % | 79500 | 41.5 | 36.8 | 24.6 | 51.8 | 28.9 | 11.9 | 15.0 | 13.2 | 8.76 | 0.47, 0.52 | 104 | 564 |
| 12 | wt % | 85100 | 42.1 | 38.7 | 26.1 | 52.9 | 30.8 | 13.1 | 15.6 | 14.1 | 9.37 | 0.48, 0.52 | 104 | 564 |
| 16 | wt % | 94400 | 43.0 | 39.3 | 27.8 | 53.1 | 33.2 | 14.5 | 16.0 | 14.5 | 10.0 | 0.48, 0.51 | 104 | 564 |

*ITO/HAT-CN (10 nm)/BPBPA (80 nm)/NBP-BC (5 nm)/RH:Pt-1 (40 nm)/ANT-Biz (5 nm)/ANT-Biz:Liq (35 nm)/Yb (1 nm)/Ag (100 nm)

TABLE 5
Operational lifetime of device* based on Pt-1

| Conc. | L₀ [cd m⁻²] | LT₉₅@L₀ [h] | n | LT₉₅@1000 cd m⁻² [h] |
|---|---|---|---|---|
| 4 wt/wt % | 8000 | 43.4 | 1.7 | 1488 |

n denotes for acceleration factor in LT(L₁) = LT(L₀) × (L₀/L₁)ⁿ and 1.7
*ITO/HAT-CN (10 nm)/BPBPA (80 nm)/NBP-BC (5 nm)/RH:Pt-1 (40 nm)/ANT-Biz (5 nm)/ANT-Biz:Liq (35 nm)/Yb (1 nm)/Ag (100 nm)

TABLE 6
Device* data of Pt(II) complex, Pt-1-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-1-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 63700 | 40.0 | 34.5 | 23.6 | 50.2 | 27.3 | 12.1 | 13.8 | 11.7 | 7.92 | 0.45, 0.54 | 97 | 554 |
| 4 wt % | 72900 | 49.1 | 44.3 | 29.2 | 61.4 | 36.0 | 15.2 | 17.1 | 15.2 | 10.0 | 0.46, 0.53 | 96 | 555 |
| 8 wt % | 80800 | 51.3 | 46.8 | 32.9 | 64.4 | 36.1 | 17.2 | 18.5 | 16.4 | 11.5 | 0.47, 0.52 | 101 | 560 |

*(ITO/HAT-CN (10 nm)/BPBPA (80 nm)/NBP-BC (5 nm)/RH:Pt-1-dCz (40 nm)/ANT-Biz (5 nm)/ANT-Biz:Liq (35 nm)/Yb (1 nm)/Ag (100 nm)

TABLE 7
Operational lifetime of device* based on Pt-1-dCz

| Conc. | L₀ [cd m⁻²] | LT₉₅@L₀ [h] | n | LT₉₅@1000 cd m⁻² [h] |
|---|---|---|---|---|
| 4 wt/wt % | 9000 | 159 | 1.7 | 6662 |

n denotes for acceleration factor in LT(L₁) = LT(L₀) × (L₀/L₁)ⁿ and 1.7
*(ITO/HAT-CN (10 nm)/BPBPA (80 nm)/NBP-BC (5 nm)/RH:Pt-1-dCz (40 nm)/ANT-Biz (5 nm)/ANT-Biz:Liq (35 nm)/Yb (1 nm)/Ag (100 nm))

TABLE 8
Device* data of Pt(II) complex, Pt-2-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-2-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 149700 | 49.0 | 45.1 | 35,5 | 61.6 | 38.1 | 20.3 | 21.4 | 19.3 | 15.0 | 0.52, 0.47 | 106 | 583 |
| 4 wt % | 120700 | 38.4 | 33.9 | 27.0 | 48.2 | 26.5 | 13.6 | 18.6 | 16.3 | 12.8 | 0.55, 0.45 | 108 | 596 |
| 6 wt % | 90040 | 31.6 | 28.3 | 23.8 | 39.7 | 20.7 | 11.1 | 17.2 | 15.3 | 12.5 | 0.57, 0.43 | 109 | 599 |

*(ITO/HAT-CN (10 nm)/BPBPA (80 nm)/NBP-BC (5 nm)/RH:Pt-2-dCz (40 nm)/ANT-Biz (5 nm)/ANT-Biz:Liq (35 nm)/Yb (1 nm)/Ag (100 nm))

TABLE 9
Device* data of Pt(II) complex, Pt-4-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-4-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 91300 | 46.5 | 40.6 | 32.7 | 58.4 | 31.9 | 17.1 | 14.3 | 12.2 | 9.79 | 0.46, 0.53 | 77 | 558 |
| 4 wt % | 144000 | 78.1 | 72.8 | 58.8 | 98.2 | 64.3 | 33.6 | 24.7 | 22.5 | 17.9 | 0.47, 0.52 | 77 | 563 |
| 6 wt % | 146000 | 76.2 | 70.3 | 58.6 | 95.8 | 59.9 | 33.5 | 24.5 | 22.1 | 18.2 | 0.48, 0.51 | 78 | 565 |
| 8 wt % | 160000 | 70.1 | 65.3 | 57.5 | 88.1 | 55.5 | 32.8 | 22.7 | 20.7 | 18.0 | 0.50. 0.49 | 78 | 566 |

*(ITO/FSFA:NDP-9 (2 wt %, 10 nm)/FSFA (120 nm)/NPB-BC (5 nm)/RH:Pt-4-dCz (40 nm)/ANT-Biz(5 nm)/ANT-Biz:Liq (1:1, 30 am)/Yb (1 nm)/Ag (100 nm)

TABLE 10
Operational lifetime of device* based on Pt-4-dCz

| Conc. | L₀ [cd m⁻²] | LT₉₅@L₀ [h] | n | LT₉₅@1000 cd m⁻² [h] |
|---|---|---|---|---|
| 6 wt/wt % | 23000 | 35.3 | 1.7 | 7289 |

n denotes for acceleration factor in LT(L₁) = LT(L₀) × (L₀/L₁)ⁿ and 1.7
*(ITO/FSFA:NDP-9 (2 wt %, 10 nm)/FSFA (120 nm)/NPB-BC (5 nm)/RH:Pt-4-dCz (40 nm)/ANT-Biz(5 nm)/ANT-Biz:Liq (1:1, 30 nm)/Yb (1 nm)/Ag (100 nm)

TABLE 11
Device* data of Pt(II) complex, Pt-5-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-5-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 65000 | 23.5 | 20.4 | 17.2 | 24.6 | 12.6 | 7.03 | 22.3 | 17.8 | 14.2 | 0.64, 0.36 | 89 | 623 |
| 4 wt % | 75000 | 22.3 | 20.2 | 16.2 | 23.4 | 12.7 | 6.58 | 24.7 | 20.9 | 15.9 | 0.65, 0.35 | 90 | 629 |
| 6 wt % | 70800 | 19.8 | 17.5 | 13.2 | 20.7 | 11.2 | 5.18 | 25.5 | 21.3 | 14.8 | 0.66, 0.34 | 90 | 636 |
| 8 wt % | 65100 | 16.3 | 14.3 | 10.3 | 17.0 | 9.03 | 3.83 | 24.7 | 20.7 | 13.4 | 0.67. 0.33 | 90 | 637 |

*(ITO/FSFA:NDP-9 (2 wt %, 10 nm)/FSFA (120 nm)/NPB-BC (5 nm)/RH:Pt-5-dCz (40 nm)/ANT-Biz(5 nm)/ANT-Biz:Liq (1:1, 30 nm)/Yb (1 nm)/Ag (100 nm)

TABLE 12
Operational lifetime of device* based on Pt-5-dCz

| Conc. | L₀ [cd m⁻²] | LT₉₅@L₀ [h] | n | LT₉₅@1000 cd m⁻² [h] |
|---|---|---|---|---|
| 6 wt/wt % | 9000 | 87.5 | 1.7 | 3666 |

n denotes for acceleration factor in LT(L₁) = LT(L₀) × (L₀/L₁)ⁿ and 1.7
*(ITO/FSFA:NDP-9 (2 wt %, 10 nm)/FSFA (120 nm)/NPB-BC (5 nm)/RH:Pt-5-dCz (40 nm)/ANT-Biz(5 nm)/ANT-Biz:Liq (1:1, 30 nm)/Yb (1 nm)/Ag (100 nm)

TABLE 13
Device data of Pd(II) complex, Pd-2-dCz (Device structure A*)

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pd-2-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 1 wt % | 78300 | 46.5 | 38.7 | 26.8 | 58.4 | 28.8 | 12.9 | 22.7 | 19.2 | 12.7 | 0.52, 0.46 | 127 | 594 |
| 2 wt % | 63100 | 39.4 | 32.0 | 21.4 | 49.5 | 22.3 | 9.57 | 21.3 | 17.2 | 11.3 | 0.54, 0.47 | 127 | 604 |
| 4 wt % | 58500 | 32.7 | 27.8 | 19.4 | 41.2 | 19.4 | 8.45 | 18.4 | 15.6 | 10.7 | 0.55, 0.44 | 127 | 604 |

*ITO/FSFA:NDP-9 (3 wt %, 10 nm)/FSFA (120 nm)/NPB-BC (10 nm)/H1:H2:Pd-2-dCz (40 nm)/ANT-Biz:Liq (1:1, 30 nm)/Yb (1 nm)/Ag (100 nm).

TABLE 14
Operational lifetime of device based
on Pd-2-dCz (Device structure A*)

| Conc. | L₀ [cd m⁻²] | LT₉₅@L₀ [h] | n | LT₉₅@1000 cd m⁻² [h] |
|---|---|---|---|---|
| 1 wt/wt % | 9000 | 27.7 | 1.7 | 1160 |

n denotes for acceleration factor in LT(L₁) = LT(L₀) × (L₀/L₁)ⁿ and 1.7
*ITO/FSFA:NDP-9 (3 wt %, 10 nm)/FSFA (120 nm)/NPB-BC (10 nm)/H1:H2:Pd-2-dCz (40 nm)/ANT-Biz:Liq (1:1, 30 nm)/ Yb (1 nm)/Ag (100 nm).

TABLE 15
Device data of Pd(II) complex, Pd-2-dCz (Device structure B*)

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pd-2-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 67300 | 31.9 | 29.6 | 20.2 | 33.5 | 19.9 | 9.05 | 15.7 | 14.0 | 9.75 | 0.53. 0.46 | 127 | 591 |
| 4 wt % | 66600 | 31..2 | 26.7 | 18.5 | 32.6 | 18.6 | 8.31 | 17.6 | 14.8 | 10.1 | 0.55, 0.44 | 128 | 603 |

*ITO/FSFA:NDP-9 (3 wt %, 10 nm)/FSFA (120 nm)/NBP-BC (5 nm)/RH:Pd-2-dCz (40 nm)/ANT-Biz:Liq (30 nm)/Yb (1 nm)/Ag (100 nm)

TABLE 16
Operational lifetime of device based
on Pd-2-dCz (Device structure B*)

| Conc. | L₀ [cd m⁻²] | LT₉₅@L₀ [h] | n | LT₉₅@1000 cd m⁻² [h] |
|---|---|---|---|---|
| 4 wt/wt % | 7000 | 117 | 1.7 | 3197 |

n denotes for acceleration factor in LT(L₁) = LT(L₀) × (L₀/L₁)ⁿ and 1.7
*ITO/FSFA:NDP-9 (3 wt %, 10 nm)/FSFA (120 nm)/NBP-BC (5 nm)/RH:Pd-2-dCz (40 nm)/ANT-Biz:Liq (30 nm)/Yb (1 nm)/Ag (100 nm)

### Example 5. Additional OLED Devices Containing the Pt(II) or Pd(II) Complexes

### Materials and Methods

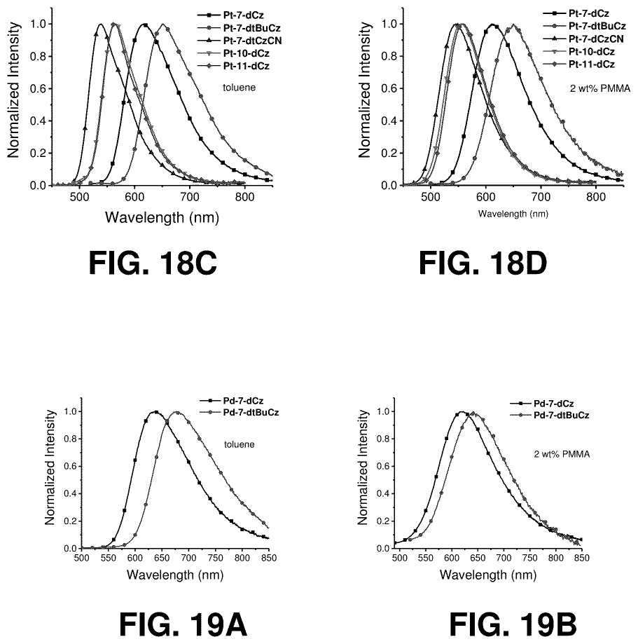

The emission maxima λₑₘ (nm) of the complexes, Pt-4-dfCz, Pt-6, Pt-7-dCz, Pt-8-dCz, Pt-12-dCz, Pt-7-dCz, Pt-7-dtBuCz, Pt-7-dtCzCN, Pt-10-dCz, Pt-11-dCz, Pd-7-dCz or Pd-7-dtBuCz in solutions or films are directly obtained from the emission spectra shown in FIGS. 18A-18D and 19A-19B.

The OLED devices of Pt-4-dfCz, Pt-6, Pt-7-dCz, Pt-8-dCz, Pt-12-dCz, Pt-7-dCz, Pt-7-dtBuCz, Pt-7-dtCzCN, Pt-10-dCz, Pt-11-dCz, Pd-7-dCz, and Pd-7-dtBuCz respectively are prepared and characterized using the material and methods described in Example 4 above.

### Results

### OLED Performance

Photophysical properties of additional Pt(II) complexes, Pt-4-dfCz, Pt-6, Pt-7-dCz, Pt-7-dtBuCz, Pt-7-dCzCN, Pt-8-dCz, Pt-10-dCz, Pt-11-dCz and Pt-12-dCz are shown in Table 17.

Photophysical properties of additional Pd(II) complexes, Pd-7-dCz and Pd-7-dtBuCz are shown in Table 18.

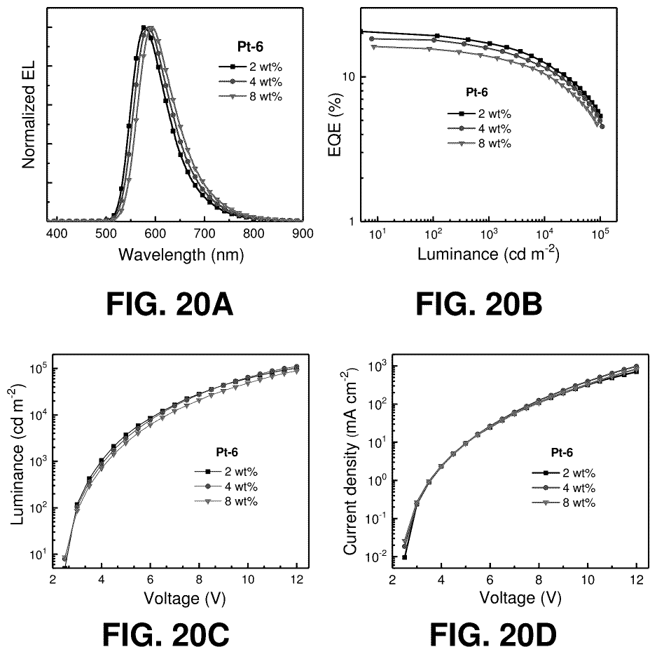

Vacuum-deposited devices fabricated with Pt-6 exhibited electroluminescence at λₘₐₓ at 570, 585 and 594 nm at doping concentrations of 2-8 wt % (FIGS. 20A-20D). The performance data of the device with Pt-6 are shown in Table 19.

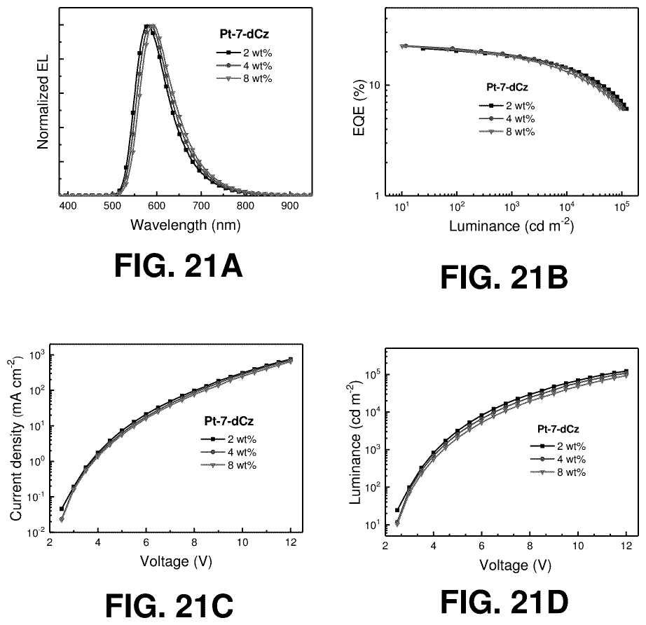

Vacuum-deposited devices fabricated with Pt-7-dCz exhibited electroluminescence at λₘₐₓ at 578, 584 and 590 nm at doping concentrations of 2-8 wt % (FIGS. 21A-21D). The performance data of the device with Pt-7-dCz are shown in Table 20.

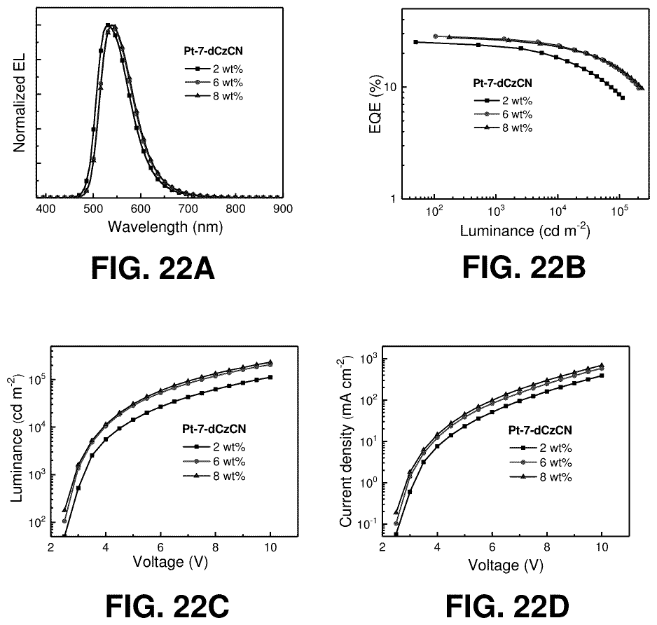

Vacuum-deposited devices fabricated with Pt-7-dCzCN exhibited electroluminescence at λₘₐₓ at 530, 538 and 540 nm at doping concentrations of 2-8 wt % (FIGS. 22A-22D). The performance data of the device with Pt-7-dCzCN are shown in Table 21.

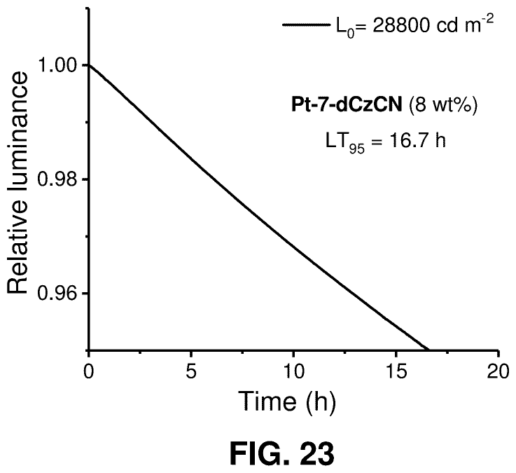

The operational lifetime of device fabricated with 8 wt % Pt-7-dCzCN is shown in FIG. 23 and summarized in Table 22.

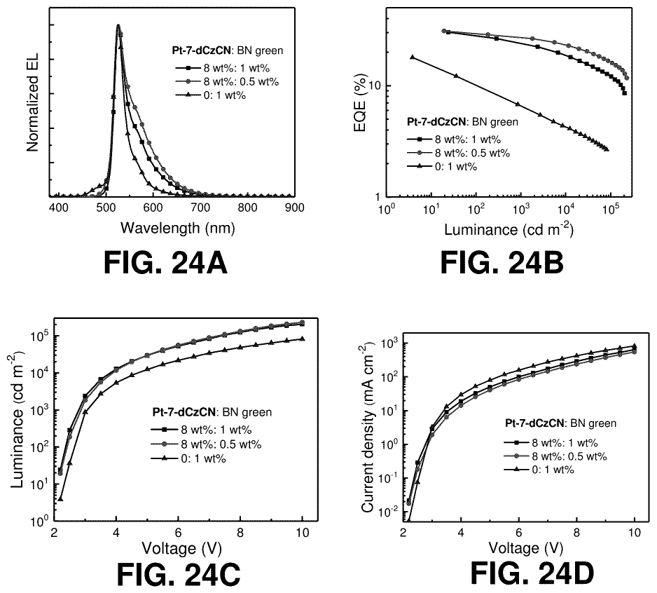

Vacuum-deposited devices fabricated with Pt-7-dCzCN:BN Green exhibited electroluminescence at λₘₐₓ at 527, 526 and 525 nm with doping concentration of 8 wt %:1 wt %, 8 wt %:0.5 wt %, and 0 wt %:1 wt % respectively (FIGS. 24A-24D). The performance data of the device with Pt-7-dCzCN:BN Green are shown in Table 23.

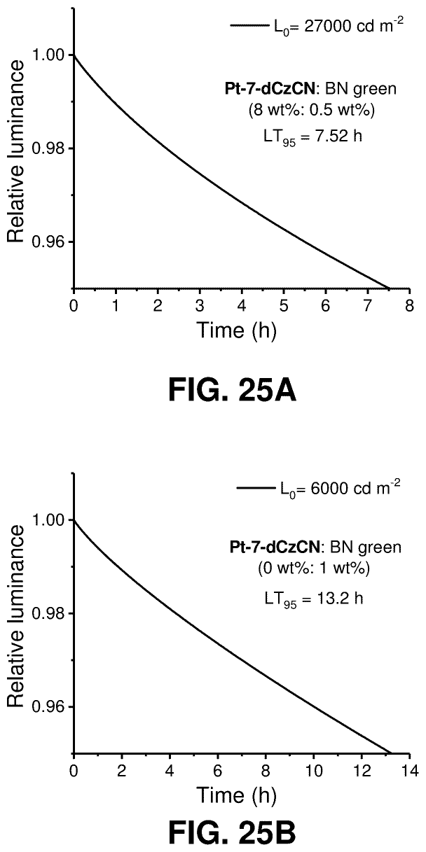

The operational lifetime of device fabricated with Pt-7-dCzCN:BN Green with doping concentration of 8 wt %:0.5 wt % (FIG. 25A) and 0 wt %:1 wt % (FIG. 25B) are shown in FIGS. 25A-25B and summarized in Table 24.

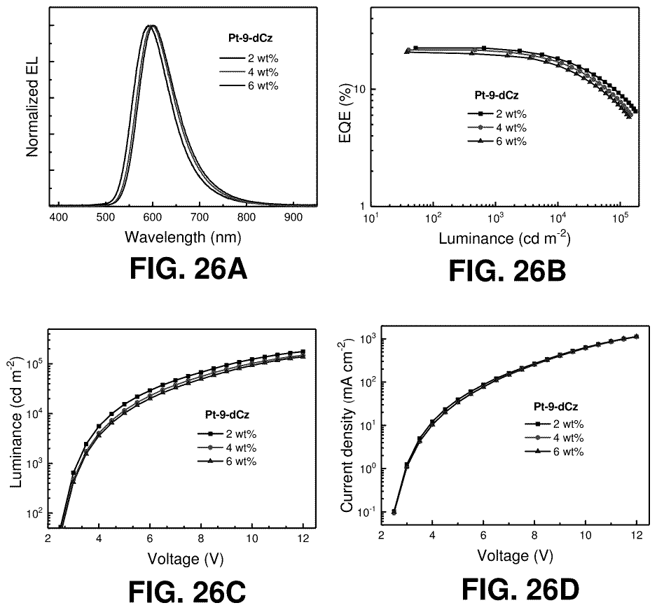

Vacuum-deposited devices fabricated with Pt-9-dCz exhibited electroluminescence at λₘₐₓ at 590, 596 and 600 nm at doping concentrations of 2-6 wt % (FIGS. 26A-26D). The performance data of the device with Pt-9-dCz are shown in Table 25.

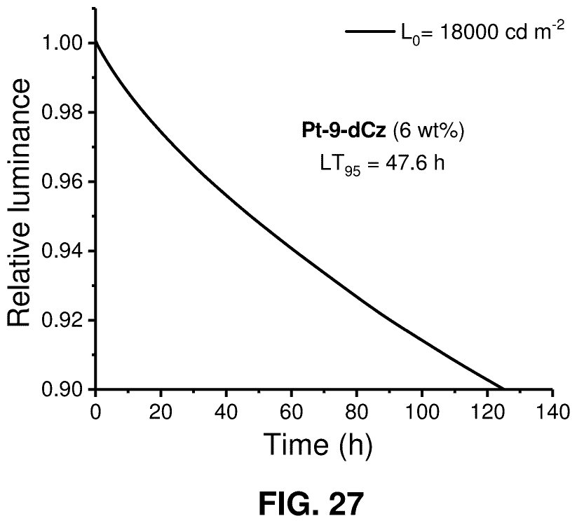

The operational lifetime of device fabricated with 6 wt % Pt-9-dCz is shown in FIG. 27 and summarized in Table 26.

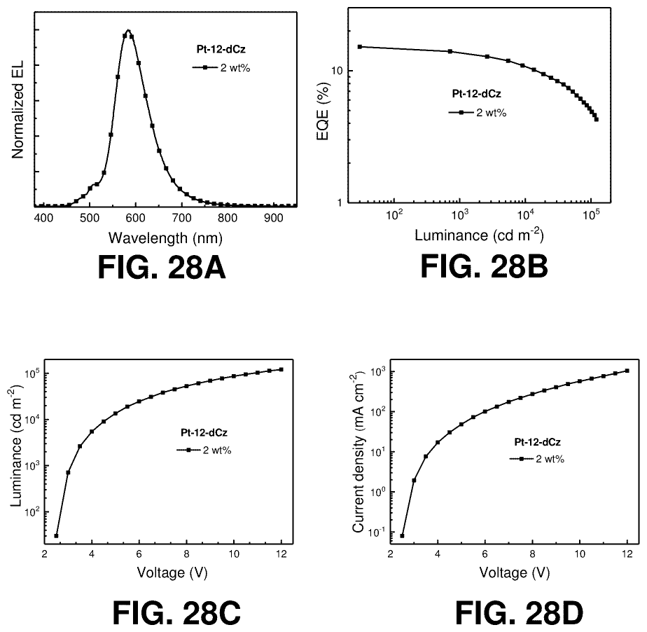

Vacuum-deposited devices fabricated with Pt-12-dCz exhibited electroluminescence at λₘₐₓ at 583 nm at doping concentrations of 2 wt % (FIGS. 28A-28D). The performance data of the device with Pt-12-dCz are shown in Table 27.

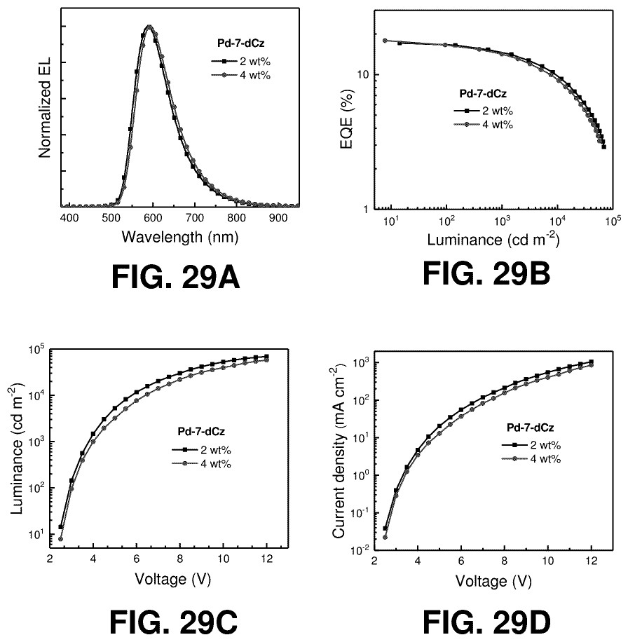

Vacuum-deposited devices fabricated with Pd-7-dCz exhibited electroluminescence at λₘₐₓ at 587 and 594 nm at doping concentrations of 2-4 wt % (FIGS. 29A-29D). The performance data of the device with Pt-7-dCz are shown in Table 28.

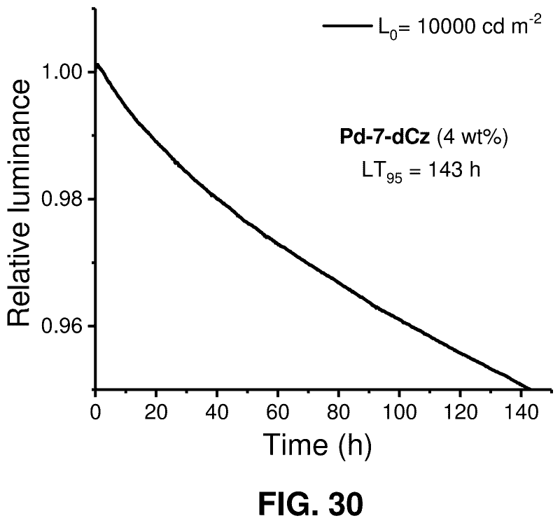

The operational lifetime of device fabricated with 4 wt % Pd-7-dCz is shown in FIG. 30 and summarized in Table 29.

TABLE 17
Photophysical properties of additional Pt(II) complexes

| | | λₑₘ | τ | Φ | kᵣ | kₙᵣ |
|---|---|---|---|---|---|---|
| Complex | Medium | (nm) | (μs) | (%) | (10⁵ s⁻¹) | (10⁵ s⁻¹) |
| Pt-4-dfCz | Toluene | 597 | 1.48 | 83 | 5.7 | 1.1 |
| | 2 wt % PMMA | 587 | 1.24 | 88 | 6.2 | 1.9 |
| Pt-6 | Toluene | 616 | 0.64 | 62 | 9.7 | 5.9 |
| | 2 wt % PMMA | 615 | 0.61 | 62 | 10.2 | 6.2 |
| Pt-7-dCz | Toluene | 617 | 0.97 | 64 | 6.6 | 3.7 |
| | 2 wt % PMMA | 613 | 0.96 | 82 | 8.5 | 1.9 |
| Pt-7-dtBuCz | Toluene | 650 | 0.57 | 41 | 7.2 | 10.4 |
| | 2 wt % PMMA | 650 | 0.46 | 42 | 9.1 | 12.6 |
| Pt-7-dCzCN | Toluene | 538 | 1.06 | 89 | 8.4 | 1.0 |
| | 2 wt % PMMA | 545 | 1.24 | 99 | 8.0 | 0.08 |
| Pt-8-dCz | Toluene | 645 | 1.70 | 78 | 4.6 | 1.3 |
| | 2 wt % PMMA | 637 | 1.42 | 85 | 6.0 | 1.1 |
| Pt-10-dCz | Toluene | 564 | 1.61 | 57 | 3.5 | 2.7 |
| | 2 wt % PMMA | 557 | 1.49 | 83 | 5.6 | 1.1 |
| Pt-11-dCz | Toluene | 563 | 1.36 | 78 | 5.7 | 1.6 |
| | 2 wt % PMMA | 557 | 1.17 | 91 | 7.8 | 0.8 |
| Pt-12-dCz | Toluene | 650 | 0.97 | 48 | 4.9 | 5.4 |
| | 2 wt % PMMA | 618 | 0.89 | 78 | 8.8 | 2.5 |

TABLE 18
Photophysical properties of additional Pd(II) complexes

| | | λₑₘ | τ | Φ | kᵣ | kₙᵣ |
|---|---|---|---|---|---|---|
| Complex | Medium | (nm) | (μs) | (%) | (10⁵ s⁻¹) | (10⁵ s⁻¹) |
| Pd-7-dCz | Toluene | 636 | 0.53 | 23 | 4.3 | 14.5 |
| | 2 wt % PMMA | 619 | 0.62 | 54 | 8.7 | 7.4 |
| Pd-7-dtBuCz | Toluene | 677 | 0.19 | 8 | 4.2 | 48.4 |
| | 2 wt % PMMA | 641 | 0.29 | 21 | 7.2 | 27.2 |

TABLE 19
Device data of Pt(II) complex, Pt-6

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-6 | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 102000 | 52.1 | 44.7 | 33.4 | 65.4 | 35.2 | 16.8 | 20.1 | 17.1 | 12.5 | 0.52, 0.48 | 87 | 579 |
| 4 wt % | 101000 | 42.8 | 36.7 | 28.3 | 53.5 | 28.6 | 14.3 | 18.3 | 15.5 | 11.7 | 0.54, 0.46 | 88 | 585 |
| 8 wt % | 88200 | 33.0 | 28.8 | 22.3 | 41.4 | 21.6 | 10.5 | 16.2 | 14.6 | 10.4 | 0.57. 0.43 | 89 | 594 |

TABLE 20
Device data of Pt(II) complex, Pt-7-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-7-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 122000 | 53.1 | 46,4 | 37.5 | 66.7 | 36.1 | 18.8 | 21.4 | 18.2 | 14.4 | 0.52, 0.47 | 98 | 578 |
| 4 wt % | 108000 | 50.3 | 44.1 | 34.8 | 63.2 | 32.7 | 16.8 | 22.6 | 18.7 | 14.4 | 0.54, 0.46 | 89 | 584 |
| 8 wt % | 92500 | 45.9 | 39.5 | 28.9 | 57.7 | 27.8 | 12.9 | 22.5 | 18.1 | 13.1 | 0.56, 0.44 | 90 | 590 |

TABLE 21
Device data of Pt(II) complex, Pt-7-dCzCN

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-7-dCzCN | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 156000 | 91.3 | 84.2 | 67.0 | 115 | 85.3 | 46.7 | 25.2 | 23.2 | 18.5 | 0.35, 0.61 | 79 | 530 |
| 6 wt % | 238000 | 103 | 99.6 | 85.3 | 129 | 106 | 67.0 | 28.4 | 27.0 | 23.4 | 0.38, 0.60 | 79 | 538 |
| 8 wt % | 231000 | 94.4 | 92.2 | 80.3 | 108 | 98.5 | 65.5 | 27.7 | 26.7 | 23.3 | 0.38. 0.59 | 79 | 540 |

TABLE 22
Operational lifetime of device based on Pt-7-dCzCN

| Conc. | L₀ [cd m⁻²] | LT₉₅@L₀ [h] | n | LT₉₅@1000 cd m⁻² [h] |
|---|---|---|---|---|
| 8 wt/wt % | 28800 | 16.7 | 1.7 | 5054 |

n denotes for acceleration factor in LT(L₁) = LT(L₀) × (L₀/L₁)ⁿ and 1.7

TABLE 23
Device data of Pt(II) complex, Pt-7-dCzCN:BN Green Emitter

| | | CE [cd A⁻¹] | | | PE [Im W⁻¹] | | | EQE [%] | | | | | |
|---|---|---|---|---|---|---|---|---|---|---|---|---|---|
| Pt-7-dCzCN: | L | | at 1000 | at 10000 | | at 1000 | at 10000 | | at 1000 | at 10000 | CIE | FWHM | λₘₐₓ |
| BN green | [cd m⁻²] | Max | cd m⁻² | cd m⁻² | Max | cd m⁻² | cd m⁻² | Max | cd m⁻² | cd m⁻² | [(x, y)] | [nm] | [nm] |
| 8 wt %:1 wt % | 205000 | 112 | 93.4 | 71.3 | 160 | 97.4 | 62.9 | 30.1 | 24.4 | 19.2 | 0.34, | 33 | 527 |
| | | | | | | | | | | | 0.63 | | |
| 8 wt %:0.5 wt % | 230000 | 112 | 99.7 | 83.8 | 158 | 109 | 66.1 | 30.9 | 27.4 | 23.5 | 0.36, | 49 | 526 |
| | | | | | | | | | | | 0.61 | | |
| 0:1 wt % | 81300 | 71.7 | 26.1 | 16.0 | 102 | 25.5 | 10.5 | 17.9 | 6.46 | 4.2 | 0.25, | 26 | 525 |
| | | | | | | | | | | | 0.67 | | |

TABLE 24
Operational lifetime of device based
on Pt-7-dCzCN:BN Green Emitter

| Conc. of | L₀ | LT₉₅@L₀ | | LT₉₅@1000 cd m⁻² |
|---|---|---|---|---|
| Pt-7-dCzCN:BN green | [cd m⁻²] | [h] | n | [h] |
| 8 wt %:0.5 wt % | 27000 | 7.52 | 1.7 | 2039 |
| 0:1 wt % | 6000 | 13.2 | 1.7 | 277 |

n denotes for acceleration factor in LT(L₁) = LT(L₀) × (L₀/L₁)ⁿ and 1.7

TABLE 25
Device data of Pt(II) complex, Pt-9-dCz

| | | CE [cd A⁻¹] | | | PE [lm W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-9-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 176500 | 51.6 | 50.5 | 42.2 | 64.0 | 50.9 | 29.4 | 22.5 | 22.2 | 18.2 | 0.55, 0.45 | 94 | 590 |
| 4 wt % | 148800 | 43.4 | 42.5 | 34.8 | 54.1 | 41.4 | 22.3 | 21.6 | 21.1 | 17.1 | 0.57, 0.43 | 94 | 596 |
| 6 wt % | 138000 | 38.1 | 36.8 | 30.2 | 47.8 | 35.9 | 19.0 | 20.7 | 19.7 | 15.9 | 0.58, 0.42 | 94 | 600 |

TABLE 26
Operational lifetime of device based on Pt-9-dCz

| Conc. | L₀ [cd m⁻²] | LT₉₅@L₀ [h] | n | LT₉₅@1000 cd m⁻² [h] |
|---|---|---|---|---|
| 6 wt/wt % | 18000 | 47.6 | 1.7 | 6479 |

n denotes for acceleration factor in LT(L₁) = LT(L₀) × (L₀/L₁)ⁿ and 1.7

TABLE 27
Device data of Pt(II) complex, Pt-12-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pt-12-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 121000 | 37.4 | 36.5 | 29.8 | 47.0 | 38.2 | 20.7 | 15.2 | 13.9 | 10.8 | 0.51. 0.47 | 81 | 583 |

TABLE 28
Device data of Pd(II) complex, Pd-7-dCz

| | | CE [cd A⁻¹] | | | PE [Im W⁻¹] | | | EQE [%] | | | | | |
|---|---|---|---|---|---|---|---|---|---|---|---|---|---|
| | L | | at 1000 | at 10000 | | at 1000 | at 10000 | | at 1000 | at 10000 | CIE | FWHM | λₘₐₓ |
| Pd-7-dCz | [cd m⁻²] | Max | cd m⁻² | cd m⁻² | Max | cd m⁻² | cd m⁻² | Max | cd m⁻² | cd m⁻² | [(x, y)] | [nm] | [nm] |
| 2 wt % | 68700 | 37.2 | 32.8 | 22.2 | 46.7 | 27.6 | 12.2 | 17.2 | 14.7 | 9.89 | 0.54, 0.46 | 101 | 587 |
| 4 wt % | 57420 | 35.2 | 28.9 | 18.9 | 44.3 | 22.7 | 9.22 | 17.9 | 14.2 | 9.26 | 0.55. 0.44 | 103 | 594 |

TABLE 29
Operational lifetime of device based on Pd-7-dCz

| Conc. | L₀ [cd m⁻²] | LT₉₅@L₀ [h] | n | LT₉₅@1000 cd m⁻² [h] |
|---|---|---|---|---|
| 4 wt/wt % | 10000 | 142.8 | 1.7 | 7157 |

n denotes for acceleration factor in LT(L₁) = LT(L₀) × (L₀/L₁)ⁿ and 1.7

### Example 6. Variable Temperature Emission Lifetime Experiments

### Materials and Methods

For the measurement of emission spectra and lifetime under variable temperature, OPTISTAT™ cryostat was used to precisely control the sample temperature, from cryogenic temperature of 77 K up to room temperature. The sample was placed inside the cryostat, which was equipped with a temperature controller using cryogen flow (liquid nitrogen) and resistive heater to stabilize the desired temperature.

### Results

Variable-temperature emission lifetime measurements showed that the emission lifetimes of these metal complexes increased exponentially as the temperature decreased from 297 K to 77 K. The temperature-dependent emission lifetime data were fitted using an Arrhenius plot (ln k_{TADF} versus 1/T) to determine the singlet-triplet energy gap (ΔE_{ST}). A small energy gap between the singlet and triplet excited states facilitated up-conversion from triplet to singlet excited state through reverse intersystem crossing (RISC), thereby promoting spin-allowed radiative decay from singlet excited state to ground state.

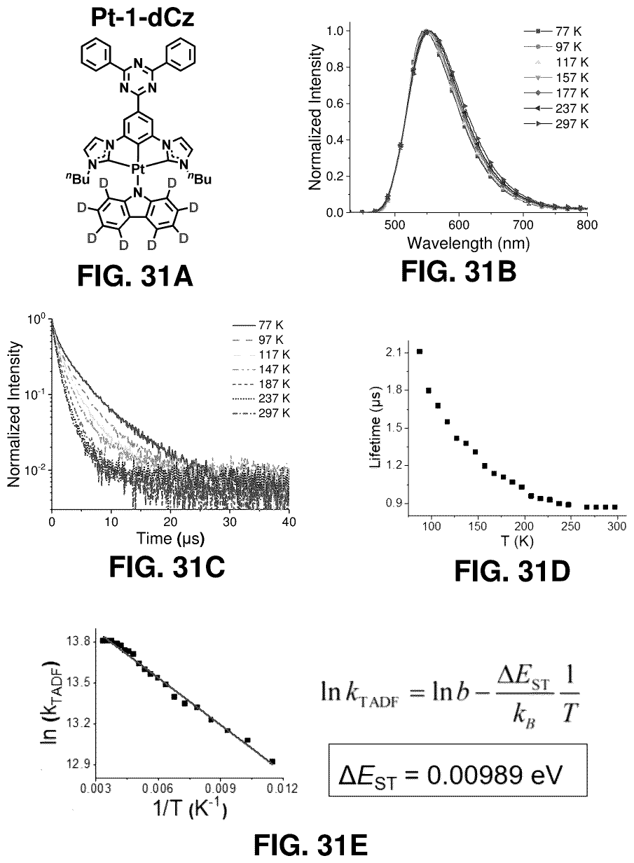

The normalized temperature-dependent PL spectra (FIG. 31B), PL intensity decay curves (FIG. 31C) and emission lifetime plot (FIG. 31D) with the corresponding Arrhenius plot with linear fitting to the kinetic data (FIG. 31E) of Pt-1-dCz in 2 wt % PMMA film are shown in FIGS. 31B-31E.

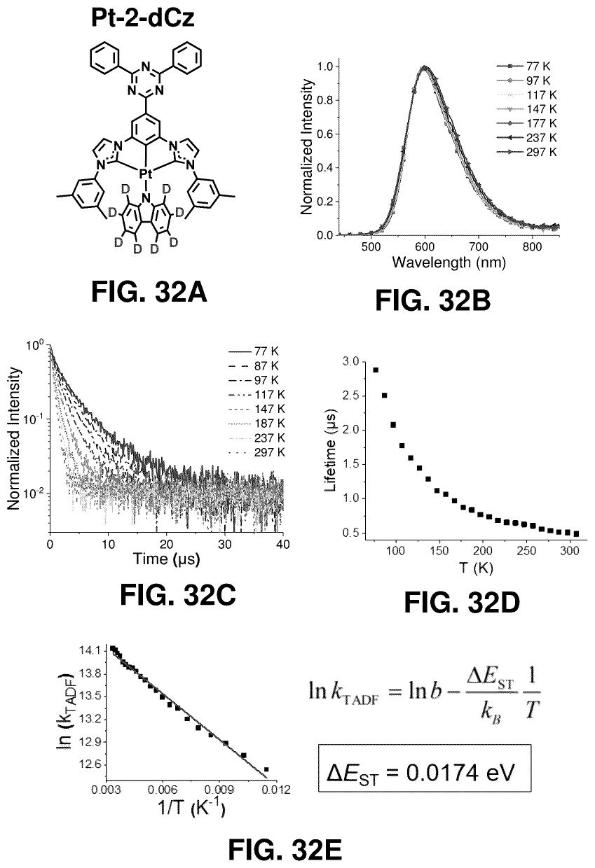

The normalized temperature-dependent PL spectra (FIG. 32B), PL intensity decay curves (FIG. 32C), and emission lifetime plot (FIG. 32D) with the corresponding Arrhenius plot with linear fitting to the kinetic data (FIG. 32E) of Pt-2-dCz in 2 wt % PMMA film are shown in FIGS. 32B-32E.

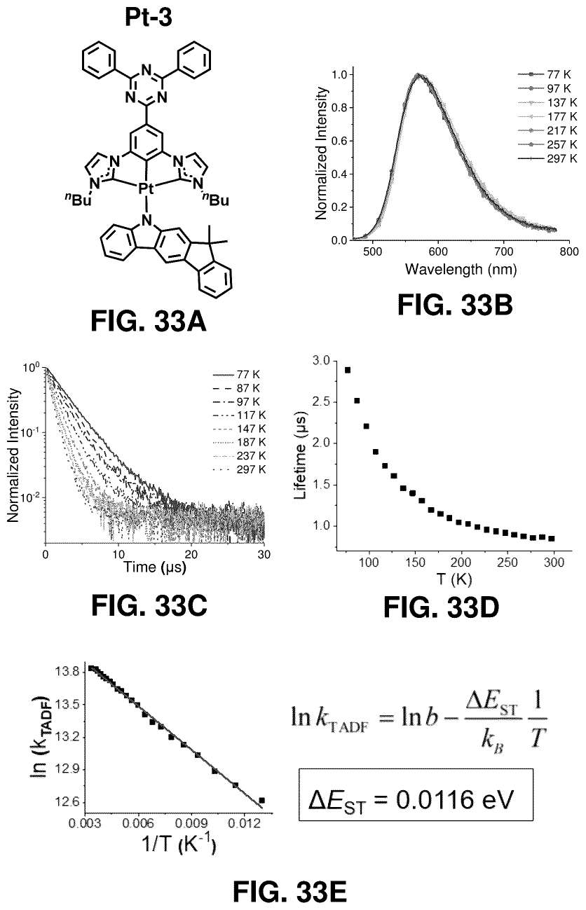

The normalized temperature-dependent PL spectra (FIG. 33B), PL intensity decay curves (FIG. 33C), and emission lifetime plot (FIG. 33D) with the corresponding Arrhenius plot with linear fitting to the kinetic data (FIG. 33E) of Pt-3 in 2 wt % PMMA film are shown in FIGS. 33B-33E.

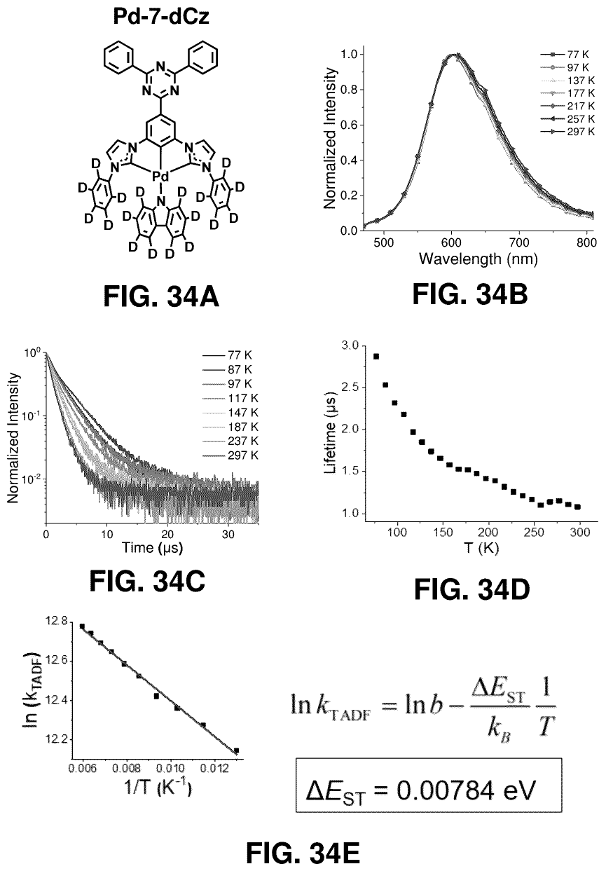

The normalized temperature-dependent PL spectra (FIG. 34B), PL intensity decay curves (FIG. 34C) and emission lifetime plot (FIG. 34D) with the corresponding Arrhenius plot with linear fitting to the kinetic data (FIG. 34E) of Pd-7-dCz in 2 wt % PMMA film are shown in FIGS. 34B-34E.

It is understood that the disclosed method and compositions are not limited to the particular methodology, protocols, and reagents described as these can vary. It is also to be understood that the terminology used herein is for the purpose of describing particular embodiments only, and is not intended to limit the scope of the present invention which will be limited only by the appended claims.

Those skilled in the art will recognize, or be able to ascertain using no more than routine experimentation, many equivalents to the specific embodiments of the method and compositions described herein. Such equivalents are intended to be encompassed by the following claims.

We claim:

1. A metal complex having a structure of: 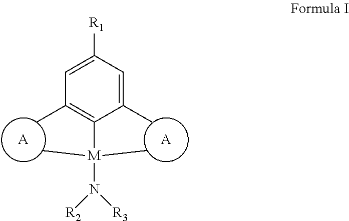
wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) R₁ is 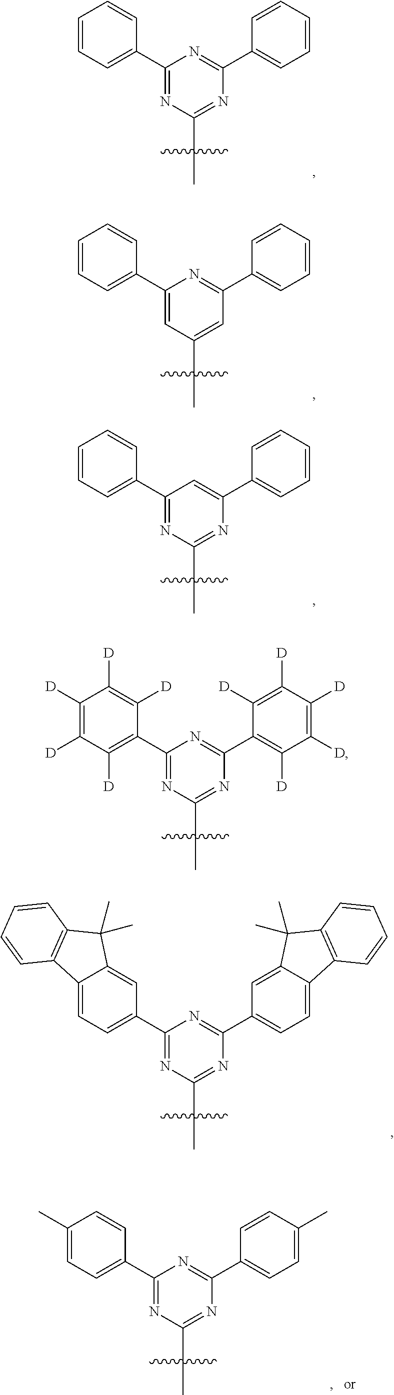 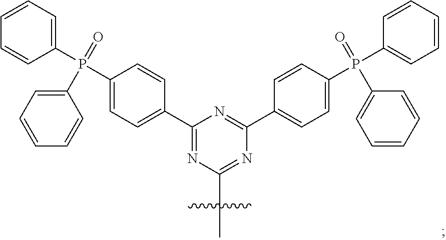 [SMILES: *c1nc(-c2ccc(P(=O)(c3ccccc3)c3ccccc3)cc2)nc(-c2ccc(P(=O)(c3ccccc3)c3ccccc3)cc2)n1]
(iv) R₂ and R₃ are independently a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
R₂ and R₃ together with the nitrogen atom to which they are attached form a fused ring system; and
(v) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

2. The metal complex of claim 1, having a structure of: 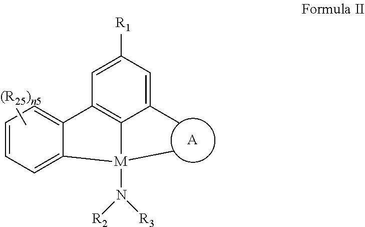
wherein: n5 is an integer from 0 to 4, from 0 to 3, from 0 to 2, or 0 or 1; each occurrence of R₂₅ is independently hydrogen, deuterium, an unsubstituted C₁-C₆ alkyl, 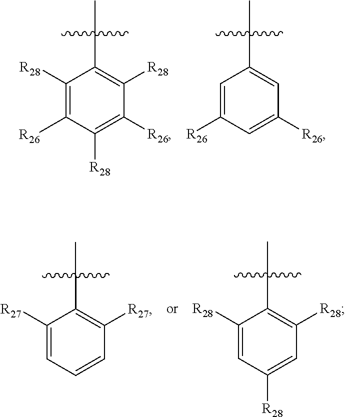
and each R₂₆, R₂₇, and R₂₈ is independently hydrogen, deuterium, or an unsubstituted C₁-C₁₂ alkyl.

3. The metal complex of claim 1, having a structure of: 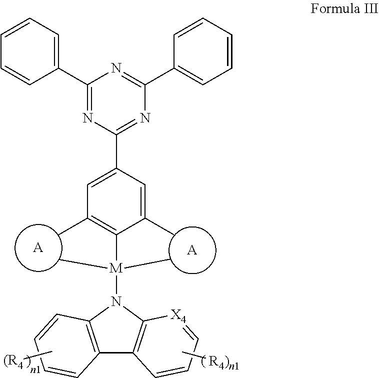
wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) X₄ is C or N;
(iv) each n1 is independently an integer from 0 to 4, from 0 to 3, from 0 to 2, or 0 or 1;
(v) each occurrence of R₄ is independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
two neighboring R₄ together with the carbon atom to which they are attached form a fused ring system;
(vi) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

4. The metal complex of claim 3, having a structure of: 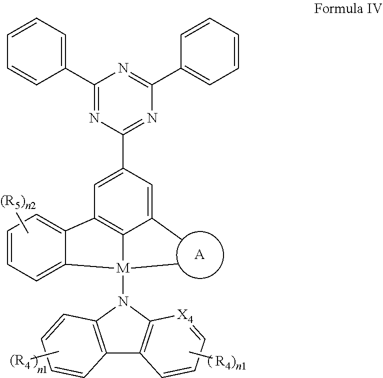
wherein: n2 is an integer from 0 to 4, from 0 to 3, from 0 to 2, or 0 or 1; each occurrence of R₅ is independently hydrogen, deuterium, an unsubstituted C₁-C₆ alkyl, 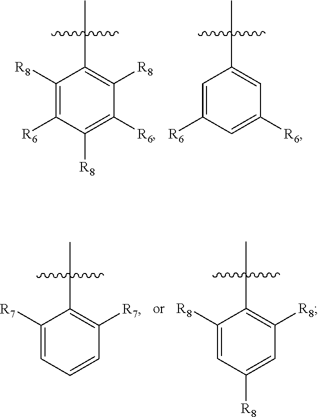
and each R₆, R₇, and R₈ is independently hydrogen, deuterium, or an unsubstituted C₁-C₁₂ alkyl.

5. The metal complex of claim 1, having a structure of: 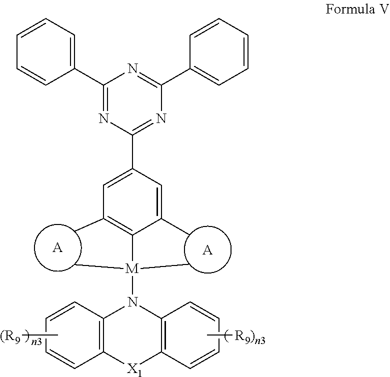
wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) each n3 is independently an integer from 0 to 4, from 0 to 3, from 0 to 2, or 0 or 1;
(iv) each occurrence of R₉ is independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
two neighboring R₉ together with the carbon atom to which they are attached form a fused ring system;
(v) λ₁ is —CR₁₀R₁₁, —C═R₁₂, O, S, or Se;
(vi) R₁₀ and R₁₁ are independently hydrogen, deuterium, a substituted alkyl, an unsubstituted alkyl, a substituted aryl (e.g., a substituted phenyl), an unsubstituted aryl (e.g., an unsubstituted phenyl), or a substituted heteroaryl;
(vii) R₁₂ is O, S or Se; and
(viii) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

6. The metal complex of claim 5, having a structure of: 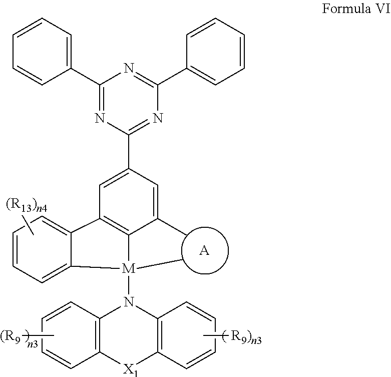
wherein: n4 is an integer from 0 to 4, from 0 to 3, from 0 to 2, or 0 or 1; each occurrence of R₁₃ is independently hydrogen, deuterium, an unsubstituted C₁-C₆ alkyl, 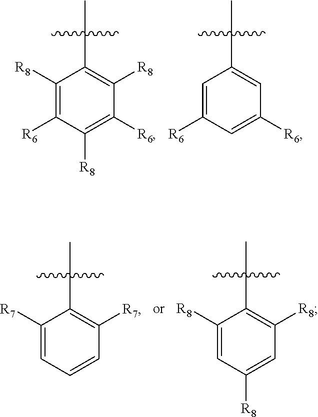
and each R₆, R₇, and R₈ is independently hydrogen, deuterium, or an unsubstituted C₁-C₁₂ alkyl.

7. The metal complex of claim 1, having a structure of: 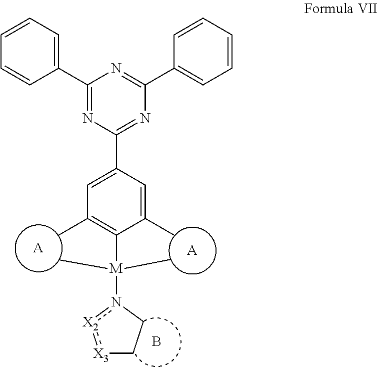
wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) X₂ and X₃ are independently —CR₁₅R₁₆, —C═R₁₇, N, O, or S;
(vi) R₁₅ and R₁₆ are independently hydrogen, deuterium, substituted alkyl, an unsubstituted alkyl, a substituted aryl (e.g., a substituted phenyl), an unsubstituted aryl (e.g., an unsubstituted phenyl), or a substituted heteroaryl;
(vii) R₁₇ is O or S;
(iii) B, when present, together with the carbon atoms to which it is attached, form a substituted aryl or an unsubstituted aryl;
(iv) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

8. The metal complex of claim 1, having a structure of: 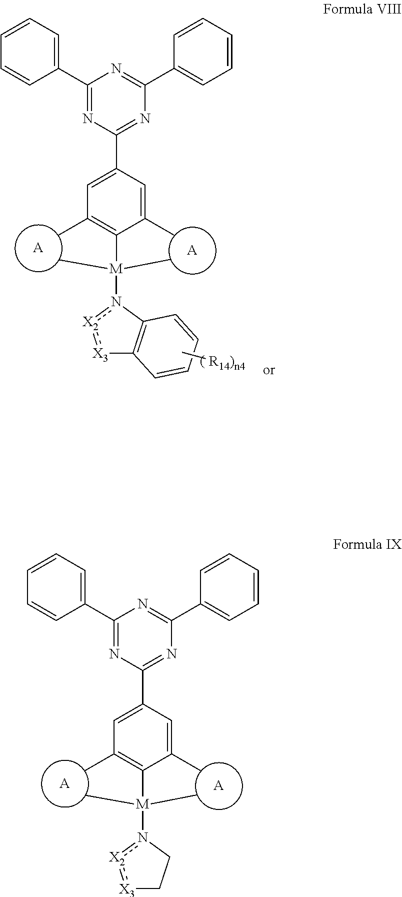
wherein:
(i) M is Pt, Pd, or Au;
(ii) each \textcircled{A} is independently a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring;
(iii) X₂ and X₃ are independently —CR₁₅R₁₆, —C═R₁₇, N, O, or S;
(vi) R₁₅ and R₁₆ are independently hydrogen, deuterium, a substituted alkyl, an unsubstituted alkyl, a substituted aryl (e.g., a substituted phenyl), or an unsubstituted aryl (e.g., an unsubstituted phenyl);
(vii) R₁₇ is O or S;
(iii) n4 is independently an integer from 0 to 4, from 0 to 3, from 0 to 2, or 0 or 1;
(iv) each occurrence of R₁₄ is independently hydrogen, deuterium, a substituted alkyl, an unsubstituted alkyl, a substituted aryl, an unsubstituted aryl, a substituted heteroaryl, an unsubstituted heteroaryl, a substituted polyaryl, an unsubstituted polyaryl, a substituted heteropolyaryl, an unsubstituted heteropolyaryl, a substituted cyclic ring, or an unsubstituted cyclic ring, or
two neighboring R₁₄ together with the carbon atom to which they are attached form a fused ring system;
(v) the substituent(s), when present, are independently a deuterium, a substituted C₁-C₁₂ alkyl, an unsubstituted C₁-C₁₂ alkyl, a substituted C₁-C₁₂ alkenyl, an unsubstituted C₁-C₁₂ alkenyl, a substituted C₁-C₁₂ alkynyl, an unsubstituted C₁-C₁₂ alkynyl, a substituted aryl (e.g., phenyl), an unsubstituted aryl (e.g., phenyl), a substituted heteroaryl, an unsubstituted heteroaryl, a substituted polyaryl, an unsubstituted polyaryl, a substituted heteropolyaryl, an unsubstituted heteropolyaryl, an amino, an amido, a carbonyl, an alkoxy, a cyano, an isocyano, a nitro, hydroxyl, a halide, an oxo, a silyl, a sulfinyl, a sulfonyl, a sulfonic acid, a phosphonium, a phosphanyl, a phosphoryl, a phosphonyl, or a thiol.

9. The metal complex of claim 1, wherein each 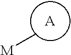
is 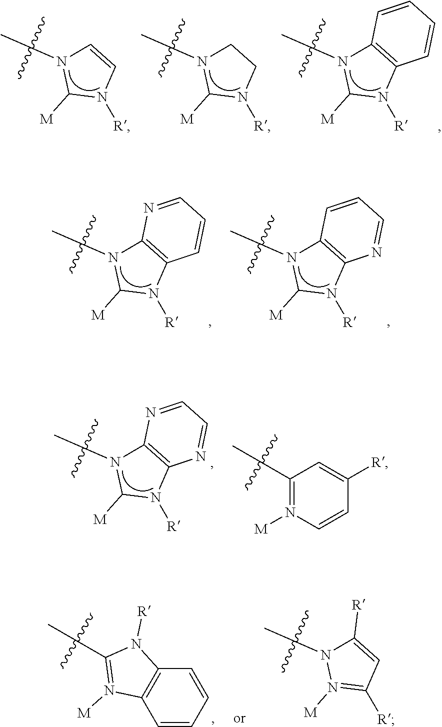
each R′ is independently a substituted C₁-C₆ alkyl, an unsubstituted C₁-C₆ alkyl, a substituted aryl, or an unsubstituted aryl; and the substituent(s), when present, are independently a deuterium or an unsubstituted C₁-C₁₂ alkyl.

10. The metal complex of claim 9, wherein each R′ is independently hydrogen, deuterium, an unsubstituted C₁-C₆ alkyl, 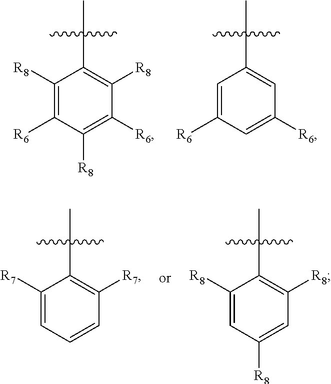
and each R₆, R₇, and R₈ is independently hydrogen, deuterium, or an unsubstituted C₁-C₁₂ alkyl; optionally wherein each R′ is independently

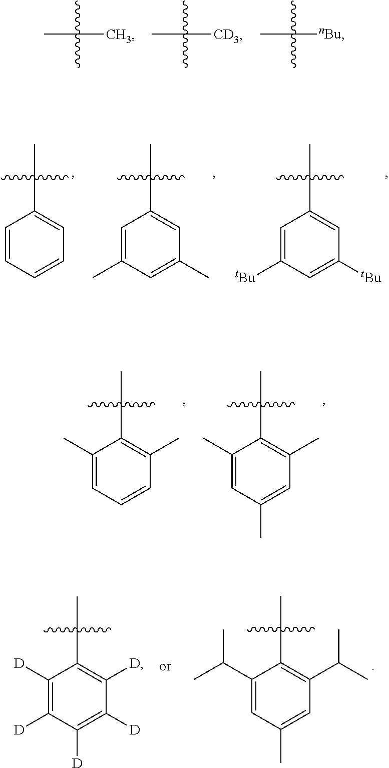

11. The metal complex of claim 1, having any one of the following structures: 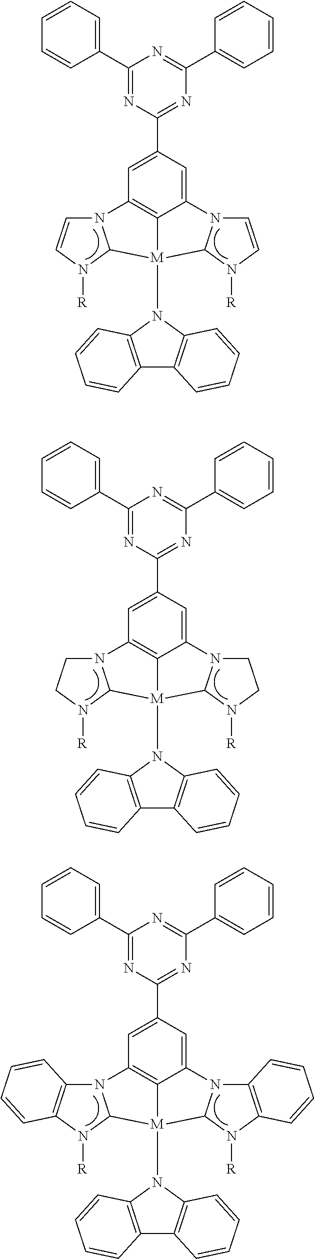 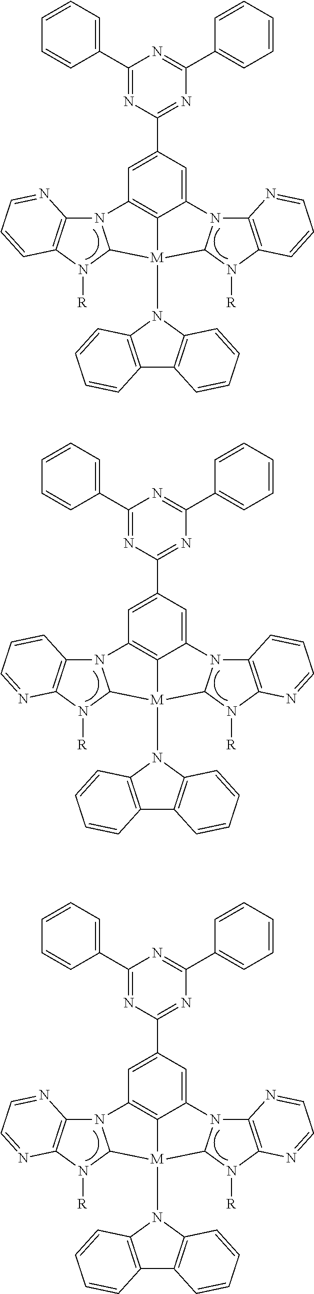 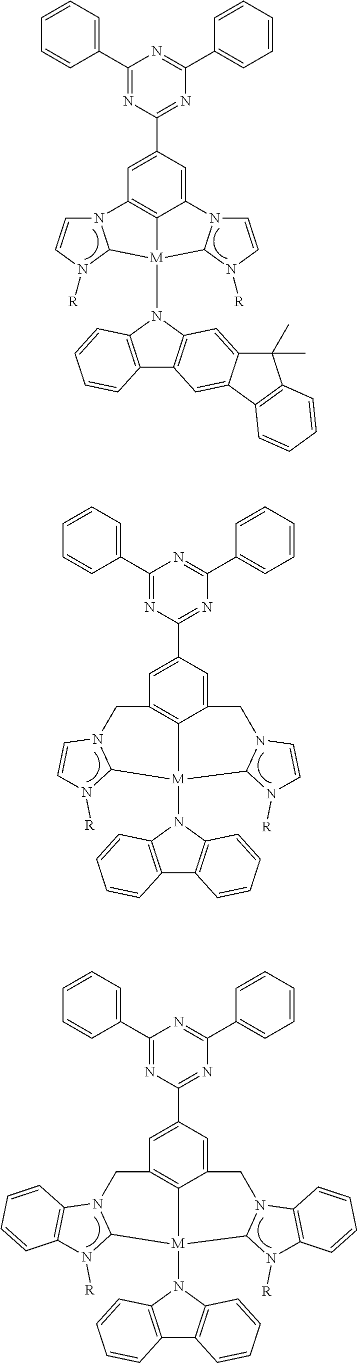 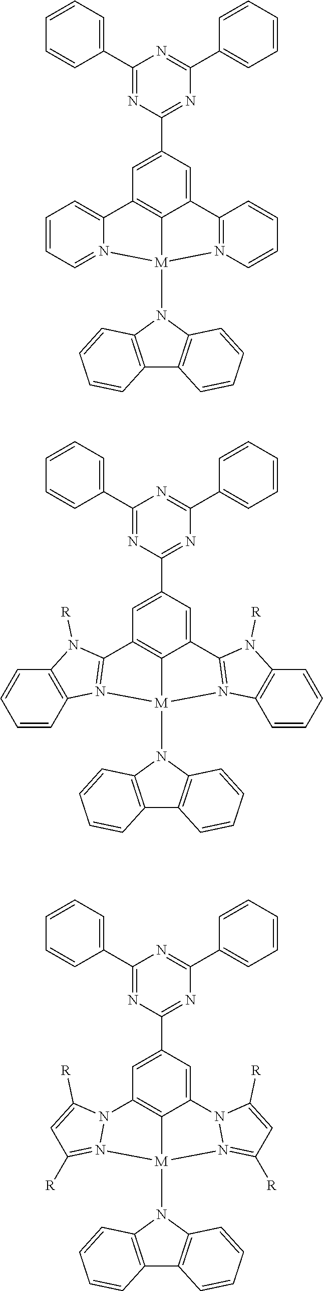 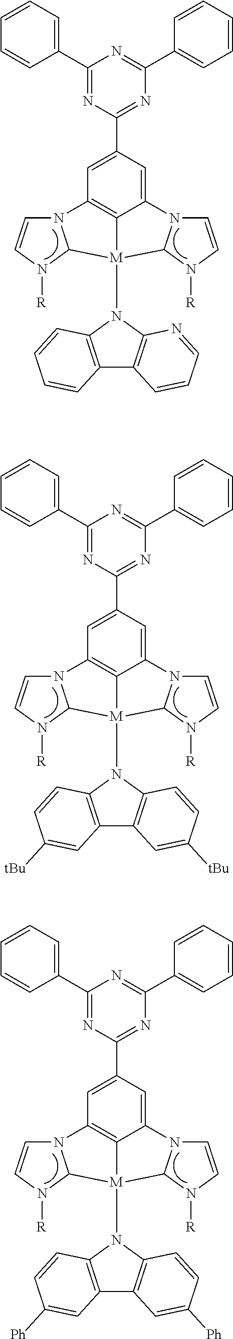 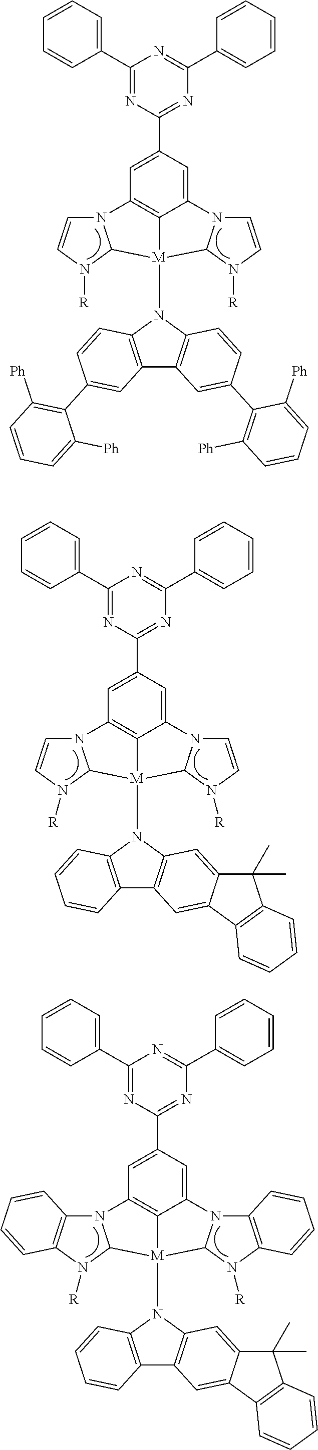 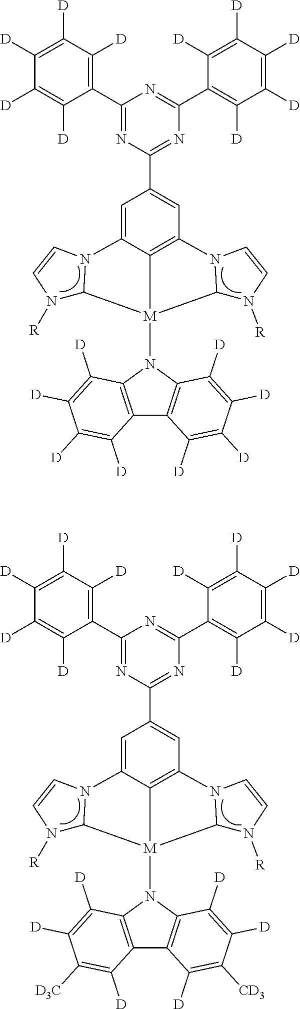 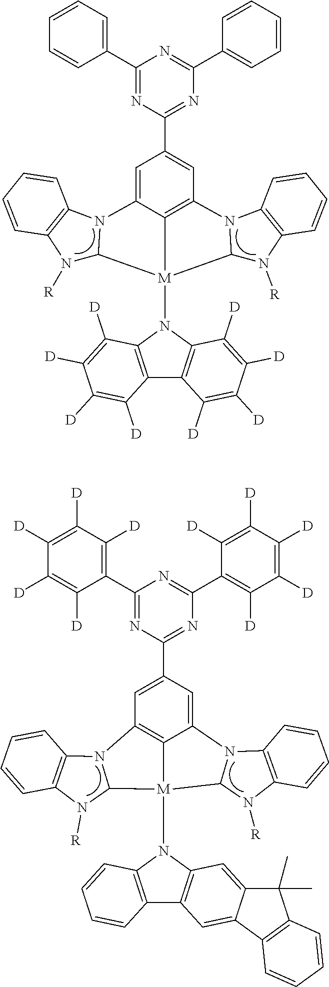 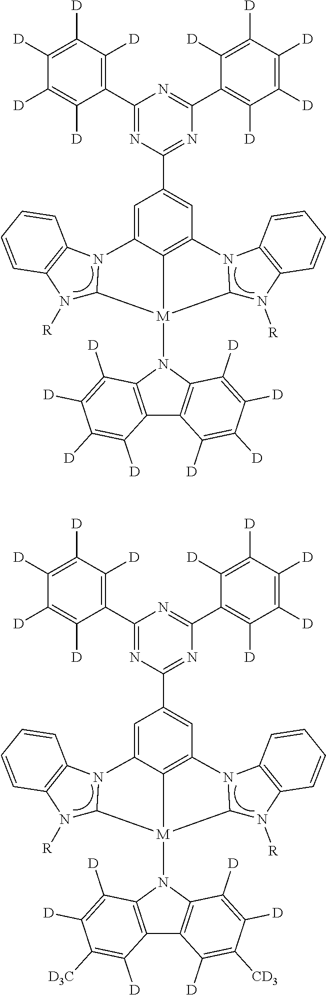 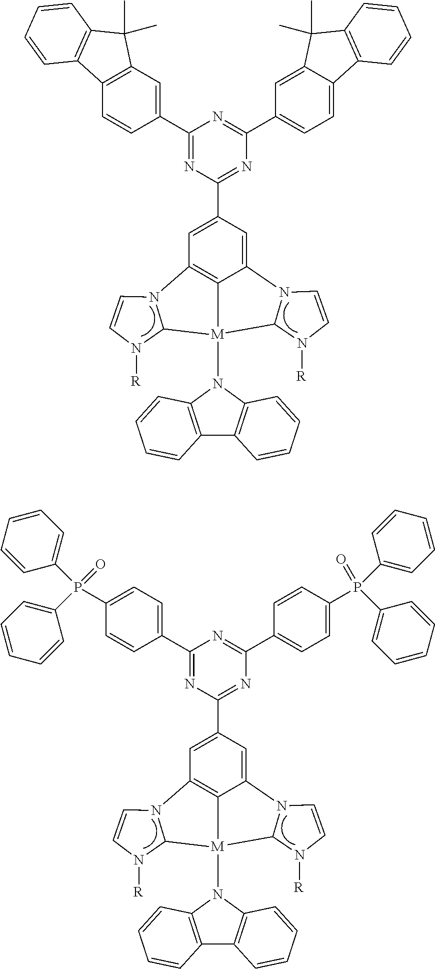 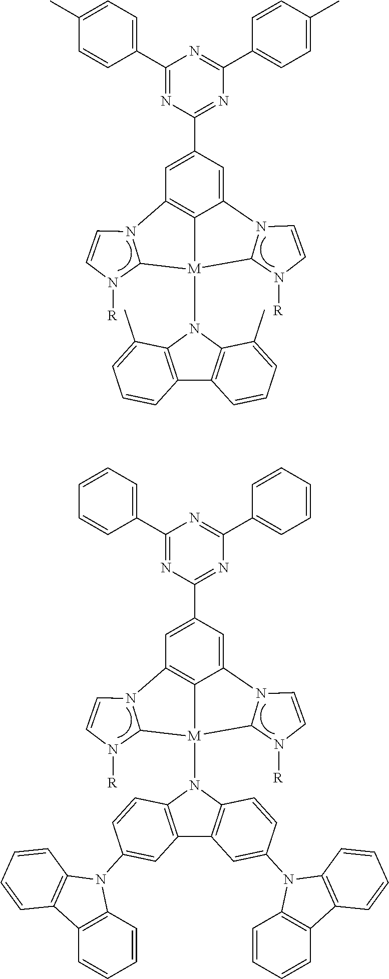 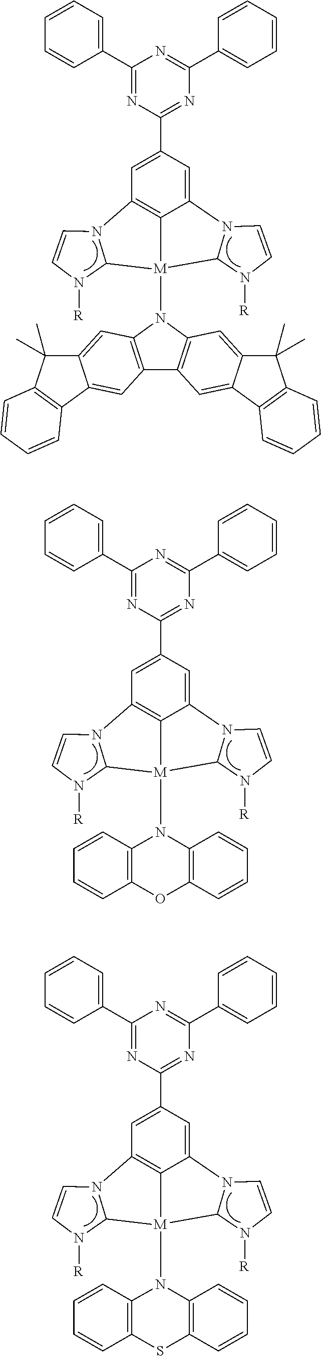 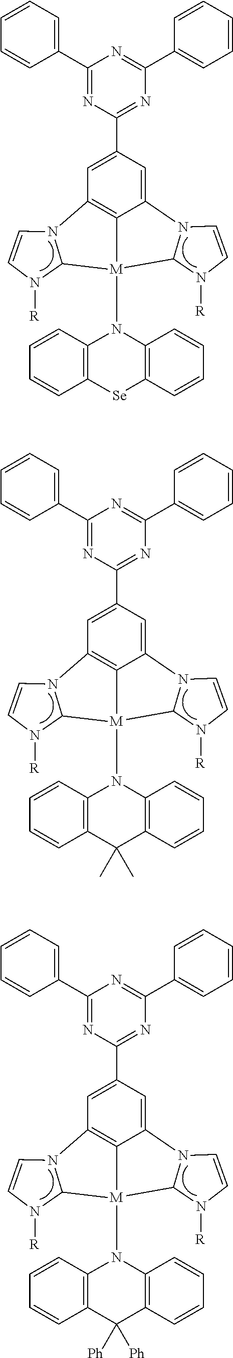 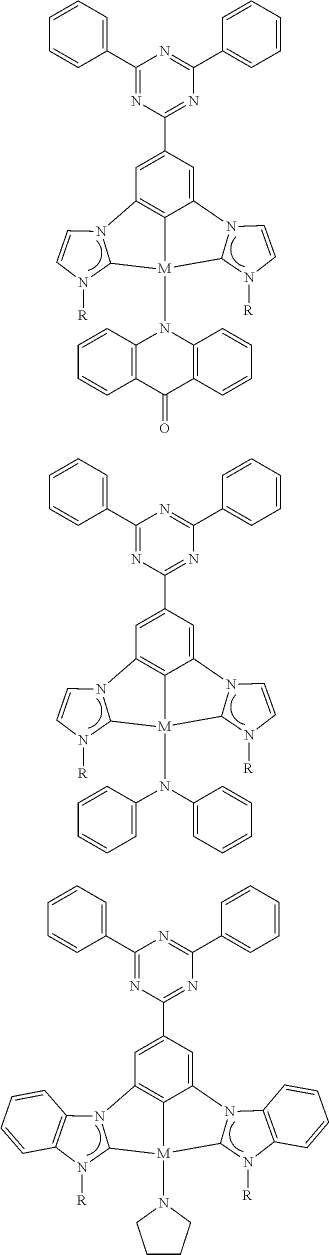 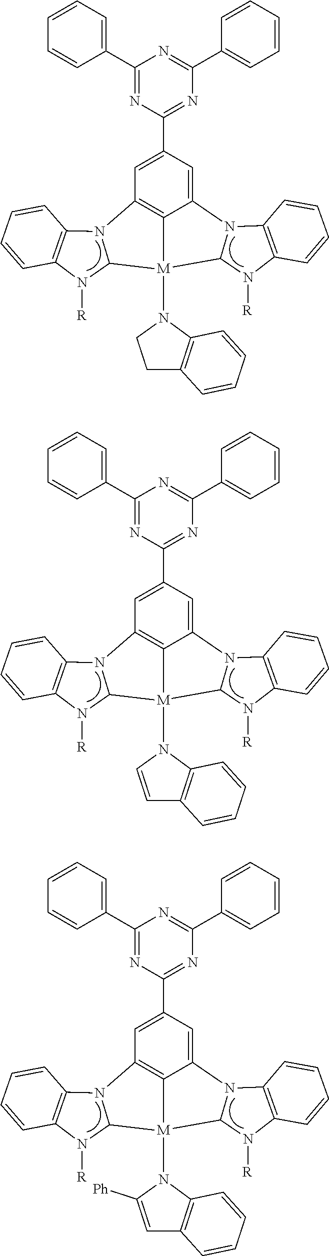 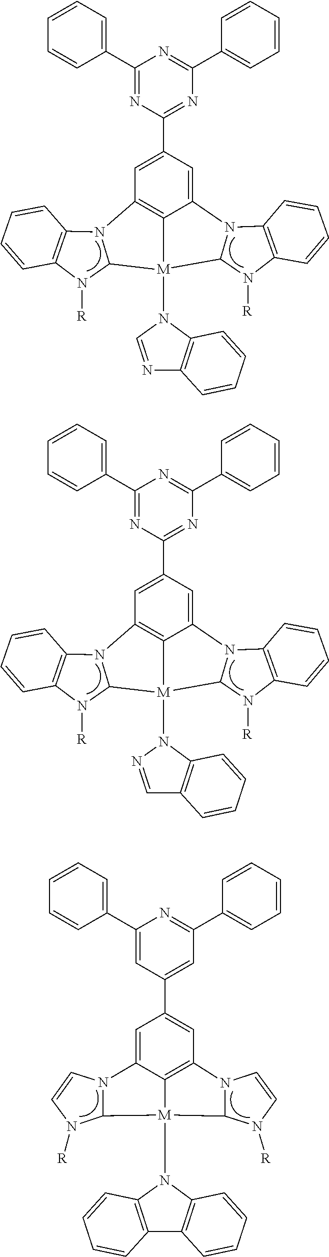 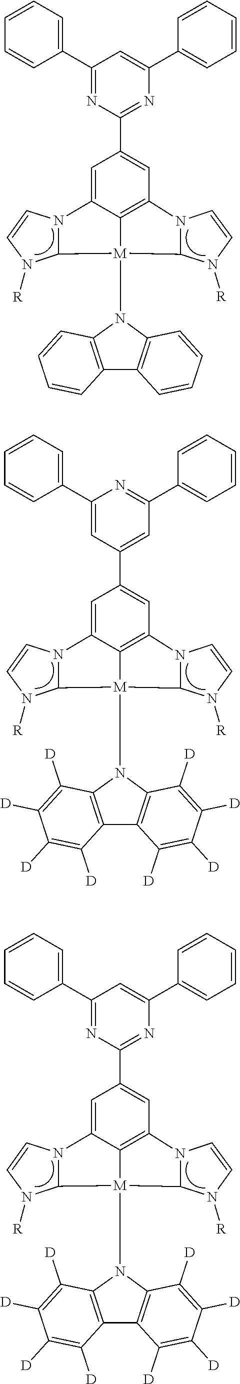
wherein M is Pt, Pd, or Au; each R is independently a substituted C₁-C₆ alkyl, an unsubstituted C₁-C₆ alkyl, a substituted phenyl, or an unsubstituted phenyl; and the substituent(s), when present, are independently an unsubstituted C₁-C₁₂ alkyl.

12. The metal complex of claim 11, wherein each R is independently an unsubstituted C₁-C₆ alkyl, 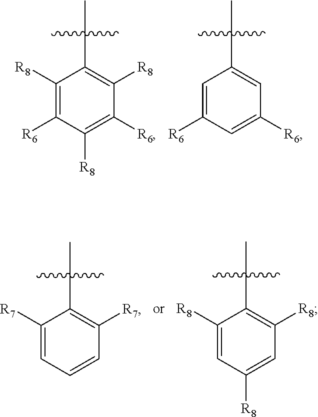
and each R₆, R₇, and R₈ is independently hydrogen, deuterium, or an unsubstituted C₁-C₁₂ alkyl; optionally wherein each R is independently

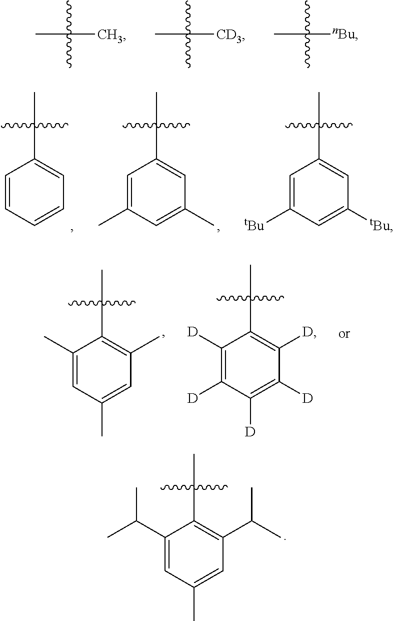

13. The metal complex of claim 1, having any one of the following structures:

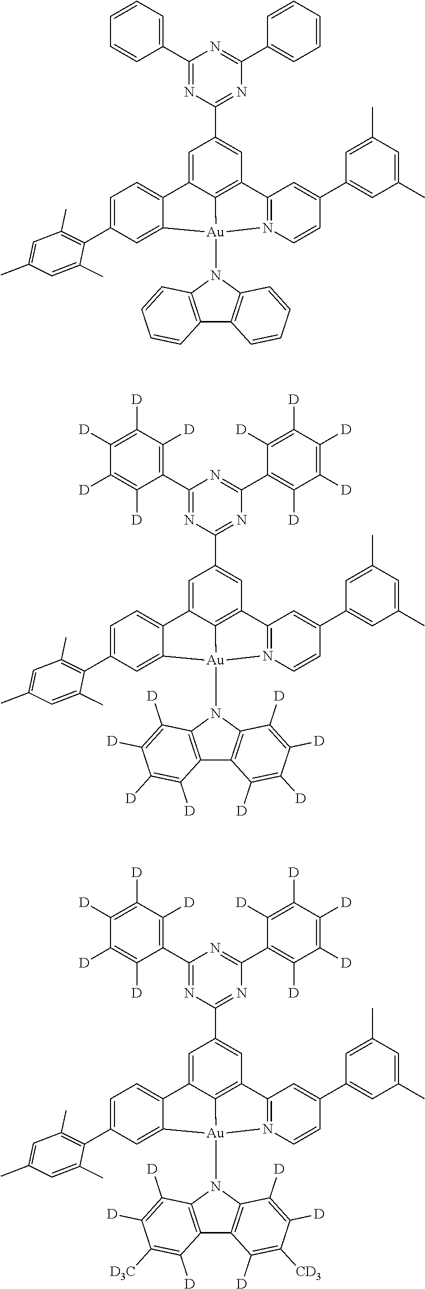

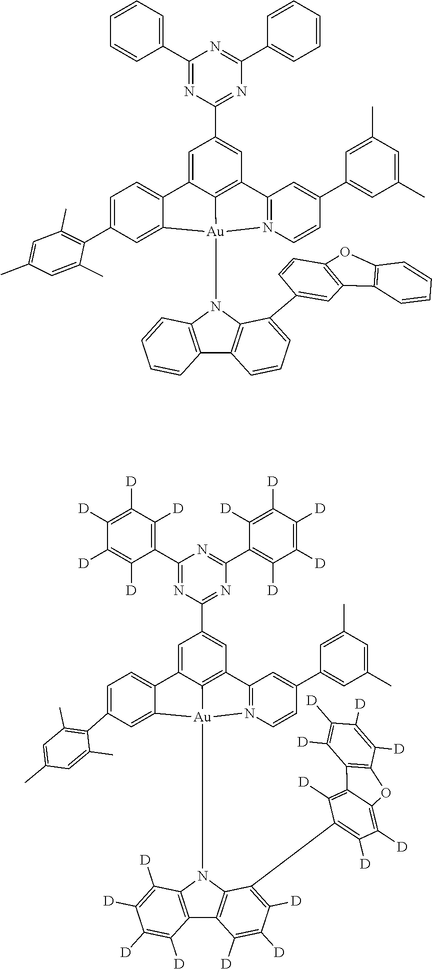

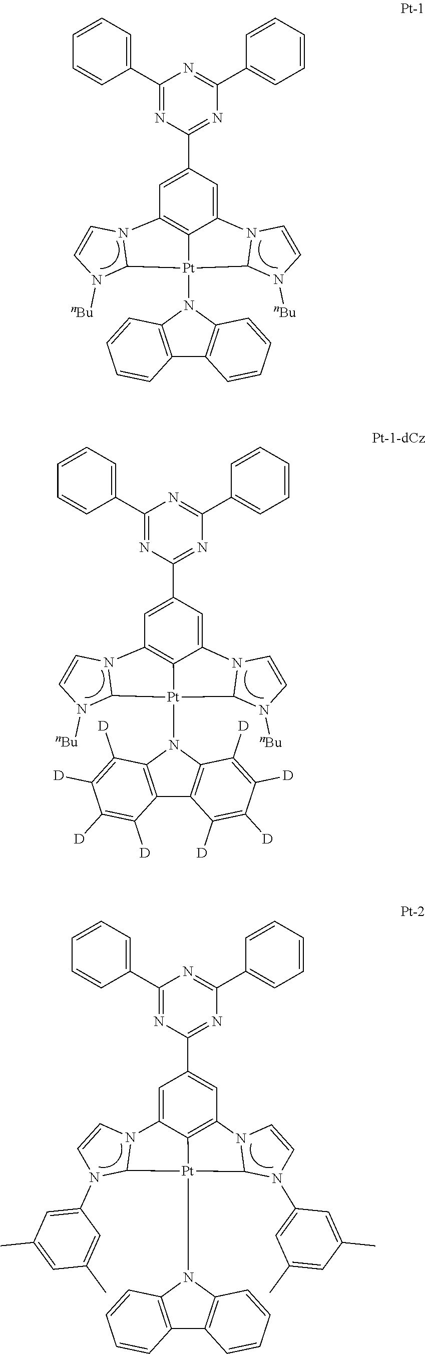

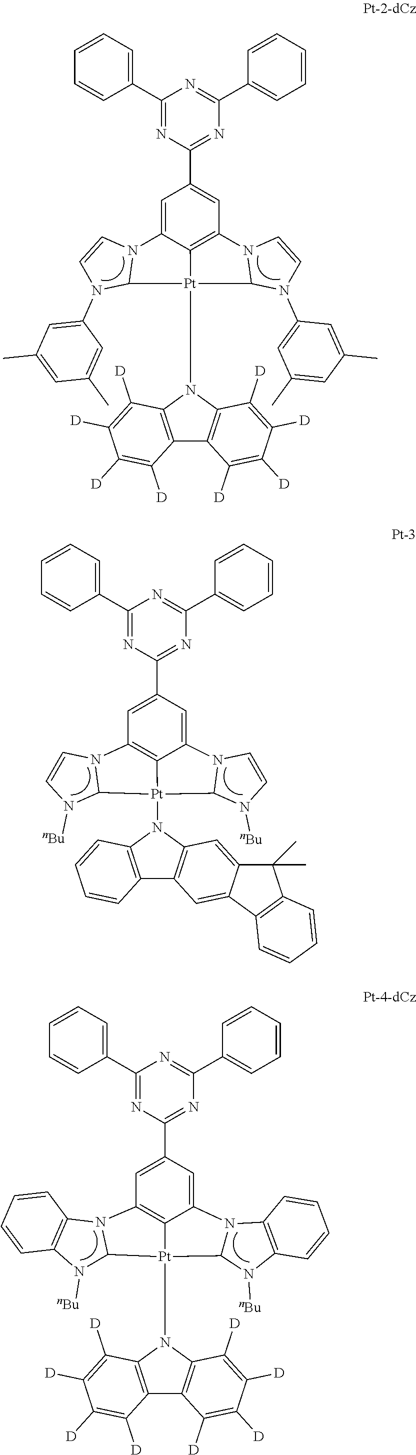

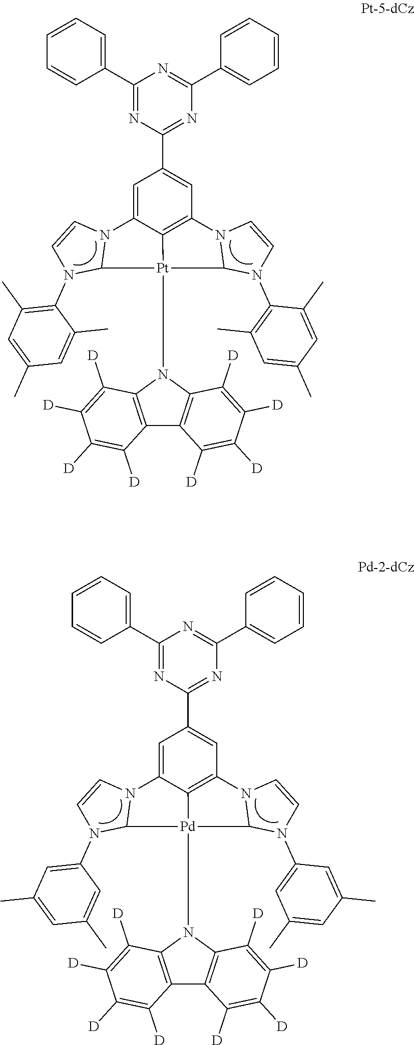

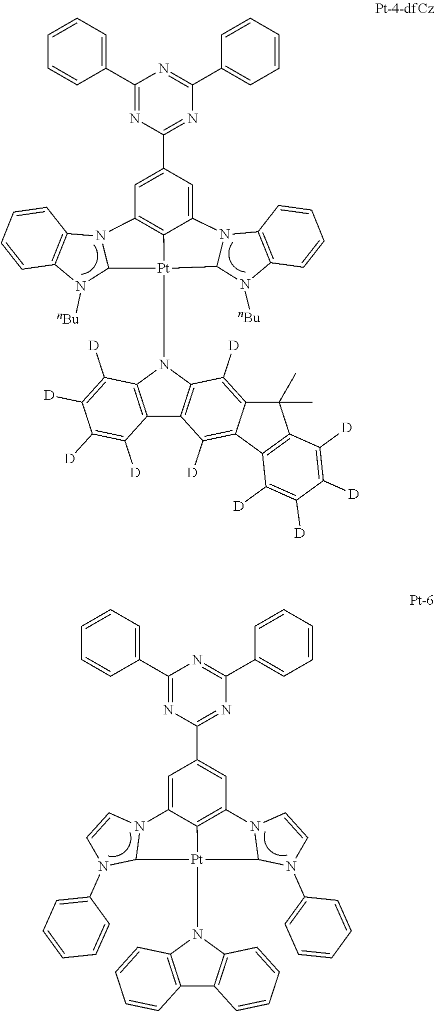

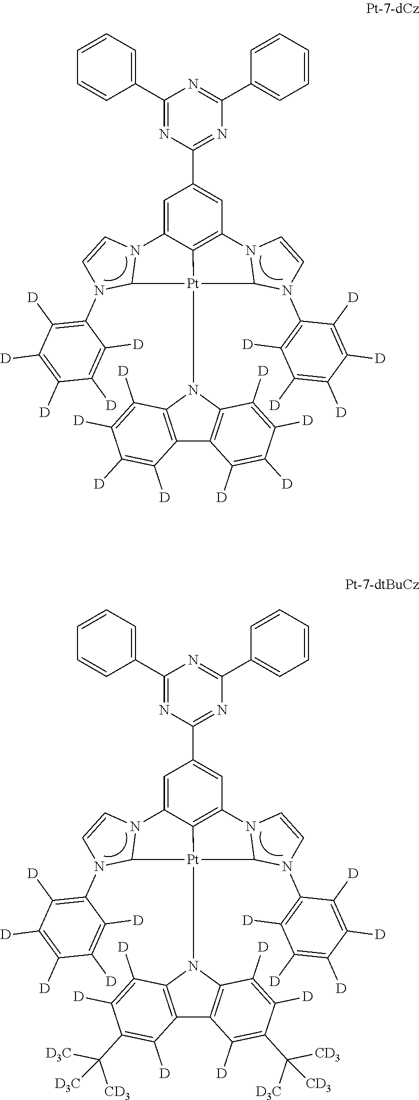

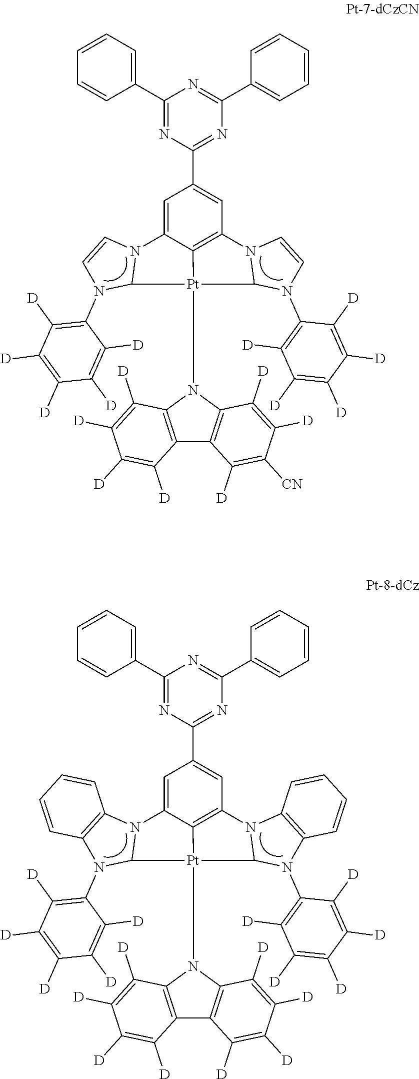

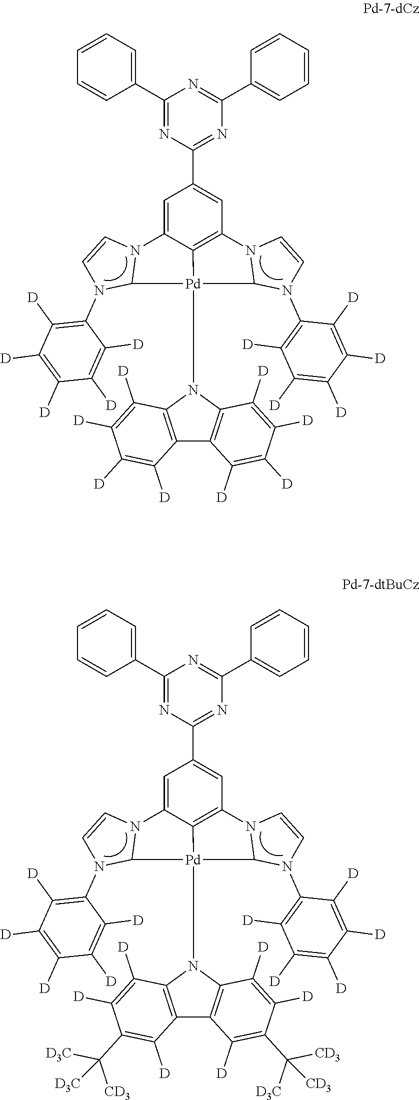

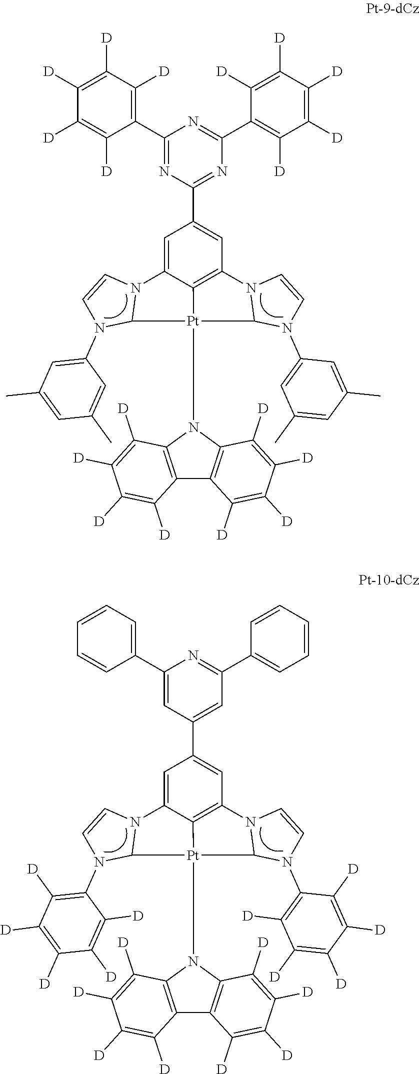

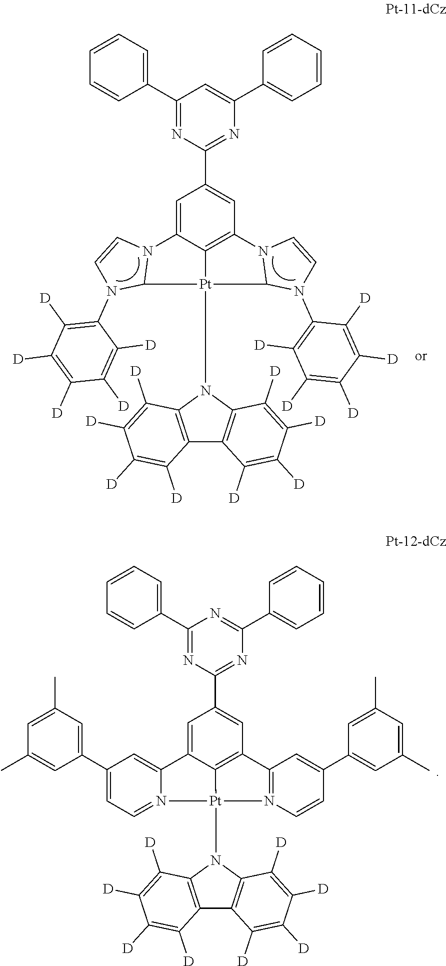

14. The metal complex of claim 1,
(a) having a maximum emission wavelength (λₘₐₓ) in a range from 540 nm to 660 nm or from 560 nm to 625 nm;
(b) having an emission quantum yield (Φₑₘ) of at least 50%, at least 55%, at least 60%, at least 65%, at least 70%, at least 75%, at least 80%, at least 85%, in a range from 50% to 90%, from 55% to 90%, from 60% to 90%, from 65% to 90%, or from 70% to 90%, measured in films, at room temperature;
(c) having an emission lifetime (τₑₘ) of ≤2.5 μs, ≤2.3 μs, 2.0 μs, ≤1.5 μs, ≤1.3 μs, in a range from 0.3 μs to 2.5 μs, from 0.3 μs to 2.3 μs, from 0.3 μs to 2.0 μs, from 0.3 μs to 1.5 μs, or from 0.3 μs to 1.3 μs, measured in films, at room temperature; and/or
(d) having a radiative decay rate constant (kᵣ) of at least 5.5×10⁵ s⁻¹, at least 6.0×10⁵ s⁻¹, at least 8.0×10⁵ s⁻¹, at least 1.0×10⁶ s⁻¹, in a range from 5.5×10⁵ s⁻¹ to 1.6×10⁶ s⁻¹, measured in films, at room temperature.

15. An organic light-emitting component comprising a light-emitting layer or two or more light-emitting layers, wherein the light-emitting layer or each light-emitting layer of the two or more light-emitting layers comprises one or more metal complex(es) of claim 1;
optionally wherein the total concentration of the one or more metal complexes in the light-emitting layer or each light-emitting layer of the two or more light-emitting layers is from about 1 wt % to about 20 wt %, from about 1 wt % to about 10 wt %, from about 2 wt % to about 20 wt %, from about 2 wt % to about 16 wt %, from about 2 wt % to about 10 wt %, or from about 2 wt % to about 8 wt %, such as about 2 wt %, about 4 wt %, about 6 wt %, or about 8 wt %.

16. The organic light-emitting component of claim 15 further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located in between the anode and the light-emitting layer, and
wherein the electron transport region is located in between the cathode and the light emitting layer.

17. The organic light-emitting component of claim 15, wherein the organic light-emitting component:
(a) emits light at λₘₐₓ in a range from 530 nm to 660 nm or from 540 nm to 600 nm, such as from 554 nm to 637 nm or from 541 nm to 599 nm;
(b) has a maximum quantum efficiency (EQE) of at least 12%, at least 15%, in a range from 12% to 30%, from 12% to 25%, from 15% to 30%, from 15% to 25%, or from 20% to 30%, such as about 25.5% or about 21.4%;
(c) has a LT₉₅ of at least 1000 hours, at least 2000 hours, at least 3000 hours, at least 4000 hours, at least 5000 hours, in a range from 1000 cd m⁻² to 7500 cd m⁻², from 1000 cd m⁻² to 7000 cd m⁻², from 1000 cd m⁻² to 6000 cd m⁻², from 2000 cd m⁻² to 7500 cd m⁻², from 2000 cd m⁻² to 7000 cd m⁻², from 2000 cd m⁻² to 6000 cd m⁻², from 3000 cd m⁻² to 7500 cd m⁻², from 3000 cd m⁻² to 7000 cd m⁻², from 3000 cd m⁻² to 6000 cd m⁻², from 4000 cd m⁻² to 7500 cd m⁻², from 4000 cd m⁻² to 7000 cd m⁻², or from 4000 cd m⁻² to 6000 cd m⁻², at 1000 cd m⁻², such as about 7300 hours or about 6660 hours, at 1000 cd m⁻²; and/or
(d) is an organic light-emitting diode (“OLED”) or a light-emitting electrochemical cell (“LEEC”).

18. The organic light-emitting component of claim 15, wherein the light emitting layer or each light-emitting layer of the two or more light-emitting layers further comprises an organic dye, and wherein the one or more metal complex(es) act(s) as a sensitizer to transfer energy to the organic dye.

19. The organic light-emitting component of claim 15, wherein the light-emitting layer or each of the light-emitting layer of the two or more light-emitting layers is formed by vacuum-evaporation deposition, spin-coating, ink-printing, or roll-to-roll printing.

20. A device comprising one or more organic light-emitting components of claim 15, wherein the device is a stationary visual display unit, a mobile visual display unit, an illumination device, a wearable device, a phototherapy device, or a medical monitoring device.
